(19) United States
(12) Patent Application Publication
(10) Pub. No.: US 2019/0252622 A1
(43) Pub. Date: Aug. 15, 2019

(54) ORGANIC LIGHT-EMITTING DEVICE

(71) Applicants: Samsung Electronics Co., Ltd., Suwon-si (KR); Samsung SDI Co., Ltd., Yongin-si (KR); NOVALED GMBH, Dresden (DE)

(72) Inventors: Jongsoo KIM, Seoul (KR); Bodo WALLIKEWITZ, Dresden (DE); Ulrich DENKER, Dresden (DE); Joonghyuk KIM, Seoul (KR); Namheon LEE, Suwon-si (KR); Sunghan KIM, Seongnam-si (KR)

(21) Appl. No.: 16/043,427

(22) Filed: Jul. 24, 2018

(30) Foreign Application Priority Data
Feb. 13, 2018 (KR) 10-2018-0018057

(51) Int. Cl. H01L 51/00; H01L 51/50; H01L 51/52

(52) U.S. Cl. CPC H01L 51/0072; H01L 51/5092; H01L 51/5012; H01L 51/5056; H01L 51/5218; H01L 51/5221; H01L 51/508; H01L 51/5096

(57) ABSTRACT

An organic light-emitting device comprising: a first electrode; a second electrode facing the first electrode; and an organic layer disposed between the first electrode and the second electrode, wherein the organic layer comprises an emission layer and an electron transport layer disposed between the emission layer and the second electrode, the electron transport layer comprises a first electron transport layer disposed between the emission layer and the second electrode and a second electron transport layer disposed between the first electron transport layer and the second electrode, the first electron transport layer comprises a first metal-free compound, the second electron transport layer comprises a second metal-free compound, the first metal-free compound and the second metal-free compound are different from each other, and the second metal-free compound is represented by Formula 2 as provided herein.

### CROSS-REFERENCE TO RELATED APPLICATION

This application claims priority to and the benefit of Korean Patent Application No. 10-2018-0018057, filed on Feb. 13, 2018, in the Korean Intellectual Property Office, and all the benefits accruing therefrom under 35 U.S.C. § 119, the content of which is incorporated herein in its entirety by reference.

### BACKGROUND

### 1. Field

One or more embodiments of the present disclosure relate to an organic light-emitting device.

### 2. Description of the Related Art

Organic light-emitting devices (OLEDs) are self-emitting devices that produce multi-color images, and also may have advantages such as wide viewing angles, high contrast ratios, short response times, high brightness, and good driving voltage characteristics.

The structure of an OLED may include an anode layer, a cathode layer, and an organic layer disposed between the anode layer and the cathode layer, wherein the organic layer includes an emission layer. The organic layer can also include a hole transport region or layer between the anode and the emission layer, and an electron transport region or layer between the emission layer and the cathode. During operation of the OLED, holes provided or injected from the anode may move toward the emission layer through the hole transport region or layer, and electrons provided or injected from the cathode may move toward the emission layer through the electron transport region or layer. The holes and the electrons may recombine in the emission layer to produce excitons. These excitons decay from an excited state to a ground state, thereby generating light.

### SUMMARY

Aspects of the present disclosure provide an organic light-emitting device that includes a second electron transport layer including a second metal-free compound represented by a certain formula to thereby provide long lifespan characteristics.

Additional aspects will be set forth in part in the description which follows and, in part, will be apparent from the description, or may be learned by practice of the presented embodiments.

An aspect of the present disclosure provides an organic light-emitting device including: a first electrode; a second electrode facing the first electrode; and an organic layer disposed between the first electrode and the second electrode, wherein the organic layer comprises an emission layer and an electron transport layer disposed between the emission layer and the second electrode, the electron transport layer includes a first electron transport layer disposed between the emission layer and the second electrode and a second electron transport layer disposed between the first electron transport layer and the second electrode, the first electron transport layer includes a first metal-free compound, the second electron transport layer includes a second metal-free compound, the first metal-free compound and the second metal-free compound are different from each other, and the second metal-free compound is represented by Formula 2 below:

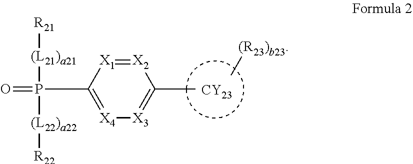

wherein, in Formula 2, ring CY₂₃ may be a pi electron-depleted nitrogen-containing C₁-C₃₀ cyclic group, X₁ may be N or C(R₁), X₂ may be N or C(R₂), X₃ may be N or C(R₃), and X₄ may be N or C(R₄), each occurrence of L₂₁ and L₂₂ is the same or different, and may each independently be a single bond, a substituted or unsubstituted C₅-C₃₀ carbocyclic group, or a substituted or unsubstituted C₁-C₃₀ heterocyclic group, a21 and a22 may each independently be an integer from 1 to 10, R₁ to R₄, R₂₁ and R₂₂ may each independently be hydrogen, deuterium, —F, —Cl, —Br, —I, —SF₅, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkylaryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkylheteroaryl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —B(Q₆)(Q₇), or —P(═O)(Q₈)(Q₉), each occurrence of R₂₃ is the same or different, and is hydrogen, deuterium, —F, —Cl, —Br, —I, —SF₅, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkylaryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkylheteroaryl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —B(Q₈)(Q₇), or —P(═O)(Q₈)(Q₉), b23 may be an integer from 0 to 20, R₁ and R₂ may optionally be linked to form a substituted or unsubstituted C₅-C₃₉ carbocyclic group or a substituted or unsubstituted C₁-C₃₀ heterocyclic group, R₃ and R₄ may optionally be linked to form a substituted or unsubstituted C₅-C₃₉ carbocyclic group or a substituted or unsubstituted C₁-C₃₀ heterocyclic group, at least one substituent of the substituted C₅-C₃₉ carbocyclic group, the substituted C₁-C₃₉ heterocyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₇-C₆₀ alkylaryl group, the substituted C₆-C₆₀ aryloxy group, the substituted C₆-C₆₀ arylthio group, the substituted C₁-C₆₀ heteroaryl group, the substituted C₂-C₆₀ alkylheteroaryl group, the substituted monovalent non-aromatic condensed polycyclic group, and the substituted monovalent non-aromatic condensed heteropolycyclic group, when present, may be deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, or a C₁-C₈₀ alkoxy group; a C₁-C₈₀ alkyl group, a C₂-C₆₀ alkenyl group, a C₂-C₆₀ alkynyl group, and a C₁-C₆₀ alkoxy group, each substituted with at least one selected from deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkylaryl group, a C₆-C₆₀ aryloxy group, a C₆-C₆₀ arylthio group, a C₁-C₆₀ heteroaryl group, a C₂-C₆₀ alkylheteroaryl group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —B(Q₁₈)(Q₁₇), or P(═O)(Q₁₈)(Q₁₉); a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkylheteroaryl group, a monovalent non-aromatic condensed polycyclic group, or a monovalent non-aromatic condensed heteropolycyclic group; a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkylaryl group, a C₆-C₆₀ aryloxy group, a C₆-C₆₀ arylthio group, a C₁-C₆₀ heteroaryl group, a C₂-C₆₀ alkylheteroaryl group, a monovalent non-aromatic condensed polycyclic group, or a monovalent non-aromatic condensed heteropolycyclic group, each substituted with at least one selected from deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkylaryl group, a C₆-C₆₀ aryloxy group, a C₆-C₆₀ arylthio group, a C₁-C₆₀ heteroaryl group, a C₂-C₆₀ alkyl heteroaryl group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —B(Q₂₆)(Q₂₇), or —P(═O)(Q₂₈)(Q₂₉); or —N(Q₃₁)(Q₃₂), —Si(Q₃₃)(Q₃₄)(Q₃₅), —B(Q₃₆)(Q₃₇), or —P(═O)(Q₃₈)(Q₃₉), and Q₁ to Q₉, Q₁₁ to Q₁₉, Q₂₁ to Q₂₉, and Q₃₁ to Q₃₉ may each be hydrogen, deuterium, —F, —Cl, —Br, —I, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryl group substituted with at least one of a C₁-C₆₀ alkyl group and a C₆-C₆₀ aryl group, a C₆-C₆₀ aryloxy group, a C₆-C₆₀ arylthio group, a C₁-C₆₀ heteroaryl group, a C₂-C₆₀ alkylheteroaryl group, a monovalent non-aromatic condensed polycyclic group, or a monovalent non-aromatic condensed heteropolycyclic group.

### BRIEF DESCRIPTION OF THE DRAWING

These and/or other aspects will become apparent and more readily apparent from the following description of the exemplary embodiments, taken in conjunction with the accompanying drawings in which:

FIG. 1 is a schematic view of an organic light-emitting device according to an embodiment; and

FIG. 2 is an annotated chemical structure according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present disclosure. As used herein, the term “and/or” includes any and all combinations of one or more of the associated listed items. Expressions such as “at least one of,” when preceding a list of elements, modify the entire list of elements and do not modify the individual elements of the list.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

It will be understood that, although the terms first, second, third, etc., may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the present embodiments.

The terminology used herein is for the purpose of describing particular embodiments only and is not intended to be limiting. As used herein, the singular forms “a,” “an,” and “the” are intended to include the plural forms as well, unless the context clearly indicates otherwise.

The term “or” means “and/or.” As used herein, the terms such as “comprising”, “including”, “having”, or the like are intended to indicate the existence of the features regions, integers, steps, operations, components, and/or elements disclosed in the specification, and are not intended to preclude the possibility that one or more other features or elements may exist or may be added.

It will also be understood that when an element such as a layer, a region or a component is referred to as being “on” another layer or element, it can be directly on the other layer or element, or intervening layers, regions, or components may also be present. In contrast, when an element is referred to as being “directly on” another element, there are no intervening elements present.

In the drawings, the sizes of elements are exaggerated or reduced for ease of description. The size or thickness of each element shown in the drawings are arbitrarily illustrated for better understanding or ease of description, and thus the present disclosure is not limited thereto.

Unless otherwise defined, all terms (including technical and scientific terms) used herein have the same meaning as commonly understood by one of ordinary skill in the art to which this general inventive concept belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

An organic light-emitting device according to an embodiment may include: a first electrode; a second electrode facing the first electrode; and an organic layer disposed between the first electrode and the second electrode. The organic layer includes an emission layer, and an electron transport layer may be disposed between the emission layer and the second electrode. The electron transport layer may include a first electron transport layer disposed between the emission layer and the second electrode and a second electron transport layer disposed between the first electron transport layer and the second electrode.

The first electron transport layer may include a first metal-free compound, and the second electron transport layer may include a second metal-free compound. The first metal-free compound and the second metal-free compound may be different from each other.

The second metal-free compound may be represented by Formula 2:

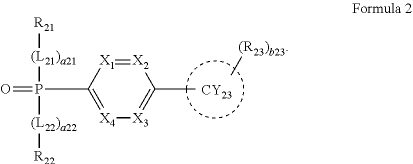

Ring CY₂₃ in Formula 2 may be a pi electron-depleted nitrogen-containing C₁-C₃₀ cyclic group. For example, ring CY₂₃ may be i) a first ring, ii) a condensed ring condensed with two or more first rings that are condensed with each other, or iii) a condensed ring condensed with at least one first ring and at least one second ring that are condensed with each other.

The first ring may be an imidazole group, a pyrazole group, a thiazole group, an isothiazole group, an oxazole group, an isoxazole group, a pyridine group, a pyrazine group, a pyridazine group, a pyrimidine group, an indazole group, a purine group, a quinoline group, an isoquinoline group, a benzoquinoline group, a benzoisoquinoline group, a phthalazine group, a naphthyridine group, a quinoxaline group, a benzoquinoxaline group, a quinazoline group, a cinnoline group, a phenanthridine group, a phenanthroline group, a phenazine group, a benzimidazole group, an iso-benzothiazole group, a benzoxazole group, an isobenzoxazole group, a triazole group, a tetrazole group, an oxadiazole group, a triazine group, a thiadiazole group, an imidazopyridine group, an imidazopyrimidine group, an azaindene group, an azaindole group, an azabenzofuran group, an azabenzothiophene group, an azabenzosilole group, an azafluorene group, an azacarbazole group, an azadibenzofuran group, an azadibenzothiophene group, or an azadibenzosilole group, but embodiments of the present disclosure are not limited thereto.

The second ring may be a benzene group, a heptalene group, an indene group, a naphthalene group, an azulene group, a heptalene group, an indacene group, an acenaphthylene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentacene group, a hexacene group, a pentaphene group, a rubicen group, a coronen group, an ovalene group, a pyrrole group, an iso-indole group, an indole group, a furan group, a thiophene group, a benzofuran group, a benzothiophene group, a benzosilole group, a benzocarbazole group, a dibenzocarbazole group, a dibenzofuran group, a dibenzothiophene group, a dibenzothiophene sulfone group, a carbazole group, a dibenzosilole group, an indeno carbazole group, an indolocarbazole group, a benzofurocarbazole group, a benzothienocarbazole group, a benzosilolocarbazole group, a triindolobenzene group, an acridine group, or a dihydroacridine group, but embodiments of the present disclosure are not limited thereto.

In Formula 2, X₁ may be N or C(R₁), X₂ may be N or C(R₂), X₃ may be N or C(R₃), and X₄ may be N or C(R₄). For example, in Formula 2, X₁ may be C(R₁), X₂ may be C(R₂), X₃ may be C(R₃), and X₄ may be C(R₄), but embodiments of the present disclosure are not limited thereto.

Each occurrence of L₂₁ and L₂₂ in Formula 2 is the same or different, and may each independently be a single bond, a substituted or unsubstituted C₅-C₃₀ carbocyclic group, or a substituted or unsubstituted C₁-C₃₀ heterocyclic group. For example, each occurrence of L₂₁ and L₂₂ is the same or different, and may each independently be a single bond; or a benzene group, a naphthalene group, an anthracene group, a phenanthrene group, a triphenylene group, a pyrene group, a chrysene group, a cyclopentadiene group, a furan group, a thiophene group, a silole group, an indene group, a fluorene group, an indole group, a carbazole group, a benzofuran group, a dibenzofuran group, a benzothiophene group, a dibenzothiophene group, a benzosilole group, a dibenzosilole group, an azafluorene group, an azacarbazole group, an azadibenzofuran group, an azadibenzothiophene group, an azadibenzosilole group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isoxazole group, a thiazole group, an isothiazole group, an oxadiazole group, a thiadiazole group, a benzopyrazole group, a benzimidazole group, a benzoxazole group, a benzothiazole group, a benzooxadiazole group, and a benzothiadiazole group, each unsubstituted or substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a biphenyl group, a terphenyl group, a naphthyl group, a pyridinyl group, a pyrimidinyl group, a triazinyl group, a fluorenyl group, a dimethylfluorenyl group, a diphenylfluorenyl group, a carbazolyl group, a phenylcarbazolyl group, a dibenzofuranyl group, a dibenzothiophenyl group, a dibenzosilolyl group, a dimethyldibenzosilolyl group, a diphenyldibenzosilolyl group, —N(Q₃₁)(Q₃₂), —Si(Q₃₃)(Q₃₄)(Q₃₅), —B(Q₃₆)(Q₃₇), or —P(═O)(Q₃₈)(Q₃₉), but embodiments are not limited thereto.

Q₃₁ to Q₃₉ may each independently be —CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂; an n-propyl group, an isopropyl group, an n-butyl group, an isobutyl group, a sec-butyl group, a tert-butyl group, an n-pentyl group, an isopentyl group, a sec-pentyl group, a tert-pentyl group, a phenyl group, or a naphthyl group; or an n-propyl group, an isopropyl group, an n-butyl group, an isobutyl group, a sec-butyl group, a tert-butyl group, an n-pentyl group, an isopentyl group, a sec-pentyl group, a tert-pentyl group, a phenyl group, and a naphthyl group, each substituted with at least one selected from deuterium, a C₁-C₁₀ alkyl group, or a phenyl group, but embodiments of the present disclosure are not limited thereto.

a21 and a22 in Formula 2 respectively indicate the number of L₂₁ groups and the number of L₂₂ groups, and may each independently be an integer from 1 to 10. When a21 is two or more, two or more of the L₂₁ groups may be identical to or different from each other, and when a22 is two or more, two or more of the L₂₂ groups may be identical to or different from each other. For example, a21 and a22 may each independently be 1 or 2, but embodiments of the present disclosure are not limited thereto.

R₁ to R₄, R₂₁, and R₂₂ in Formula 2 may each independently be hydrogen, deuterium, —F, —Br, —SF₅, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted heterocycloalkyl group, a substituted or unsubstituted C₃-C₁₀ cycloalkenyl group, a substituted or unsubstituted heterocycloalkenyl group, a substituted or unsubstituted C₆-C₆₀ aryl group, a substituted or unsubstituted C₇-C₆₀ alkylaryl group, a substituted or unsubstituted C₆-C₆₀ aryloxy group, a substituted or unsubstituted C₆-C₆₀ arylthio group, a substituted or unsubstituted heteroaryl group, a substituted or unsubstituted C₂-C₆₀ alkylheteroaryl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —B(Q₆)(Q₇), or —P(═O)(Q₈)(Q₉).

Q₁ to Qs are each independently hydrogen, deuterium, —F, —Cl, —Br, —I, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryl group substituted with at least one of a C₁-C₆₀ alkyl group and a C₆-C₆₀ aryl group, a C₆-C₆₀ aryloxy group, a C₆-C₆₀ arylthio group, a CI-Coo heteroaryl group, a C₂-C₆₀ alkylheteroaryl group, a monovalent non-aromatic condensed polycyclic group, or a monovalent non-aromatic condensed heteropolycyclic group.

For example, R₁ to R₄, R₂₁ and R₂₂ may each independently be hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, —SF₅, a C₁-C₂₀ alkyl group, or a C₁-C₂₀ alkoxy group; a C₁-C₂₀ alkyl group and a C₁-C₂₀ alkoxy group, each substituted with at least one selected from deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a cyclopentyl group, a cyclohexyl group, a cycloheptyl group, a cycloctyl group, an adamantanyl group, a norbornanyl group, a norbornenyl group, a cyclopentenyl group, a cyclohexenyl group, a cycloheptenyl group, a phenyl group, a biphenyl group, a naphthyl group, a pyridinyl group, or a pyrimidinyl group; a cyclopentyl group, a cyclohexyl group, a cycloheptyl group, a cycloctyl group, an adamantanyl group, a norbornanyl group, a norbornenyl group, a cyclopentenyl group, a cyclohexenyl group, a cycloheptenyl group, a phenyl group, a biphenyl group, a C₁-C₂₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, or an imidazopyrjmidinyl group; a cyclopentyl group, a cyclohexyl group, a cycloheptyl group, a cycloctyl group, an adamantanyl group, a norbornanyl group, a norbornenyl group, a cyclopentenyl group, a cyclohexenyl group, a cycloheptenyl group, a phenyl group, a biphenyl group, a C₁-C₂₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, or an imidazopyrimidinyl group, each substituted with at least one of deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₉ alkyl group, a C₁-C₂₉ alkoxy group, a cyclopentyl group, a cyclohexyl group, a cycloheptyl group, a cycloctyl group, an adamantanyl group, a norbornanyl group, a norbornenyl group, a cyclopentenyl group, a cyclohexenyl group, a cycloheptenyl group, a phenyl group, a biphenyl group, a C₁-C₂₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, or an imidazopyrimidinyl group; or —N(Q₁)(Q₂), —Si(Q₃)(Q₄)(Q₅), —B(Q₆)(Q₇), and —P(═O)(Q₈)(Q₉), and Q₁ to Q₉ are the same as described above, but embodiments of the present disclosure are not limited thereto.

Each occurrence of R₂₃ is the same or different, and is hydrogen, deuterium, —F, —C₁, —Br, —I, —SF₅, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkylaryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkylheteroaryl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —B(Q₆)(Q₇), or —P(═O)(Q₈)(Q₉). In other embodiments, each occurrence of R₂₃ can be the same as defined above for R₂₁ or R₂₂.

b23 in Formula 2 indicates the number of R₂₃ groups and may be an integer from 0 to 20. When b23 is two or more, two or more of the R₂₃ groups may be identical to or different from each other. For example, b23 may be 0, 1, 2, or 3, but embodiments of the present disclosure are not limited thereto.

R₁ and R₂ may optionally be linked to form a C₅-C₃₀ carbocyclic group unsubstituted or substituted with at least one group R₂₀ₐ, or a C₁-C₃₀ heterocyclic group unsubstituted or substituted with at least one group R₂₀ₐ (for example, a benzene group, a naphthalene group, a pyridine group, a pyrimidine group, and a pyrazine group, each unsubstituted or substituted with at least one R₂₀ₐ), and R₃ and R₄ may optionally be linked to form a C₅-C₃₀ carbocyclic group unsubstituted or substituted with at least one group R₂₀ₐ, or a C₁-C₃₀ heterocyclic group unsubstituted or substituted with at least one groups R₂₀ₐ (for example, a benzene group, a naphthalene group, a pyridine group, a pyrimidine group, and a pyrazine group, each unsubstituted or substituted with at least one R₂₀ₐ). R₂₀ₐ can be the same groups as described in connection with R₂₁.

In one embodiment, the second metal-free compound may be represented by one of Formulae 2-1 to 2-10:

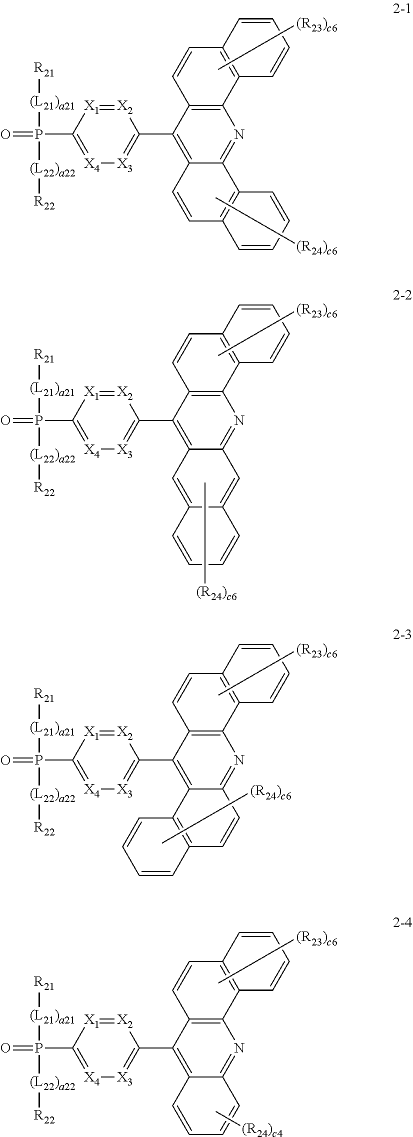

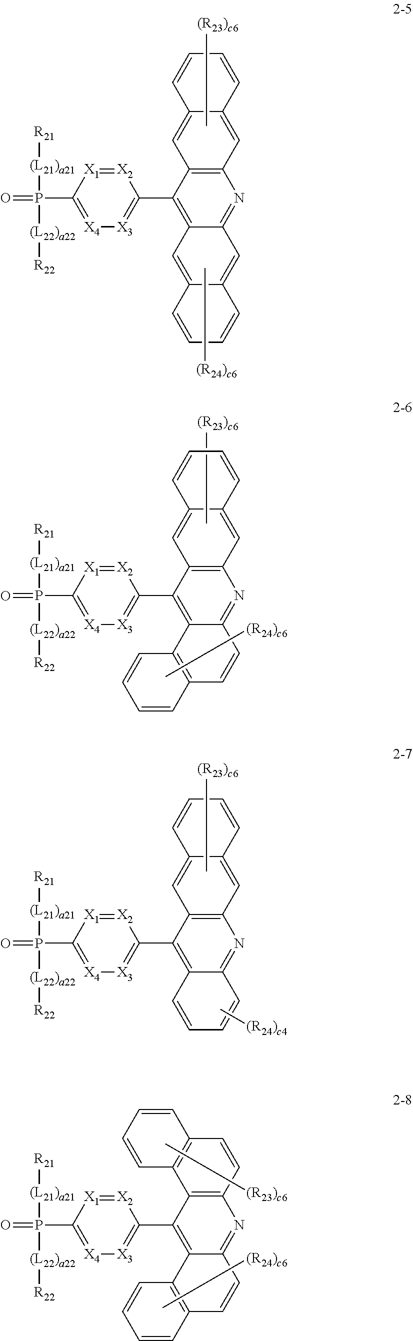

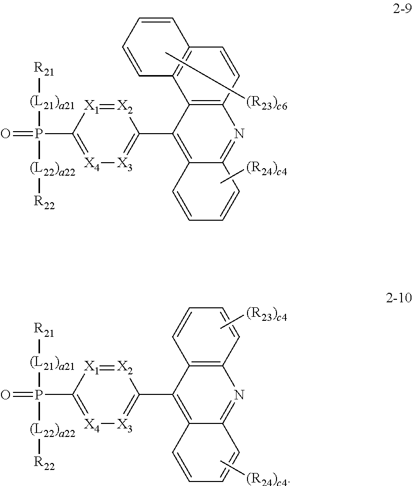

In Formulae 2-1 to 2-10, X₁ to X₄, L₂₁, L₂₂, a21, a22, and R₂₁ to R₂₃ are the same as described herein, R₂₄ is the same as described in connection with R₂₃, c6 may be an integer from 0 to 6, and c4 may be an integer from 0 to 4.

The second metal-free compound may have a dipole moment of about 3.0 D or more, for example, a dipole moment of about 3.0 D to about 5.0 D. In one embodiment, the second metal-free compound may have a dipole moment of about 3.1 D to about 5.0 D, a dipole moment of about 3.2 D to about 4.9 D, a dipole moment of about 3.3 D to about 4.5 D, or a dipole moment of about 3.5 D to about 4.5 D, but embodiments of the present disclosure are not limited thereto.

The dipole moment may evaluated by calculating a distance between atoms and Mulliken charge of each atom of a compound by using a density functional theory (DFT) method, for example of a Gaussian program structurally optimized at a level of B3LYP, 6-31G(d,p), and then calculating a dipole moment of the corresponding compound therefrom.

The dipole moment of the second metal-free compound may be greater than the dipole moment of the first metal-free compound.

The first metal-free compound may be a phosphine oxide-containing compound, for example, a cyclicphosphine oxide-containing compound.

For example, the first metal-free compound may be represented by Formula 1:

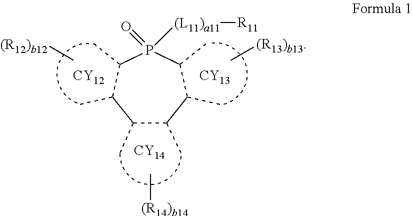

Rings CY₁₂ to CY₁₄ in Formula 1 may each independently be a C₅-C₃₀ carbocyclic group or a C₁-C₃₀ heterocyclic group. For example, rings CY₁₂ to CY₁₄ may each independently be i) a first ring, ii) a second ring, iii) a condensed ring with two or more first rings condensed with each other, iv) a condensed ring with two or more second rings condensed with each other, or v) a condensed ring with at least one first ring and at least one second ring condensed with each other, and the first ring and the second ring may be the same as described in connection with ring CY₂₃ in Formula 2.

In Formula 1, each occurrence of L₁₁ is the same or different, and is independently a single bond, a substituted or unsubstituted C₅-C₃₀ carbocyclic group, or a substituted or unsubstituted C₁-C₃₀ heterocyclic group, and a11 is an integer from 1 to 10.

R₁₁ to R₁₄ are each independently hydrogen, deuterium, —F, —Br, —SF₅, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted heterocycloalkyl group, a substituted or unsubstituted C₃-C₁₀ cycloalkenyl group, a substituted or unsubstituted heterocycloalkenyl group, a substituted or unsubstituted C₆-C₆₀ aryl group, a substituted or unsubstituted C₇-C₆₀ alkylaryl group, a substituted or unsubstituted C₆-C₆₀ aryloxy group, a substituted or unsubstituted C₆-C₆₀ arylthio group, a substituted or unsubstituted heteroaryl group, a substituted or unsubstituted C₂-C₆₀ alkylheteroaryl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —B(Q₆)(Q₇), or —P(═O)(Q₈)(Q₉).

Q₁ to Q₉ may each be independently hydrogen, deuterium, —F, —Cl, —Br, —I, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryl group substituted with at least one of a C₁-C₆₀ alkyl group and a C₆-C₆₀ aryl group, a C₆-C₆₀ aryloxy group, a C₆-C₆₀ arylthio group, a C₁-C₆₀ heteroaryl group, a C₂-C₆₀ alkylheteroaryl group, a monovalent non-aromatic condensed polycyclic group, or a monovalent non-aromatic condensed heteropolycyclic group.

b12, b13, and b14 in Formula 1 respectively indicate the number of R₁₂ groups, the number of R₁₃ groups, and the number of R₁₁ groups, and may each independently be an integer from 0 to 20. When b12 is two or more, two or more of the group R₁₂ may be identical to or different from each other, when b13 is two or more, two or more of the groups R₁₃ may be identical to or different from each other, and when b14 is two or more, two or more of the groups R₁₁ may be identical to or different from each other. For example, b12 to b14 may each independently be 0, 1, 2, or 3, but embodiments of the present disclosure are not limited thereto.

In one embodiment, the first metal-free compound may be represented by one of Formulae 1-1 to 1-16:

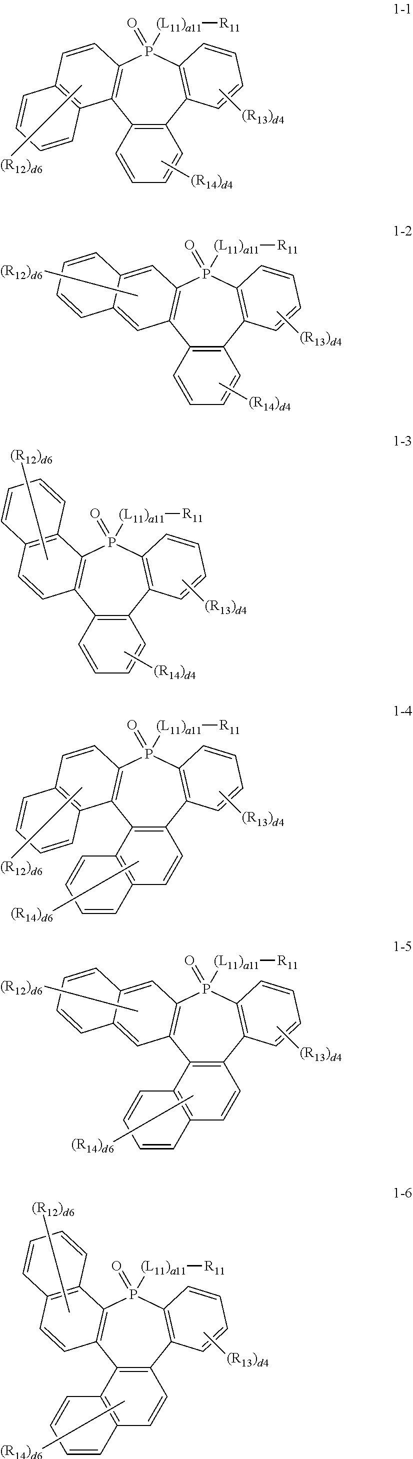

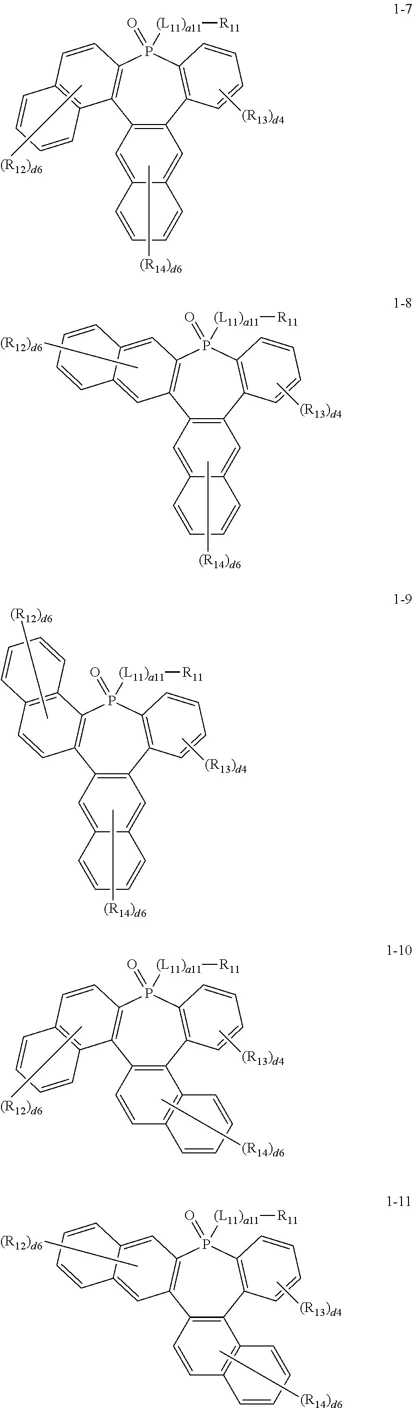

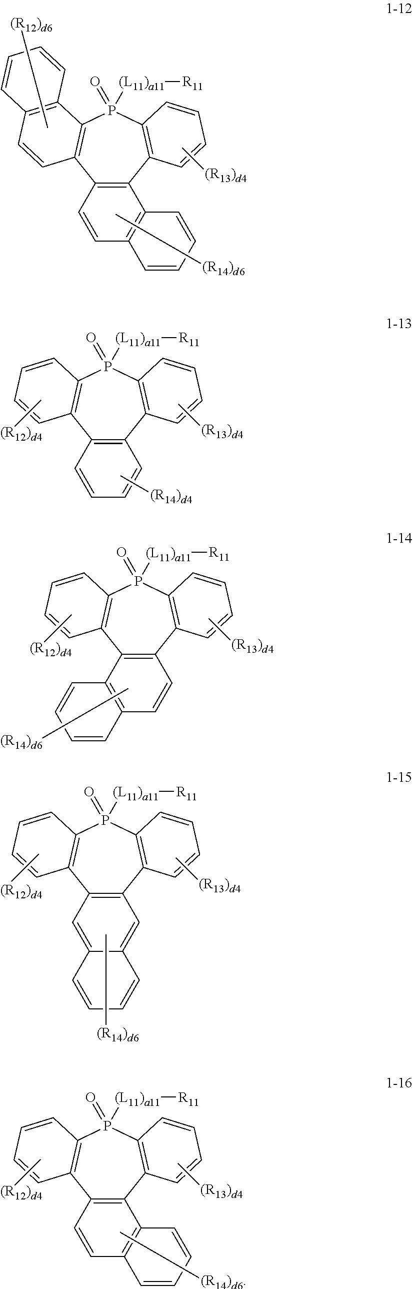

In Formulae 1-1 to 1-16, each occurrence of L₁₁ may be the same or different, and is a single bond, a substituted or unsubstituted C₅-C₃₀ carbocyclic group, or a substituted or unsubstituted C₁-C₃₀ heterocyclic group, and all may be an integer from 1 to 10.

Each occurrence of R₁₁ to R₁₄ may be the same or different, and may each independently be hydrogen, deuterium, —F, —Cl, —Br, —I, —SF₅, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted heterocycloalkyl group, a substituted or unsubstituted C₃-C₁₀ cycloalkenyl group, a substituted or unsubstituted heterocycloalkenyl group, a substituted or unsubstituted C₆-C₆₀ aryl group, a substituted or unsubstituted C₇-C₆₀ alkylaryl group, a substituted or unsubstituted C₆-C₆₀ aryloxy group, a substituted or unsubstituted C₆-C₆₀ arylthio group, a substituted or unsubstituted heteroaryl group, a substituted or unsubstituted C₂-C₆₀ alkylheteroaryl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —B(Q₆)(Q₇), or —P(═O)(Q₈)(Q₉).

Q₁ to Q₉ may each be independently hydrogen, deuterium, —F, —Cl, —Br, —I, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryl group substituted with at least one of a C₁-C₆₀ alkyl group and a C₆-C₆₀ aryl group, a C₆-C₆₀ aryloxy group, a C₆-C₆₀ arylthio group, a C₁-C₆₀ heteroaryl group, a C₂-C₆₀ alkylheteroaryl group, a monovalent non-aromatic condensed polycyclic group, or a monovalent non-aromatic condensed heteropolycyclic group.

In Formulae 1-1 to 1-16, d6 may be an integer from 0 to 6, and d4 may be an integer from 0 to 4.

In one or more embodiments, the second metal-free compound may be one of Compounds E2-1 to E2-10, but embodiments of the present disclosure are not limited thereto:

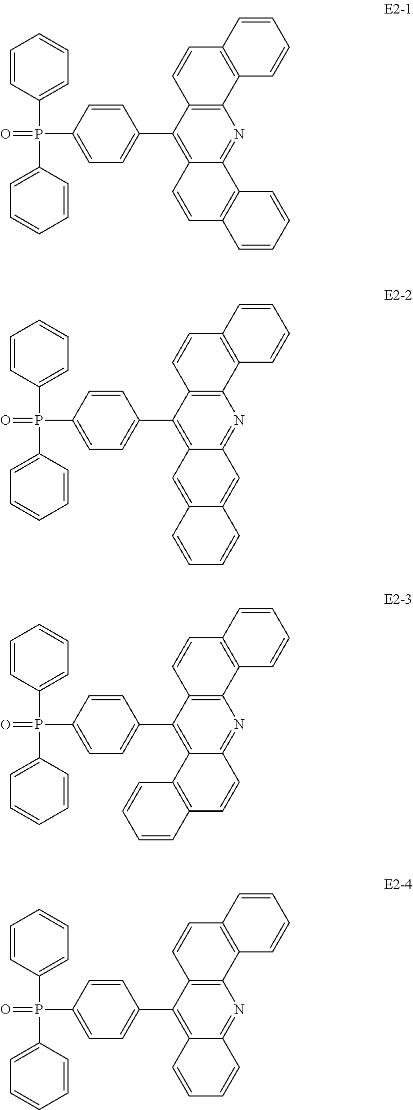 [SMILES: O=P(c1ccccc1)(c1ccccc1)c1ccc(-c2c3ccc4ccccc4c3nc3c2ccc2ccccc23)cc1 ; O=P(c1ccccc1)(c1ccccc1)c1ccc(-c2c3cc4ccccc4cc3nc3c2ccc2ccccc23)cc1 ; O=P(c1ccccc1)(c1ccccc1)c1ccc(-c2c3ccc4ccccc4c3nc3ccc4ccccc4c23)cc1 ; O=P(c1ccccc1)(c1ccccc1)c1ccc(-c2c3ccccc3nc3c2ccc2ccccc23)cc1]

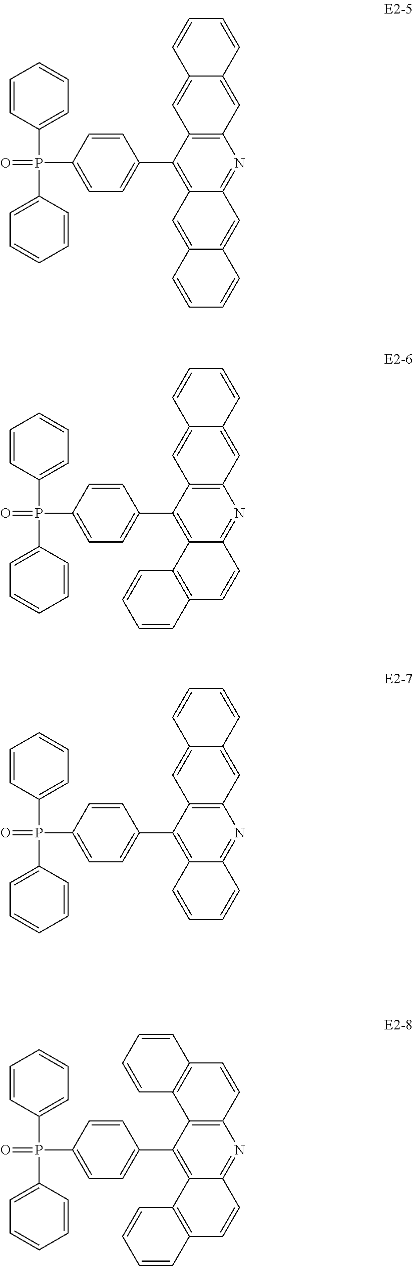 [SMILES: O=P(c1ccccc1)(c1ccccc1)c1ccc(-c2c3cc4ccccc4cc3nc3cc4ccccc4cc23)cc1 ; O=P(c1ccccc1)(c1ccccc1)c1ccc(-c2c3cc4ccccc4cc3nc3ccc4ccccc4c23)cc1 ; O=P(c1ccccc1)(c1ccccc1)c1ccc(-c2c3ccccc3nc3cc4ccccc4cc23)cc1 ; O=P(c1ccccc1)(c1ccccc1)c1ccc(-c2c3c(ccc4ccccc43)nc3ccc4ccccc4c23)cc1]

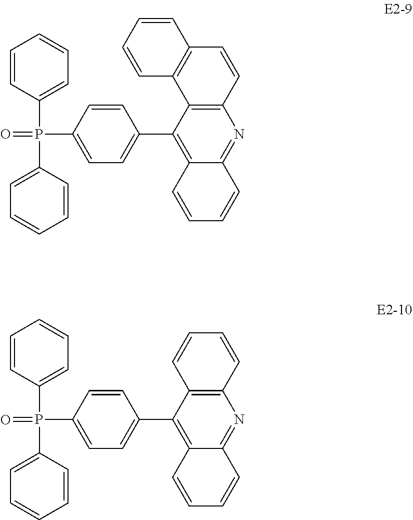 [SMILES: O=P(c1ccccc1)(c1ccccc1)c1ccc(-c2c3ccccc3nc3ccc4ccccc4c23)cc1 ; O=P(c1ccccc1)(c1ccccc1)c1ccc(-c2c3ccccc3nc3ccccc23)cc1]

In one or more embodiments, the first metal-free compound may be one of Compounds E1-1 to E1-16, but embodiments of the present disclosure are not limited thereto:

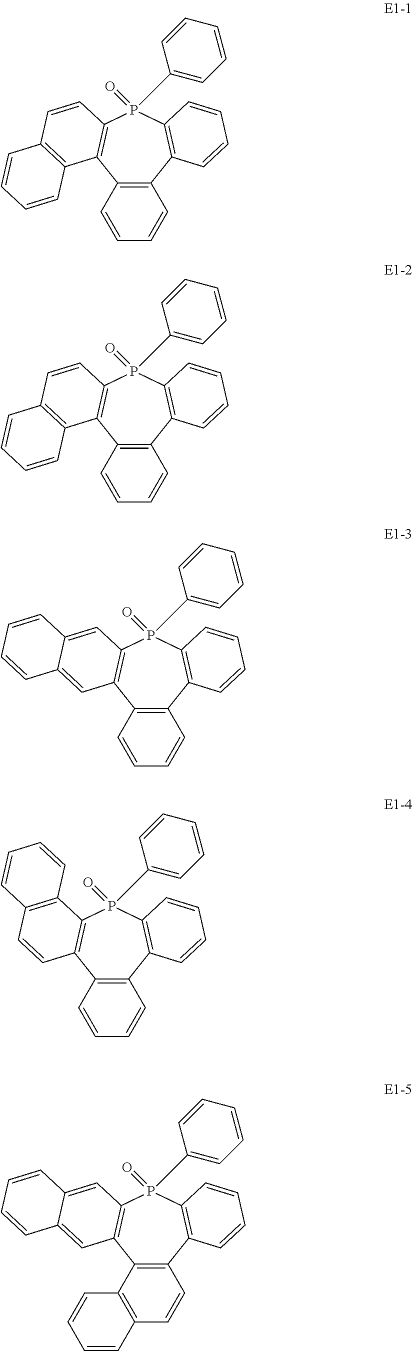 [SMILES: O=P1(c2ccccc2)c2ccccc2-c2ccccc2-c2c1ccc1ccccc21 ; O=P1(c2ccccc2)c2ccccc2-c2ccccc2-c2c1ccc1ccccc21 ; O=P1(c2ccccc2)c2ccccc2-c2ccccc2-c2cc3ccccc3cc21 ; O=P1(c2ccccc2)c2ccccc2-c2ccccc2-c2ccc3ccccc3c21 ; O=P1(c2ccccc2)c2ccccc2-c2ccc3ccccc3c2-c2cc3ccccc3cc21]

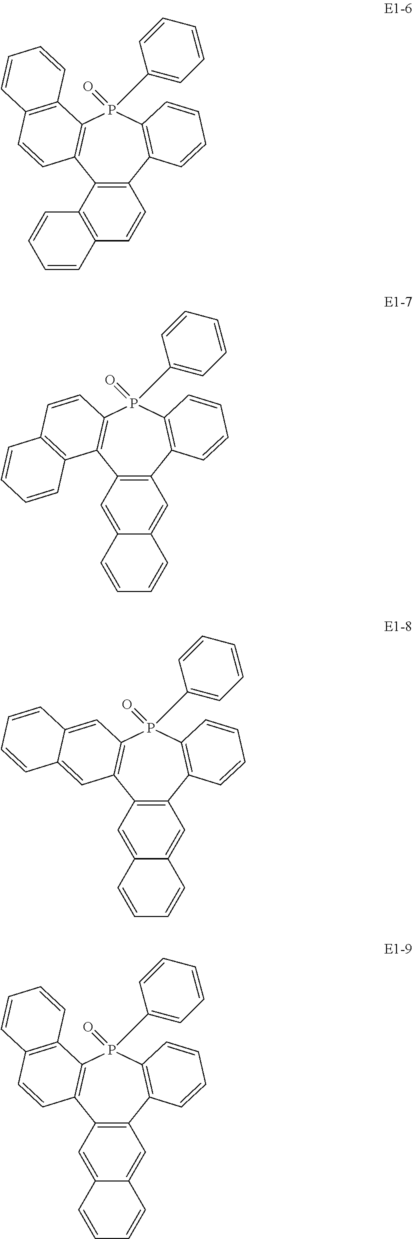

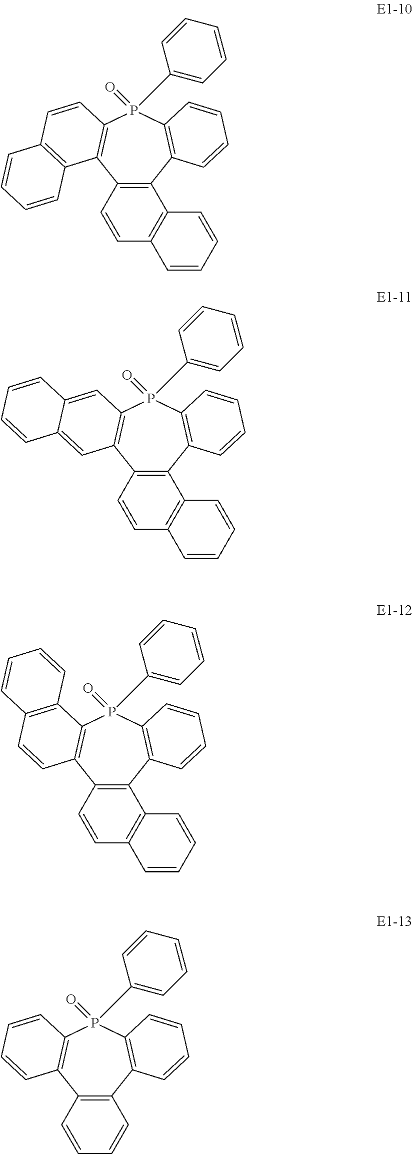

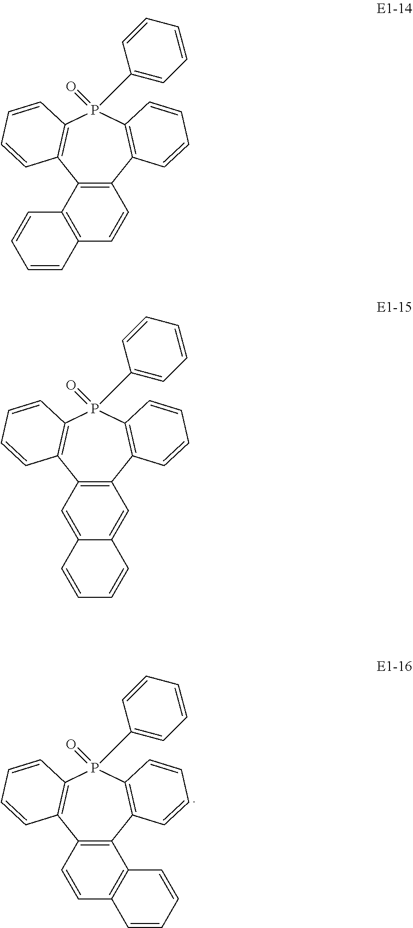 [SMILES: O=P1(c2ccccc2)c2ccccc2-c2ccc3ccccc3c2-c2ccccc21 ; O=P1(c2ccccc2)c2ccccc2-c2cc3ccccc3cc2-c2ccccc21 ; O=P1(c2ccccc2)c2ccccc2-c2ccc3ccccc3c2-c2ccccc21 ; "."]

At least one of the first electron transport layer and the second electron transport layer may further include a metal-containing compound.

For example, the first electron transport layer may further include a first metal-containing compound, and the second electron transport layer may further include a second metal-containing compound.

The metal included in the first metal-containing compound and the metal included in the second metal-containing compound may each independently be an alkali metal (for example, lithium (Li), sodium (Na), potassium (K), rubidium (Rb), and cesium (Cs)) or an alkaline earth metal (for example, beryllium (Be), magnesium (Mg), calcium (Ca), strontium (Sr), and barium (Ba)).

The first metal-containing compound and the second metal-containing compound may each independently be a metal halide, a metal oxide, or a metal complex.

In one embodiment, the first metal-containing compound and the second metal-containing compound may each independently be an alkali metal complex or an alkaline earth-metal complex,

The alkali metal complex may include a metal ion that is a Li ion, a Na ion, a K ion, a Rb ion, or a Cs ion.

The alkaline earth-metal complex may include a metal ion that is a Be ion, a Mg ion, a Ca ion, a Sr ion, or a Ba ion.

A ligand coordinated with the metal ion of the alkali metal complex and a ligand coordinated with the metal ion of the alkaline earth-metal complex may each independently be a hydroxyquinoline group, a hydroxyisoquinoline group, a hydroxybenzoquinoline group, a hydroxyacridine group, a hydroxyphenanthridine group, a hydroxyphenyloxazole, a hydroxyphenylthiazole group, a hydroxydiphenyloxadiazole group, a hydroxydiphenylthiadiazol group, a hydroxyphenylpyridine group, a hydroxyphenylbenzimidazole group, a hydroxyphenylbenzothiazole group, a bipyridine group, a phenanthroline group, or a cyclopetadiene group, but embodiments of the present disclosure are not limited thereto.

In one or more embodiments, the first metal-containing compound and the second metal-containing compound may each independently be a metal halide, a compound represented by Formulae 5-1 to 5-3, or a compound having a moiety represented by one of Formulae 5-1 to 5-3, wherein a metal of the metal halide may be an alkali metal or an alkaline earth metal:

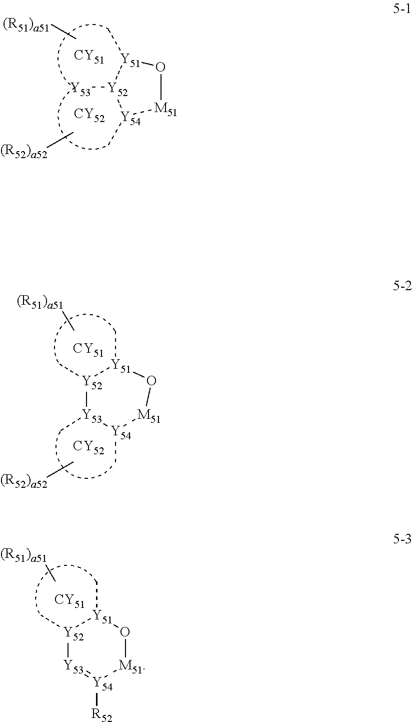

In Formulae 5-1 to 5-3, M₅₁ may be an alkali metal or an alkaline earth metal, rings CY₅₁ and CY₅₂ may each independently be a C₅-C₃₀ carbocyclic group or a C₁-C₃₀ heterocyclic group, Y₅₁ may be C, Y₅₂ and Y₅₃ may each independently be N or C, Y₅₄ may be N, each occurrence of R₅₁ and R₅₂ are the same or different, and are each independently hydrogen, deuterium, —F, —Cl, —Br, —I, —SF₅, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted heterocycloalkyl group, a substituted or unsubstituted C₃-C₁₀ cycloalkenyl group, a substituted or unsubstituted heterocycloalkenyl group, a substituted or unsubstituted C₆-C₆₀ aryl group, a substituted or unsubstituted C₇-C₆₀ alkylaryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkylheteroaryl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —B(Q₆)(Q₇), or —P(═O)(Q₈)(Q₉), and a51 and a52 are each independently an integer from 0 to 20 (for example, 0, 1, 2, or 3).

In Formulae 5-1 to 5-3, a bond between O and M₅₁ may be a covalent bond, and a bond between Y₅₄ and M₅₁ may be a coordinate bond.

Rings CY₅₁ and CY₅₂ in Formulae 5-1 to 5-3 may each independently be i) a first ring, ii) a second ring, iii) a condensed ring with two or more first rings that are condensed, iv) a condensed ring with two or more second rings that are condensed, or v) a condensed ring with at least one first ring and at least one second ring that are condensed, and the first ring and the second ring may be the same as described in connection with ring CY₂₃ in Formula 2.

Rings CY₅₁ and CY₅₂ in Formula 5-1 may be condensed with each other, and rings CY₅₁ and CY₅₂ in Formula 5-2 may be linked via a single bond.

In one embodiment, the first metal-containing compound and the second metal-containing compound may be identical to each other. In one or more embodiments, the first metal-containing compound and the second metal-containing compound may be different from each other.

In one or more embodiments, an amount of the first metal-containing compound may be in a range of about 10 parts by weight to about 90 parts by weight (for example, about 15 parts by weight to about 80 parts by weight, or about 50 parts by weight to about 80 parts by weight) based on 100 parts by weight of the first electron transport layer, and an amount of the second metal-containing compound may be in a range of about 10 parts by weight to about 90 parts by weight (for example, about 15 parts by weight to about 80 parts by weight, or about 50 parts by weight to about 80 parts by weight) based on 100 parts by weight of the second electron transport layer

In one or more embodiments, an amount of the first metal-containing compound based on 100 parts by weight of the first electron transport layer may be substantially equal, for example equal, to an amount of the second metal-containing compound based on 100 parts by weight of the second electron transport layer.

In one or more embodiments, an amount of the first metal-containing compound based on 100 parts by weight of the first electron transport layer may be different from an amount of the second metal-containing compound based on 100 parts by weight of the second electron transport layer.

In one or more embodiments, the first metal-containing compound and the second metal-containing compound may each independently be one of Compounds ET-D1 to ET-D6, but embodiments of the present disclosure are not limited thereto:

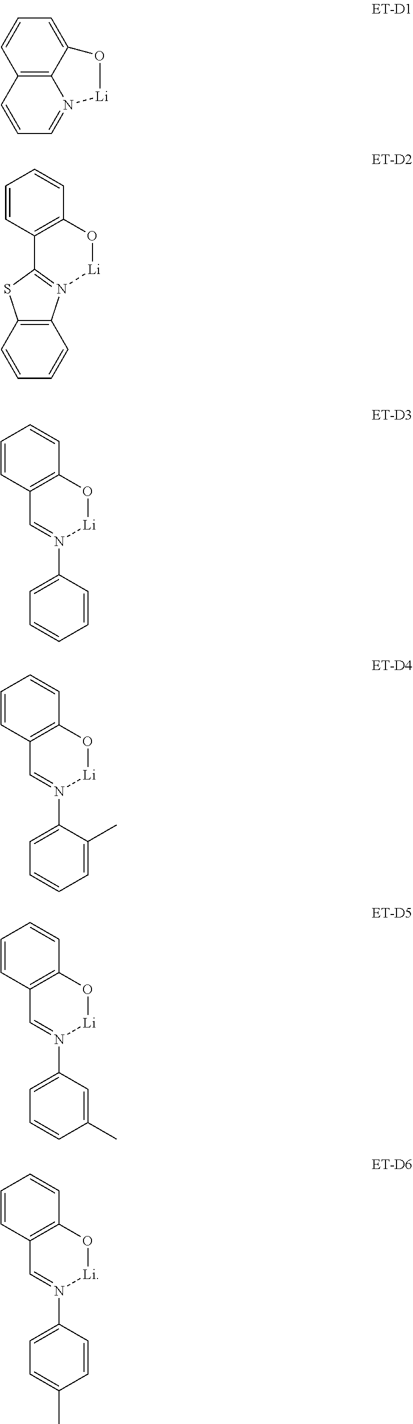

The electron transport layer of the organic light-emitting device may include the first electron transport layer and the second electron transport layer as described herein, and the second electron transport layer may include the second metal-free compound represented by Formula 2 as described herein.

As shown in FIG. 2, Formula 2 has a structure in which a “phosphine oxide moiety” and “ring CY₂₃” are linked via a linker that links the phosphine oxide moiety and ring CY₂₃ at a “para” position, the second metal-free compound represented by Formula 2 may have a relatively high dipole moment as described herein. Thus, without being bound by theory, dipole orientation is effectively induced at an interface between the first electron transport layer and the second electron transport layer, thereby increasing electron accumulation at the interface between the first electron transport layer and the second electron transport layer. Therefore, the balance of charge injection into the emission layer of the organic light-emitting device is effectively achieved, thereby improving the lifespan of the organic light-emitting device.

The organic light-emitting device may satisfy the inequality |LUMO(ETL2)|>|LUMO(ETL1)| (for example, |LUMO(ETL2)|−|LUMO(ETL1)|>0.1 eV). |LUMO(ETL1)| may be an absolute value of a lowest unoccupied molecular orbital (LUMO) energy level (eV) of the first electron transport layer, |LUMO(ETL2)| may be an absolute value of a LUMO energy level (eV) of the second electron transport layer, and LUMO(ETL1) and LUMO(ETL2) may be evaluated by using a DFT method, for example a Gaussian program structurally optimized at a level of B3LYP, 6-31G(d,p). In this manner, charge injection into the emission layer in the organic light-emitting device may be effectively controlled, thereby improving the lifespan of the organic light-emitting device.

In the organic light-emitting device, the first electron transport layer may directly contact the second electron transport layer. That is, another layer may not be provided or disposed between the first electron transport layer and the second electron transport layer. In this manner, charge injection into the emission layer in the organic light-emitting device may be effectively controlled, thereby improving the lifespan of the organic light-emitting device.

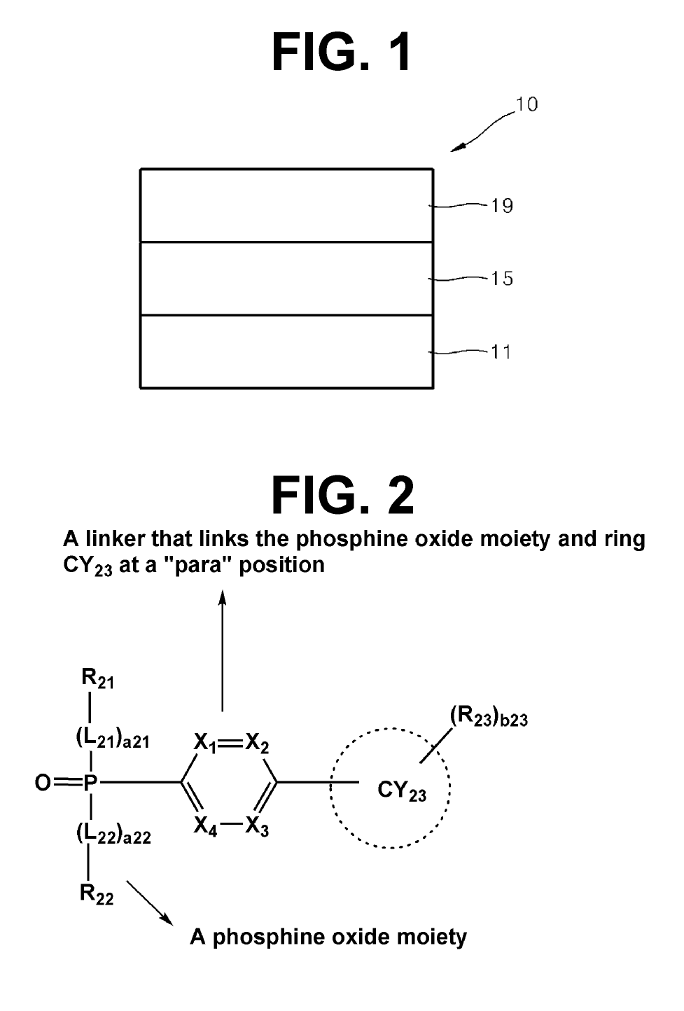

FIG. 1 is a schematic view of an organic light-emitting device 10 according to an embodiment.

The organic light-emitting device 10 of FIG. 1 includes a first electrode 11, an organic layer 15, and a second electrode 19, which are sequentially stacked. The organic layer 15 has a structure including a hole transport region, an emission layer, and an electron transport region that are sequentially stacked, wherein the electron transport region may include an electron transport layer, and the electron transport layer may include the first electron transport layer and the second electron transport layer described herein. Hereinafter, the structure of an organic light-emitting device according to an embodiment and a method of manufacturing an organic light-emitting device according to an embodiment will be described in connection with FIG. 1.

A substrate may be additionally disposed under the first electrode 11 or above the second electrode 19. For use as the substrate, any substrate that is used in general organic light-emitting devices may be used, and the substrate may be a glass substrate or a transparent plastic substrate, each having excellent mechanical strength, thermal stability, transparency, surface smoothness, ease of handling, and water resistance.

The first electrode 11 may be formed by depositing or sputtering a material for forming the first electrode 11 on the substrate. The first electrode 11 may be an anode. The material for forming the first electrode 11 may be selected from materials with a high work function to facilitate hole injection. The first electrode 11 may be a reflective electrode, a semi-transmissive electrode, or a transmissive electrode. The material for forming the first electrode may be, for example, indium tin oxide (ITO), indium zinc oxide (IZO), tin oxide (SnO₂), and zinc oxide (ZnO). In one or more embodiments, magnesium (Mg), aluminum (Al), aluminum-lithium (Al—Li), calcium (Ca), magnesium-indium (Mg—In), or magnesium-silver (Mg—Ag) may be used as the material for forming the first electrode.

The first electrode 11 may have a single-layered structure or a multi-layered structure including two or more layers. For example, the first electrode 11 may have a three-layered structure of ITO/Ag/ITO, but the structure of the first electrode 11 is not limited thereto.

The organic layer 15 is disposed on the first electrode 11.

The organic layer 15 may include a hole transport region, an emission layer, and an electron transport region.

The hole transport region may be disposed between the first electrode 11 and the emission layer.

The hole transport region may include at least one of a hole injection layer, a hole transport layer, an electron blocking layer, or a buffer layer. The hole transport layer may be a single layer or may include two or more layers.

The hole transport region may include only either a hole injection layer or a hole transport layer. In some embodiments, the hole transport region may have a stacked structure of hole injection layer/hole transport layer, a stacked structure of hole injection layer/hole transport layer/electron blocking layer, a stacked structure of hole transport layer/electron blocking layer, a stacked structure of hole injection layer/first hole transport layer/second hole transport layer, a stacked structure of hole injection layer/first hole transport layer/second hole transport layer/electron blocking layer, or a stacked structure of first hole transport layer/second hole transport layer/electron blocking layer, wherein for each structure, constituting layers that are sequentially stacked from the first electrode 11.

A hole injection layer may be formed on the first electrode 11 by using one or more suitable methods selected from vacuum deposition, spin coating, casting, or Langmuir-Blodgett (LB) deposition.

When a hole injection layer is formed by vacuum deposition, the deposition conditions may vary according to a compound that is used to form the hole injection layer, and the structure and thermal characteristics of the hole injection layer. For example, the deposition conditions may include a deposition temperature of about 100° C. to about 500° C., a vacuum pressure of about 10⁻⁸ torr to about 10⁻³ torr, and a deposition rate of about 0.01 Å/sec to about 0 Å/sec. However, the deposition conditions are not limited thereto.

When the hole injection layer is formed using spin coating, coating conditions may vary according to the material used to form the hole injection layer, and the structure and thermal properties of the hole injection layer. For example, a coating speed may be from about 2,000 rpm to about 5,000 rpm, and a temperature at which a heat treatment is performed to remove a solvent after coating may be from about 80 t to about 200° C. However, the coating conditions are not limited thereto.

Conditions for forming a hole transport layer and an electron blocking layer may be understood by referring to conditions for forming the hole injection layer.

The hole transport region may include, for example, m-MTDATA, TDATA, 2-TNATA, NPB, β-NPB, TPD, Spiro-TPD, Spiro-NPB, methylated-NPB, TAPC, HMTPD, 4,4′,4″-tris(N-carbazolyl)triphenylamine) (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate) (PANI/PSS), and compounds represented by Formulae 201 to 205:

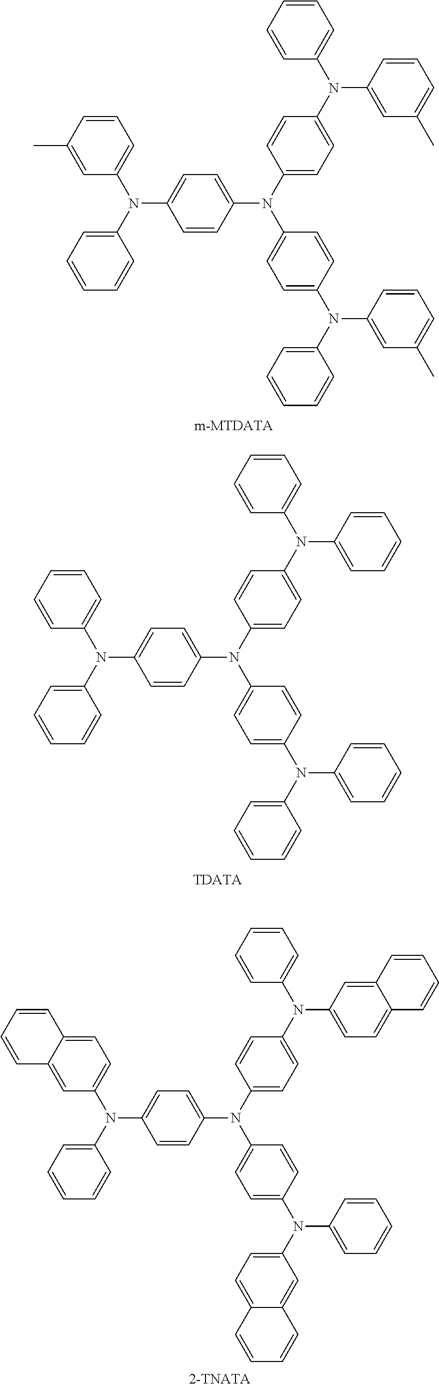

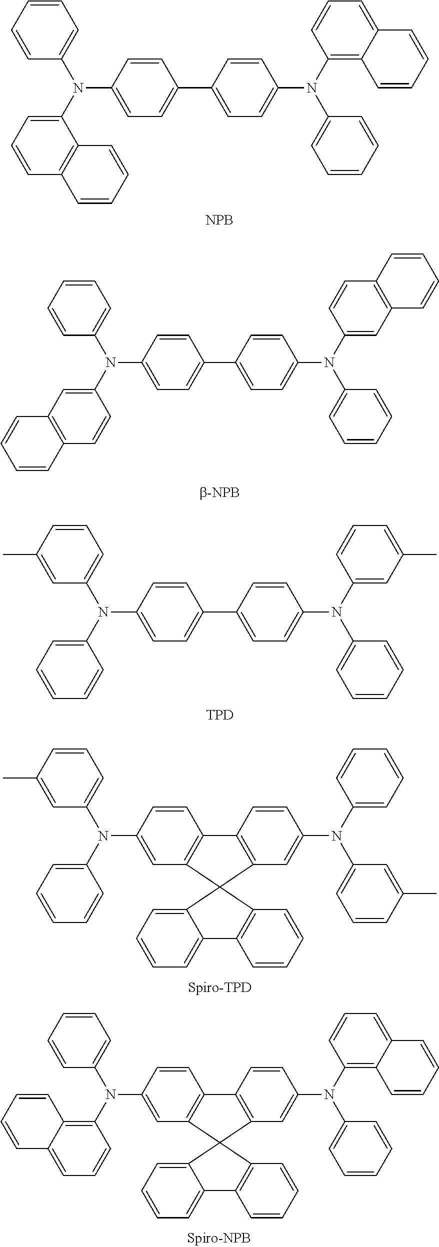

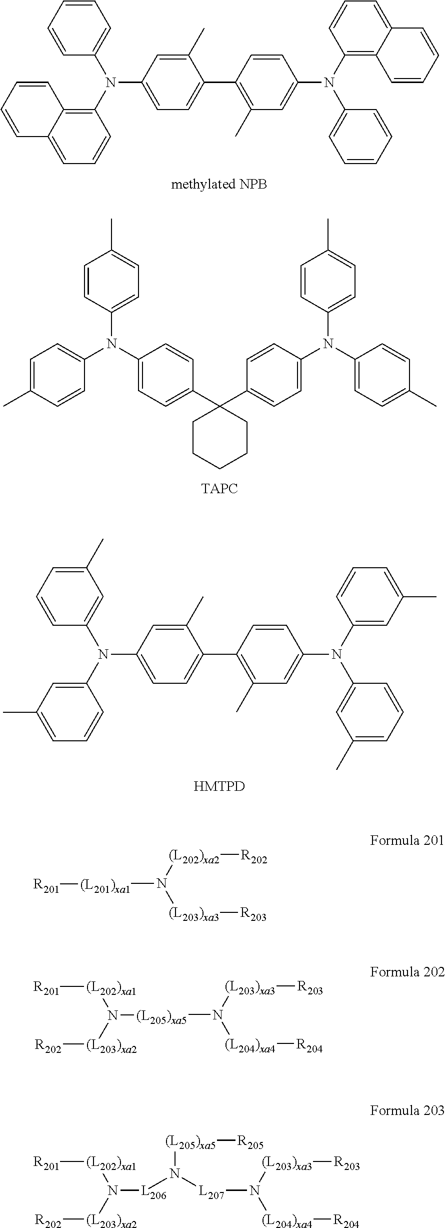

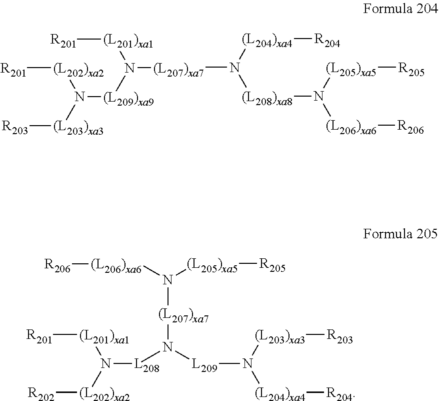

In Formulae 201 to 205, each occurrence of L₂₀₁ to L₂₀₀ may be the same or different, and each independently may be *—O—*′, *—S—*′, a substituted or unsubstituted C₅-C₆₀ carbocyclic group, or a substituted or unsubstituted C₁-C₆₀ heterocyclic group, xa1 to xa9 may each independently be an integer from 0 to 5, R₂₀₁ to R₂₀₆ may each independently be a substituted or unsubstituted C₃-C₁₀ cycloalkyl group, a substituted or unsubstituted heterocycloalkyl group, a substituted or unsubstituted C₃-C₁₀ cycloalkenyl group, a substituted or unsubstituted heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted heteroaryl group, a substituted or unsubstituted monovalent non-aromatic condensed polycyclic group, or a substituted or unsubstituted monovalent non-aromatic condensed heteropolycyclic group, and two adjacent groups from R₂₀₁ to R₂₀₆ may optionally be linked via a single bond, a dimethyl-methylene group, or a diphenyl-methylene group.

For example, each occurrence of L₂₀₁ to L₂₀₉ may each independently be a benzene group, a heptalene group, an indene group, a naphthalene group, an azulene group, a heptalene group, an indacene group, an acenaphthylene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentacene group, a hexacene group, a pentacene group, a rubicene group, a corozen group, an ovalene group, a pyrrole group, an iso-indole group, an indole group, a furan group, a thiophene group, a benzofuran group, a benzothiophene group, a benzocarbazole group, a dibenzocarbazole group, a dibenzofuran group, a dibenzothiophene group, a dibenzothiophene sulfone group, a carbazole group, a dibenzosilole group, an indeno carbazole group, an indolocarbazole group, a benzofurocarbazole group, a benzothienocarbazole group, or a triindolobenzene group, each unsubstituted or substituted with at least one of deuterium, a C₁-C₁₀ alkyl group, a C₁-C₁₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, a tetraphenyl group, or —Si(Q₁₁)(Q₁₂)(Q₁₃).

In Formulae 201 to 205, xa1 to xa9 may each independently be 0, 1, or 2

R₂₀₁ to R₂₀₆ may each independently be a phenyl group, a biphenyl group, a terphenyl group, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, an indeno carbazolyl group, an indolocarbazolyl group, a benzofurocarbazolyl group, or a benzothienocarbazolyl group, each unsubstituted or substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a alkoxy group, a cyclopentyl group, a cyclohexyl group, a cycloheptyl group, a cyclopentenyl group, a cyclohexenyl group, a phenyl group, a biphenyl group, a terphenyl group, a phenyl group substituted with a C₁-C₁₀ alkyl group, a phenyl group substituted with —F, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, —Si(Q₃₁)(Q₃₂)(Q₃₃), or —N(Q₃₁)(Q₃₂).

In one embodiment, the hole transport region may include a carbazole-containing amine-based compound.

In one or more embodiments, the hole transport region may include a carbazole-containing amine compound and a carbazole-free amine compound.

In one or more embodiments, the hole transport region may include a carbazole-free amine compound.

The carbazole-containing amine compound may be, for example, compounds represented by Formula 201, which include a carbazole group and further include at least one of a dibenzofuran group, a dibenzothiophene group, a fluorene group, a spirofluorene group, an indenocarbazole group, an indolocarbazole group, a benzofurocarbazole group, and a benzothieno group.

The carbazole-free amine compound may be, for example, compounds represented by Formula 201, which do not include a carbazole group and include at least one of a dibenzofuran group, a dibenzothiophene group, a fluorene group, a spirofluorene group, an indenocarbazole group, an indolocarbazole group, a benzofurocarbazole group, and a benzothieno group. Alternatively, the carbazole-free amine-based compound may be, for example, compounds represented by Formula 202, which do not include a carbazole group.

In one or more embodiments, the hole transport region may include at least one of the compounds represented by Formulae 201 or 202.

For example, the hole transport region may include at least one of Compounds HT1 to HT21, but embodiments of the present disclosure are not limited thereto:

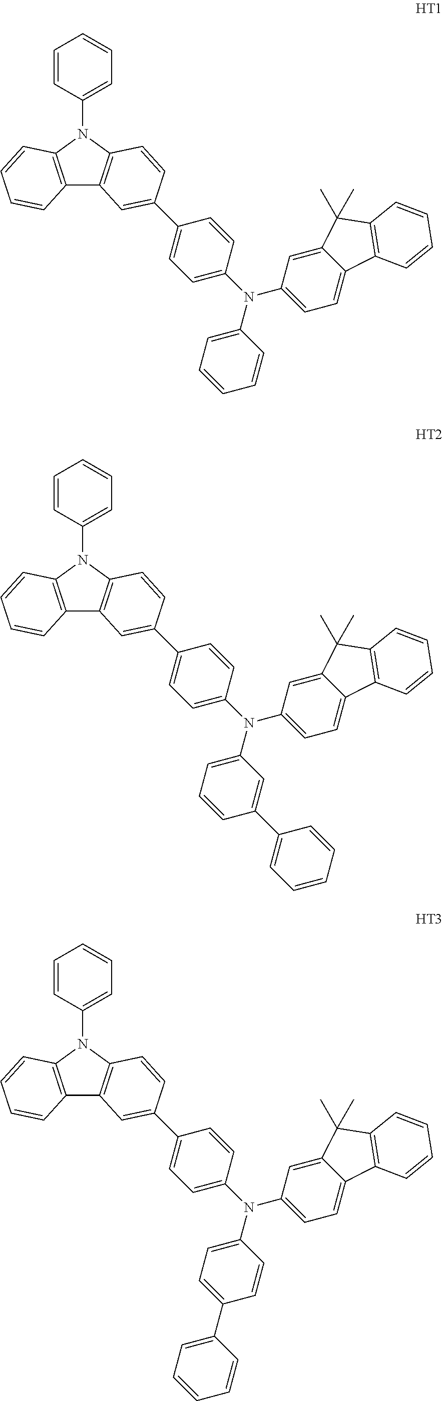 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

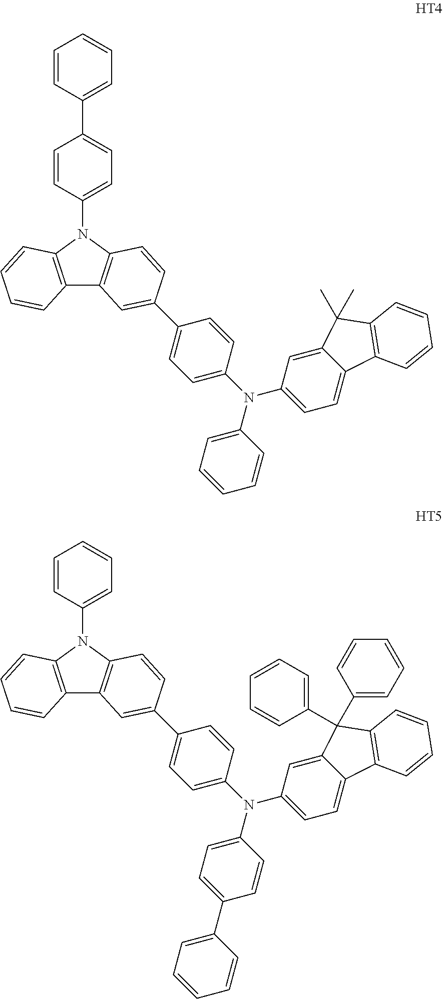 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

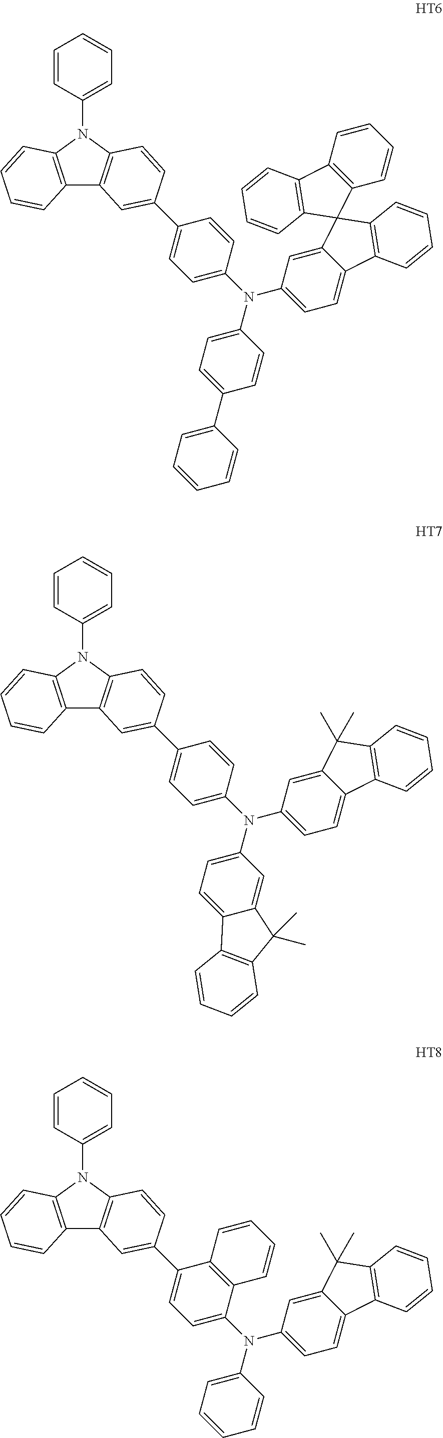 [SMILES: c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3ccccc3)c3ccc(-c4ccc5c(c4)c4ccccc4n5-c4ccccc4)c4ccccc34)cc21]

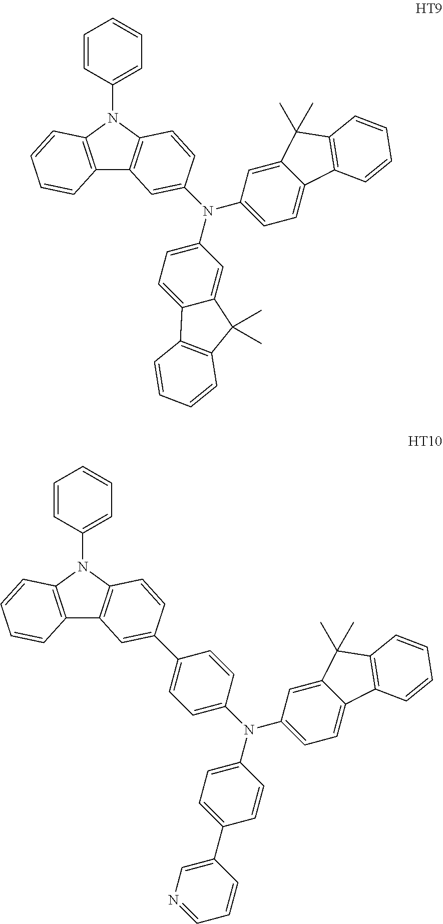 [SMILES: CC1(C)c2ccccc2-c2ccc(N(c3ccc4c(c3)C(C)(C)c3ccccc3-4)c3ccc4c(c3)c3ccccc3n4-c3ccccc3)cc21 ; CC1(C)c2ccccc2-c2ccc(N(c3ccc(-c4cccnc4)cc3)c3ccc(-c4ccc5c(c4)c4ccccc4n5-c4ccccc4)cc3)cc21]

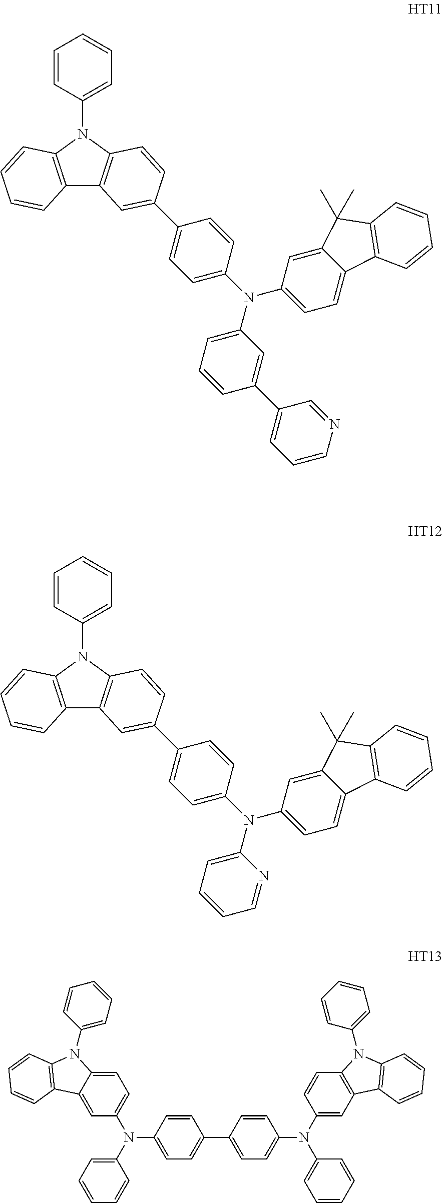 [SMILES: CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

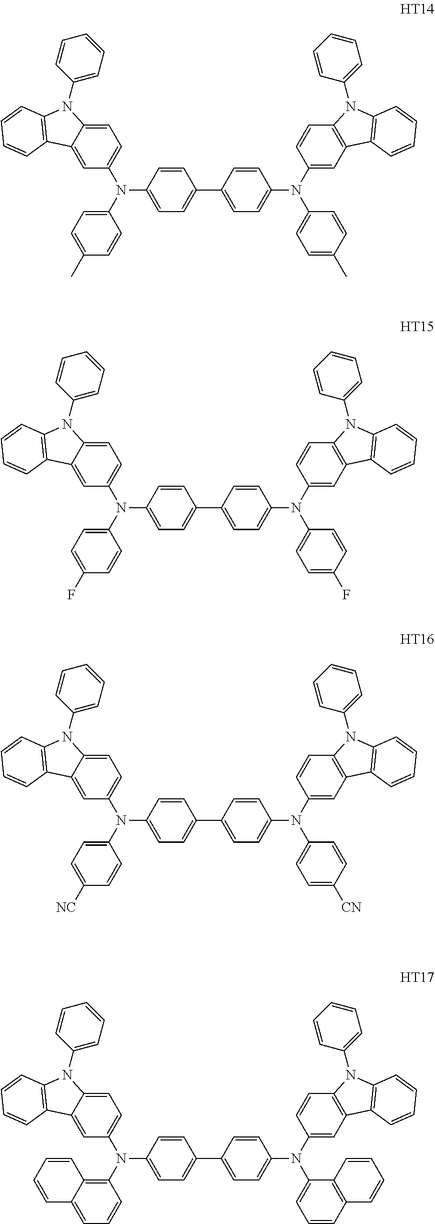 [SMILES: Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1 ; c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1]

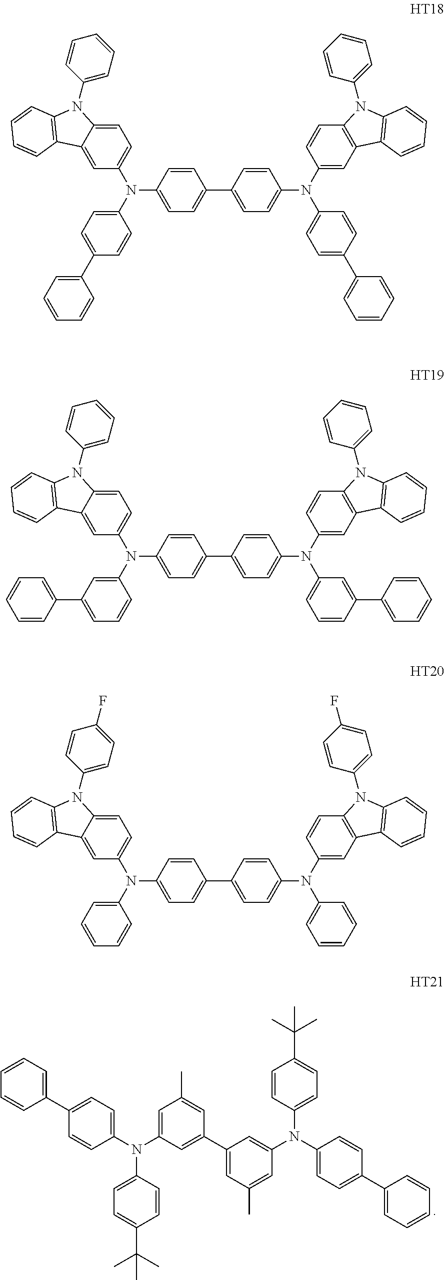 [SMILES: c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1 ; Cc1cc(-c2cc(C)cc(N(c3ccc(-c4ccccc4)cc3)c3ccc(C(C)(C)C)cc3)c2)cc(N(c2ccc(-c3ccccc3)cc2)c2ccc(C(C)(C)C)cc2)c1 ; "."]

A thickness of the hole transport region may be in a range of about 100 Å to about 10,000 Å, for example, about 100 Å to about 1,000 Å. When the hole transport region includes a hole injection layer and a hole transport layer, the thickness of the hole injection layer may be in a range of about 100 Å to about 10,000 Å, and for example, about 100 Å to about 5,000 Å, and the thickness of the hole transport layer may be in a range of about 50 Å to about 5,000 Å, and for example, about 100 Å to about 5,000 Å. When the thicknesses of the hole transport region, the hole injection layer, and the hole transport layer are within these ranges, satisfactory hole transporting characteristics may be obtained without a substantial increase in driving voltage.

The hole transport region may further include, in addition to these materials, a charge-generation material for the improvement of conductive properties. The charge-generation material may be homogeneously or non-homogeneously dispersed in the hole transport region.

The charge-generation material may be, for example, a p-dopant. The p-dopant may be one selected from a quinone derivative, a metal oxide, and a cyano group-containing compound, but embodiments of the present disclosure are not limited thereto. Non-limiting examples of the p-dopant are a quinone derivative, such as tetracyanoquinonedimethane (TCNQ) or 2,3,5,6-tetrafluoro-tetracyano-1,4-benzoquinonedimethane (F4-TCNQ); a metal oxide, such as a tungsten oxide or a molybdenum oxide; and a cyano group-containing compound, such as Compound HT-D1 or Compound HT-D2 below, but are not limited thereto:

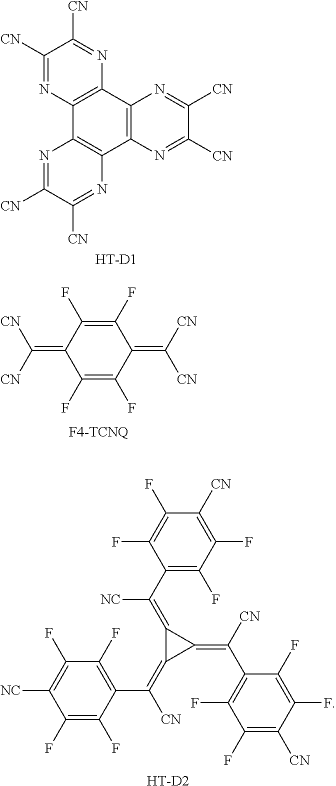

The hole transport region may include a buffer layer.

In some embodiments, the buffer layer may compensate for an optical resonance distance according to a wavelength of light emitted from the emission layer, and thus, efficiency of a formed organic light-emitting device may be improved.

In an embodiment, an emission layer (EML) may be formed on the hole transport region by vacuum deposition, spin coating, casting, LB deposition, or the like. When the emission layer is formed by vacuum deposition or spin coating, the deposition or coating conditions may be similar to those applied in forming the hole injection layer although the deposition or coating conditions may vary according to a compound that is used to form the emission layer.

In other embodiments when the hole transport region includes an electron blocking layer, a material for the electron blocking layer may be materials for the hole transport region described above and materials for a host to be explained later. However, the material for the electron blocking layer is not limited thereto. For example, when the hole transport region includes an electron blocking layer, a material for the electron blocking layer may be mCP or TAPC:

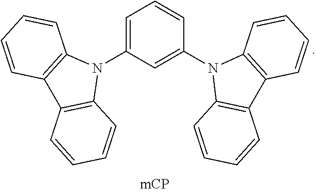 [SMILES: c1cc(-n2c3ccccc3c3ccccc32)cc(-n2c3ccccc3c3ccccc32)c1]

The emission layer may be disposed on the hole transport region.

The emission layer may include a host and a light-emitting material (dopant).

In an embodiment, the emission layer may include a first material, a second material, and a light-emitting material (dopant).

The first material may not include an electron transport moiety, and the second material may include at least one electron transport moiety.

For example, the first material may include at least one pi electron-depleted nitrogen-free cyclic group, and the second material may include at least one pi electron-depleted nitrogen-free cyclic group and at least one electron transport moiety. The electron transport moiety may be a cyano group, a pi electron-depleted nitrogen-containing cyclic group, or a group represented by one of Formulae provided below:

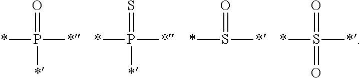

In the Formulae, *, and *′ each indicate a binding site to a neighboring atom.

The “pi electron-depleted nitrogen-containing (C₁-C₃₀) cyclic group” indicates, for example, a group including a C₁-C₃₀ cyclic group having at least one *—N=*′ moiety, and may be, for example, an imidazole group, a pyrazole group, a thiazole group, an isothiazole group, an oxazole group, an isoxazole group, a pyridine group, a pyrazine group, a pyridazine group, a pyrimidine group, an indazole group, a purine group, a quinoline group, an isoquinoline group, a benzoquinoline group, a benzoisoquinolic group, a phthalazine group, a naphthyridine group, a quinoxaline group, a benzoquinoxaline group, a quinazoline group, a cinnoline group, a phenanthridine group, a phenanthroline group, a phenazine group, a benzimidazole group, an iso-benzothiazole group, a benzoxazole group, an isobenzoxazole group, a triazole group, a tetrazole group, an oxadiazole group, a triazine group, a thiadiazole group, an imidazopyridine group, an imidazopyrimidine group, an azaindene group, an azaindole group, an azabenzofuran group, an azabenzothiophene group, an azabenzosilole group, an azafluorene group, an azacarbazole group, an azadibenzofuran group, an azadibenzothiophene group, an azadibenzosilole group, or a condensed cyclic group condensed with at least one of these groups and another cyclic group.

The pi electron-depleted nitrogen-free (C₅-C₃₀) cyclic group may be, for example, a benzene group, a heptalene group, an indene group, a naphthalene group, an azulene group, a heptalene group, an indacene group, an acenaphthylene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentacene group, a hexacene group, a pentaphene group, a rubicen group, a coronen group, an ovalene group, a pyrrole group, an iso-indole group, an indole group, a furan group, a thiophene group, a benzofuran group, a benzothiophene group, a benzosilole group, a benzocarbazole group, a dibenzocarbazole group, a dibenzofuran group, a dibenzothiophene group, a dibenzothiophene sulfone group, a carbazole group, a dibenzosilole group, an indeno carbazole group, an indolocarbazole group, a benzofurocarbazole group, a benzothienocarbazole group, a benzosilolocarbazole group, a triindolobenzene group, an acridine group, or a dihydroacridine group, and may have, for example, 5 to 30 carbon atoms, but embodiments of the present disclosure are not limited thereto.

In one embodiment, the first material may include at least one of a compound represented by Formula H-1(1), a compound represented by Formula H-1(2), and a compound represented by Formula H-1(3):

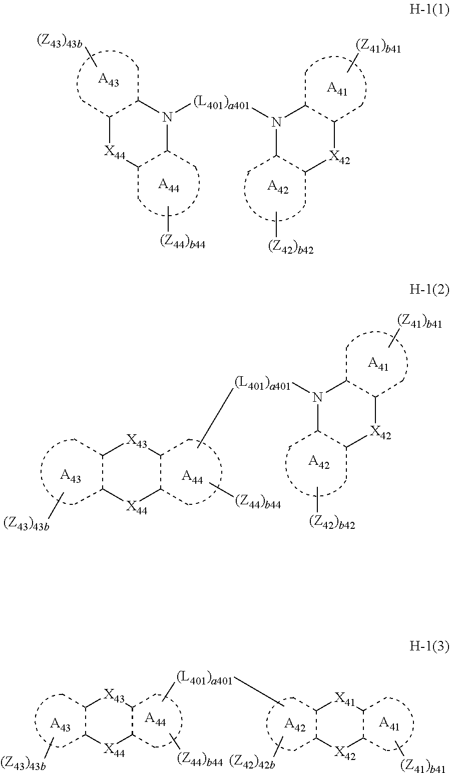

Rings A₄₁ to A₄₄ in Formulae H-1(1) to H-1(3) may each independently be a benzene group, a naphthalene group, an indene group, an indole group, a benzofuran group, a benzothiophene group, a benzosilole group, a fluorene group, a carbazole group, a dibenzofuran group, a dibenzothiophene group, or a dibenzosilole group.

For example, rings A₄₁ to A₄₄ may each independently be a benzene group, a fluorene group, a carbazole group, a dibenzofuran group, a dibenzothiophene group, or a dibenzosilole group, at least one of rings A₄₁ and A₄₂ may be a benzene group, and at least one of rings A₄₃ and A₄₄ may be a benzene group.

In Formulae H-1(1) to H-1(3), X₄₁ may be N-[(L₄₁₁)_{c411}-Z₄₁₁], C(Z₄₁₅)(Z₄₁₆), O, or S, X₄₂ may be a single bond, N-[(L₄₁₂)_{c412}-Z₄₁₂], C(Z₄₁₇)(Z₄₁₈), O, or S, X₄₃ may be N-[(L₄₁₃)_{c413}-Z₄₁₃], C(Z₄₁₉)(Z₄₂₀), O, or S, and X₄₄ may be a single bond, N-[(L₄₁₄)_{c414}-Z₄₁₄], C(Z₄₂₁)(Z₄₂₂), O, or S.

Each occurrence of L₄₀₁ and L₄₁₁ to L₄₁₄ are the same or different, and may each independently be: a single bond; or a pi electron-depleted nitrogen-free cyclic group, unsubstituted or substituted with at least one of deuterium, a C₁-C₁₀ alkyl group, a C₁-C₁₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, a tetraphenyl group, or —Si(Q₄₀₁)(Q₄₀₂)(Q₄₀₃) (for example, a benzene group, a heptalene group, an indene group, a naphthalene group, an azulene group, a heptalene group, an indacene group, an acenaphthylene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentacene group, a hexacene group, a pentacene group, a rubicene group, a corozen group, an ovalene group, a pyrrole group, an isoindole group, an indole group, a furan group, a thiophene group, a benzofuran group, a benzothiophene group, a benzosilole group, a benzocarbazole group, a dibenzocarbazole group, a dibenzofuran group, a dibenzothiophene group, a dibenzothiophene sulfone group, a carbazole group, a dibenzosilole group, an indenocarbazole group, an indolocarbazole group, a benzofurocarbazole group, a benzothienocarbazole group, a benzosilolocarbazole group, a triindolobenzene group, an acridine group, or a dihydroacridine group, each unsubstituted or substituted with deuterium, a C₁-C₁₀ alkyl group, a C₁-C₁₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, a tetraphenyl group, or —Si(Q₄₀₁)(Q₄₀₂)(Q₄₀₃)).

a401 and c411 to c414 respectively indicate the number of L₄₀₁ groups and L₄₁₁ groups to L₄₁₄ groups, and may each independently be an integer from 1 to 10, wherein, when a401 is two or more, two or more groups L₄₀₁ may be identical to or different from each other, when c411 is two or more, two or more groups L₄₁₁ may be identical to or different from each other, when c412 is two or more, two or more groups L₄₁₂ may be identical to or different from each other, when c413 is two or more, two or more groups L₄₁₃ may be identical to or different from each other, and when c414 is two or more, two or more groups L₄₁₄ may be identical to or different from each other. For example, a401 and c411 to c414 may each independently be 1, 2, or 3.

Each occurrence of Z₄₁ to Z₄₄ and Z₄₁₁ to Z₄₂₂ are the same or different, and may each independently be: hydrogen, deuterium, a C₁-C₁₀ alkyl group, and a C₁-C₁₀ alkoxy group; or a pi electron-depleted nitrogen-free cyclic group, unsubstituted or substituted with at least one selected from deuterium, a C₁-C₁₀ alkyl group, a C₁-C₁₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, a tetraphenyl group, and —Si(Q₄₀₁)(Q₄₀₂)(Q₄₀₃) (for example, a phenyl group, a biphenyl group, a terphenyl group, a tetraphenyl group, a naphthyl group, a fluorenyl group, a spiro-bifluorenyl group, a benzofluorenyl group, a dibenzofluorenyl group, a phenanthrenyl group, an anthracenyl group, a triphenylenyl group, a pyrenyl group, a chrysenyl group, a pyrrolyl group, an isoindolyl group, an indolyl group, a furanyl group, a thiophenyl group, a benzofuranyl group, a benzothiophenyl group, a benzosilolyl group, a benzocarbazolyl group, a dibenzocarbazolyl group, a dibenzofuranyl group, a dibenzothiophenyl group, a carbazolyl group, a dibenzosilolyl group, an indenocarbazolyl group, an indolocarbazolyl group, a benzofurocarbazolyl group, a benzothienocarbazolyl group, a benzosilolocarbazolyl group, an acridinyl group, or a dihydroacridinyl group, each unsubstituted or substituted with at least one of deuterium, a C₁-C₁₀ alkyl group, a C₁-C₁₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, a tetraphenyl group, or —Si(a₄₀₁)(Q₄₀₂)(Q₄₀₃)).

b41 to b44 respectively indicate the number of Z₄₁ groups to Z₄₄ groups and may each independently be 1, 2, 3, or 4. When b41 is two or more, two or more groups Z₄₁ may be identical to or different from each other, when b42 is two or more, two or more groups Z₄₂ may be identical to or different from each other, when b43 is two or more, two or more groups Z₄₃ may be identical to or different from each other, and when b44 is two or more, two or more groups Z₄₄ may be identical to or different from each other. For example, b41 to b44 may each independently be 1 or 2, but embodiments of the present disclosure are not limited thereto.

Q₄₀₁ to Q₄₀₃ may each independently be hydrogen, deuterium, a C₁-C₁₀ alkyl group, a C₁-C₁₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, or a tetraphenyl group.

In one embodiment, each occurrence of L₄₀₁ and L₄₁₁ to L₄₁₄ may be the same or different, and may each independently be: a single bond; or a benzene group, a fluorene group, a dibenzofuran group, a dibenzothiophene group, a carbazole group, a dibenzosilole group, an indeno carbazole group, an indolocarbazole group, a benzofurocarbazole group, a benzothienocarbazole group, a benzosilolocarbazole group, an acridine group, or a dihydroacridine group, each unsubstituted or substituted with at least one selected from deuterium, a C₁-C₁₀ alkyl group, a C₁-C₁₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, or a tetraphenyl group, and each occurrence of Z₄₁ to Z₄₄ and Z₄₁₁ to Z₄₂₂ may be the same or different, and may each independently be: hydrogen, deuterium, a C₁-C₁₀ alkyl group, and a C₁-C₁₀ alkoxy group; and a phenyl group, a biphenyl group, a terphenyl group, a tetraphenyl group, a fluorenyl group, a dibenzocarbazolyl group, a dibenzofuranyl group, a dibenzothiophenyl group, a carbazolyl group, a dibenzosilolyl group, an indeno carbazolyl group, an indolocarbazolyl group, a benzofurocarbazolyl group, a benzothienocarbazolyl group, a benzosilolocarbazolyl group, an acridinyl group, or a dihydroacridinyl group, each unsubstituted or substituted with at least one of deuterium, a C₁-C₁₀ alkyl group, a C₁-C₁₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, or a tetraphenyl group, but embodiments of the present disclosure are not limited thereto.

In one embodiment, the first material may include at least one compound from Formulae H1 to H32, but embodiments of the present disclosure are not limited thereto:

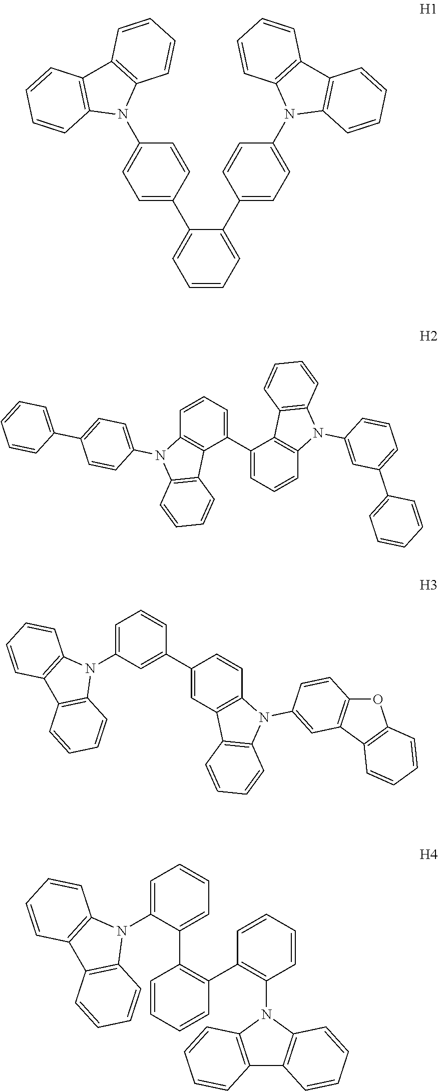 [SMILES: c1ccc(-c2ccc(-n3c4ccccc4c4ccccc43)cc2)c(-c2ccc(-n3c4ccccc4c4ccccc43)cc2)c1 ; c1ccc(-c2ccc(-n3c4ccccc4c4c(-c5cccc6c5c5ccccc5n6-c5cccc(-c6ccccc6)c5)cccc43)cc2)cc1 ; c1cc(-c2ccc3c(c2)c2ccccc2n3-c2ccc3oc4ccccc4c3c2)cc(-n2c3ccccc3c3ccccc32)c1 ; c1ccc(-c2ccccc2-n2c3ccccc3c3ccccc32)c(-c2ccccc2-n2c3ccccc3c3ccccc32)c1]

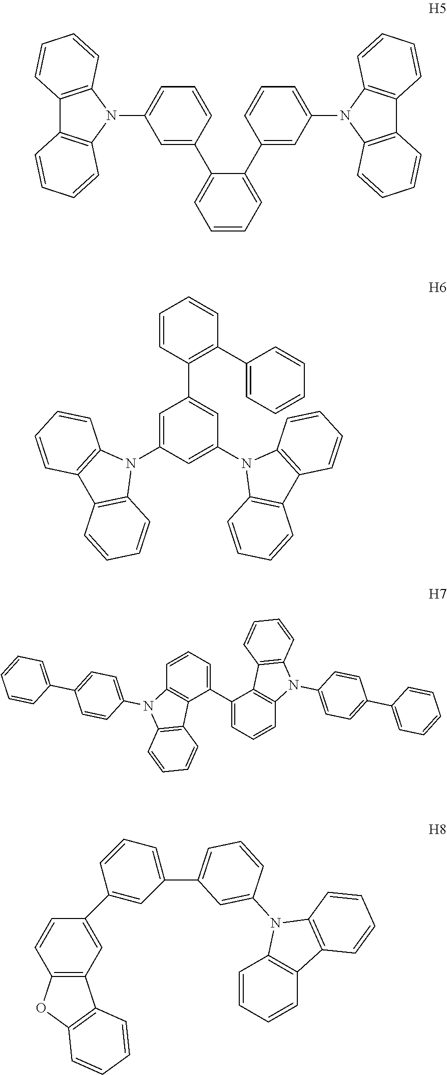 [SMILES: c1cc(-c2ccccc2-c2cccc(-n3c4ccccc4c4ccccc43)c2)cc(-n2c3ccccc3c3ccccc32)c1 ; c1ccc(-c2ccccc2-c2cc(-n3c4ccccc4c4ccccc43)cc(-n3c4ccccc4c4ccccc43)c2)cc1 ; c1ccc(-c2ccc(-n3c4ccccc4c4c(-c5cccc6c5c5ccccc5n6-c5ccc(-c6ccccc6)cc5)cccc43)cc2)cc1 ; c1cc(-c2cccc(-n3c4ccccc4c4ccccc43)c2)cc(-c2ccc3oc4ccccc4c3c2)c1]

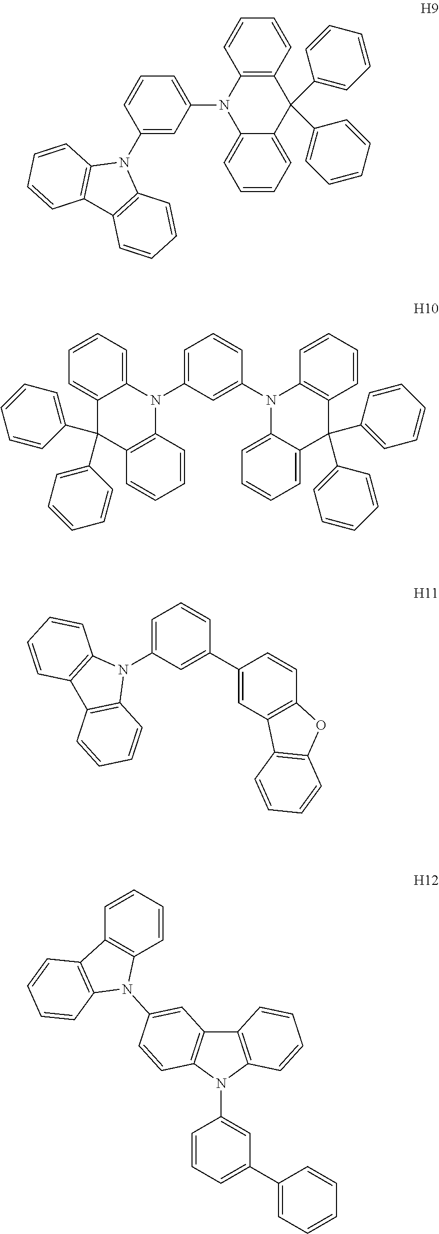 [SMILES: c1ccc(C2(c3ccccc3)c3ccccc3N(c3cccc(-n4c5ccccc5c5ccccc54)c3)c3ccccc32)cc1 ; c1ccc(C2(c3ccccc3)c3ccccc3N(c3cccc(N4c5ccccc5C(c5ccccc5)(c5ccccc5)c5ccccc54)c3)c3ccccc32)cc1 ; c1cc(-c2ccc3oc4ccccc4c3c2)cc(-n2c3ccccc3c3ccccc32)c1 ; c1ccc(-c2cccc(-n3c4ccccc4c4cc(-n5c6ccccc6c6ccccc65)ccc43)c2)cc1]

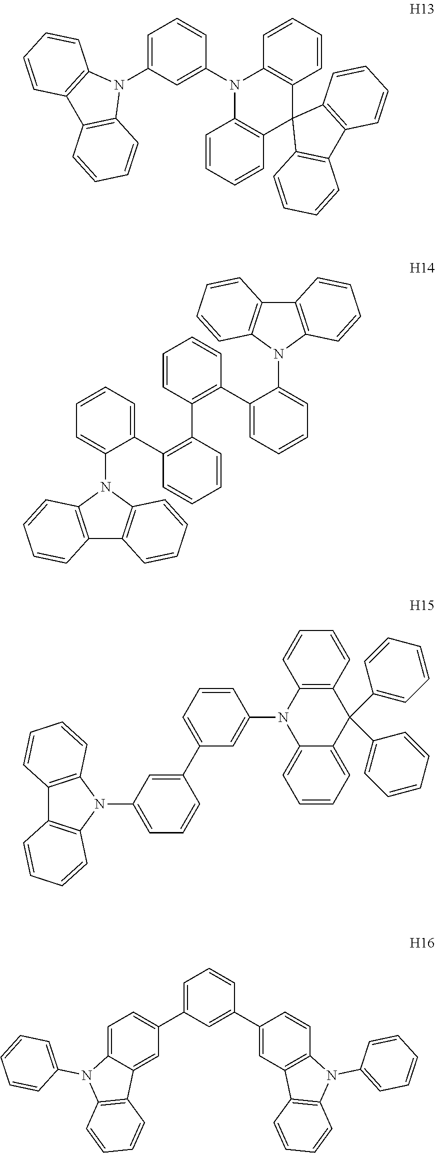 [SMILES: c1cc(N2c3ccccc3C3(c4ccccc4-c4ccccc43)c3ccccc32)cc(-n2c3ccccc3c3ccccc32)c1 ; c1ccc(-c2ccccc2-n2c3ccccc3c3ccccc32)c(-c2ccccc2-c2ccccc2-n2c3ccccc3c3ccccc32)c1 ; c1ccc(C2(c3ccccc3)c3ccccc3N(c3cccc(-c4cccc(-n5c6ccccc6c6ccccc65)c4)c3)c3ccccc32)cc1 ; c1ccc(-n2c3ccccc3c3cc(-c4cccc(-c5ccc6c(c5)c5ccccc5n6-c5ccccc5)c4)ccc32)cc1]

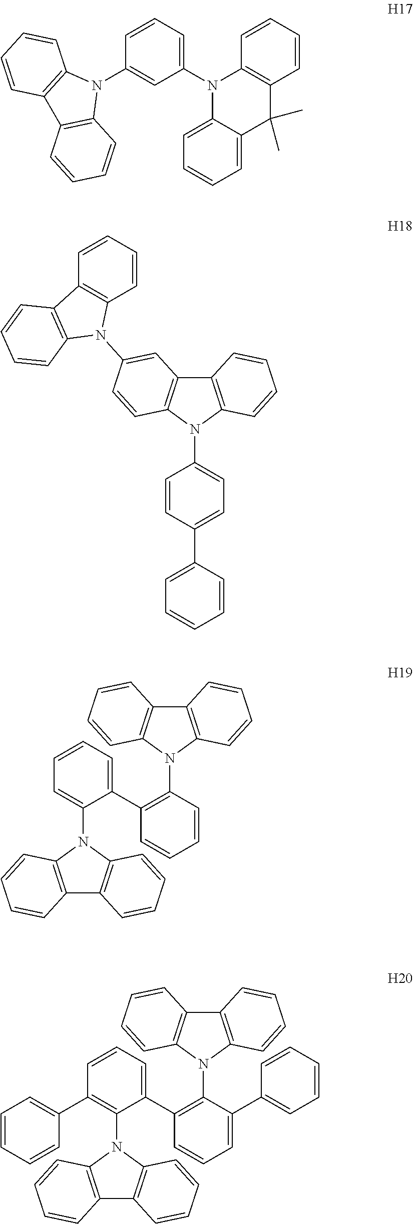 [SMILES: CC1(C)c2ccccc2N(c2cccc(-n3c4ccccc4c4ccccc43)c2)c2ccccc21 ; c1ccc(-c2ccc(-n3c4ccccc4c4cc(-n5c6ccccc6c6ccccc65)ccc43)cc2)cc1 ; c1ccc(-n2c3ccccc3c3ccccc32)c(-c2ccccc2-n2c3ccccc3c3ccccc32)c1 ; c1ccc(-c2cccc(-c3cccc(-c4ccccc4)c3-n3c4ccccc4c4ccccc43)c2-n2c3ccccc3c3ccccc32)cc1]

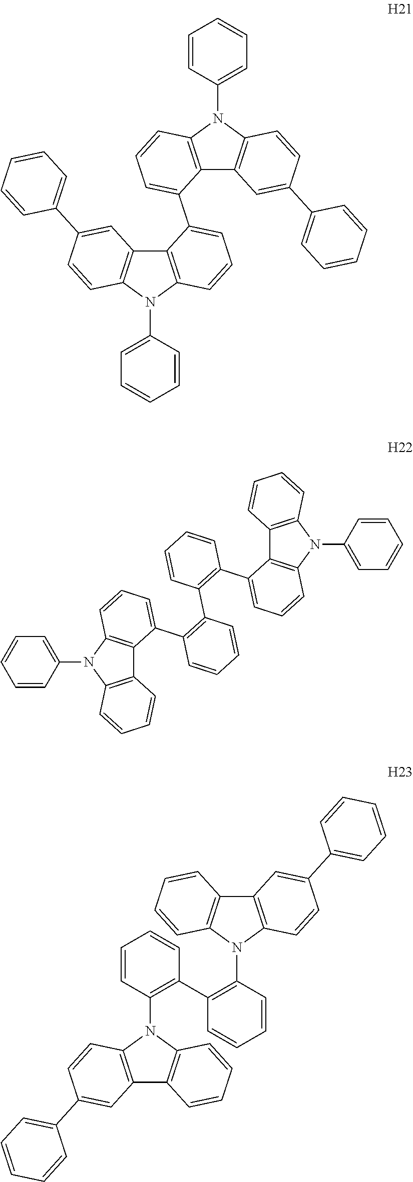 [SMILES: c1ccc(-c2ccc3c(c2)c2c(-c4cccc5c4c4cc(-c6ccccc6)ccc4n5-c4ccccc4)cccc2n3-c2ccccc2)cc1 ; c1ccc(-n2c3ccccc3c3c(-c4ccccc4-c4ccccc4-c4cccc5c4c4ccccc4n5-c4ccccc4)cccc32)cc1 ; c1ccc(-c2ccc3c(c2)c2ccccc2n3-c2ccccc2-c2ccccc2-n2c3ccccc3c3cc(-c4ccccc4)ccc32)cc1]

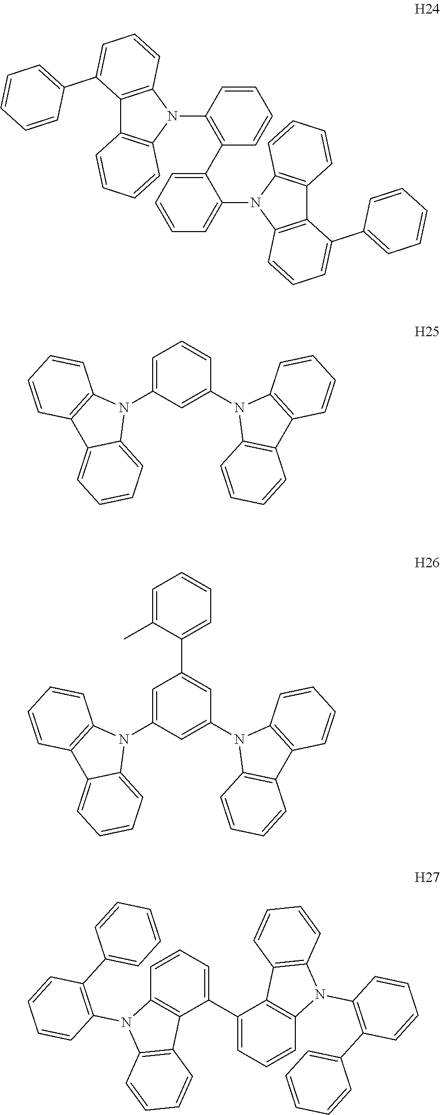 [SMILES: c1ccc(-c2cccc3c2c2ccccc2n3-c2ccccc2-c2ccccc2-n2c3ccccc3c3c(-c4ccccc4)cccc32)cc1 ; c1cc(-n2c3ccccc3c3ccccc32)cc(-n2c3ccccc3c3ccccc32)c1 ; Cc1ccccc1-c1cc(-n2c3ccccc3c3ccccc32)cc(-n2c3ccccc3c3ccccc32)c1 ; c1ccc(-c2ccccc2-n2c3ccccc3c3c(-c4cccc5c4c4ccccc4n5-c4ccccc4-c4ccccc4)cccc32)cc1]

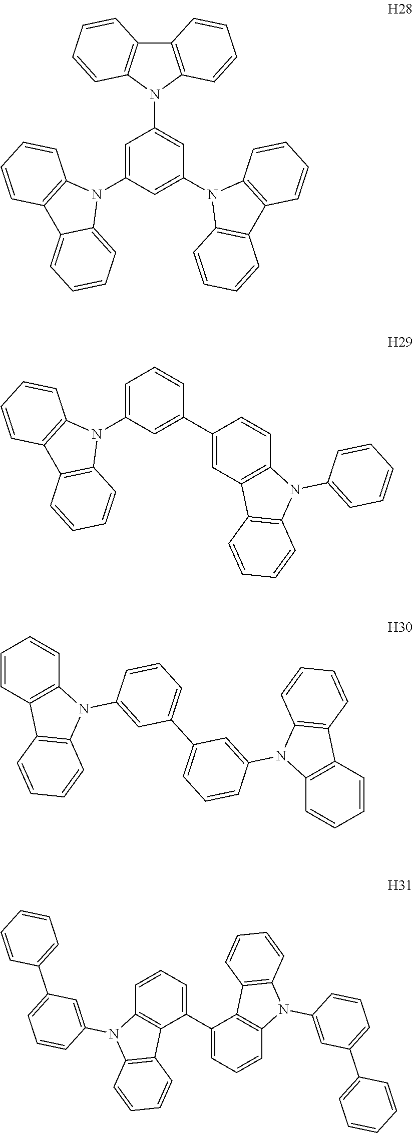 [SMILES: c1ccc2c(c1)c1ccccc1n2-c1cc(-n2c3ccccc3c3ccccc32)cc(-n2c3ccccc3c3ccccc32)c1 ; c1ccc(-n2c3ccccc3c3cc(-c4cccc(-n5c6ccccc6c6ccccc65)c4)ccc32)cc1 ; c1cc(-c2cccc(-n3c4ccccc4c4ccccc43)c2)cc(-n2c3ccccc3c3ccccc32)c1 ; c1ccc(-c2cccc(-n3c4ccccc4c4c(-c5cccc6c5c5ccccc5n6-c5cccc(-c6ccccc6)c5)cccc43)c2)cc1]

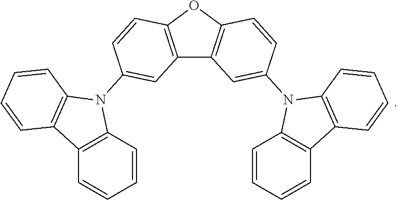 [SMILES: c1ccc2c(c1)c1ccccc1n2-c1ccc2oc3ccc(-n4c5ccccc5c5ccccc54)cc3c2c1]

In one embodiment, the second material may include at least one cyano group.

In one or more embodiments, the second material may include at least one cyano group and at least one carbazole ring.

In one or more embodiments, the second material may include a compound represented by Formula E-1:

[Ar₃₀₁]_{xb11}-[(L₃₀₁)_{xb1}-R₃₀₁]_{xb21}. Formula E-1

In Formula E-1, Ar₃₀₁ may be a substituted or unsubstituted C₅-C₆₀ carbocyclic group or a substituted or unsubstituted C₁-C₆₀ heterocyclic group, and xb11 may be 1, 2, or 3.

Each occurrence of L₃₀₁ may be the same or different, and may be a single bond, a group represented by one of Formulae provided below, a substituted or unsubstituted C₅-C₆₀ carbocyclic group, or a substituted or unsubstituted C₁-C₆₀ heterocyclic group, and xb1 may be an integer from 1 to 5. In the following Formulae, *, *′, and *″ each indicate a binding site to a neighboring atom:

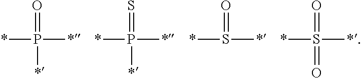

Each occurrence of R₃₀₁ may be the same or different, and may be hydrogen, deuterium, —F, —Cl, —Br, —I, a hydroxyl group, a cyano group, a nitro group, an amidino group, a hydrazino group, a hydrazono group, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —Si(Q₃₀₁)(Q₃₀₂)(Q₃₀₃), —N(Q₃₀₁)(Q₃₀₂), —B(Q₃₀₁)(Q₃₀₂), —C(═O)(Q₃₀₁), —S(═O)₂(Q₃₀₁), —S(═O)(Q₃₀₁), —P(═O)(Q₃₀₁)(Q₃₀₂), or —P(═S)(Q₃₀₁)(Q₃₀₂), and xb21 may be an integer from 1 to 5.

Each occurrence of Q₃₀₁ to Q₃₀₃ may be the same or different, and may each independently be a C₁-C₁₀ alkyl group, a C₁-C₁₀ alkoxy group, a phenyl group, a biphenyl group, a terphenyl group, or a naphthyl group.

In Formula E-1, at least one of Condition 1 to Condition 3 is satisfied. Condition 1: at least one of Ar₃₀₁, L₃₀₁, and R₃₀₁ in Formula E-1 includes independently a pi electron-depleted nitrogen-containing cyclic group; Condition 2: at least one of L₃₀₁(s) in Formula E-1 is independently a group represented by one of Formulae provided below:

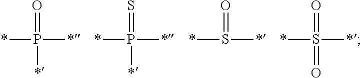

or Condition 3: at least one of R₃₀₁(s) in Formula E-1 is independently a cyano group, —S(═O)₂(Q₃₀₁), —S(═O )(Q₃₀₁), —P(═O)(Q₃₀₁)(Q₃₀₂), or —P(═S)(Q₃₀₁)(Q₃₀₂)

In one or more embodiments, the second material may include at least one of a compound represented by Formula E-1 (1), a compound represented by Formula E-1 (2), or a compound represented by Formula E-1 (3):

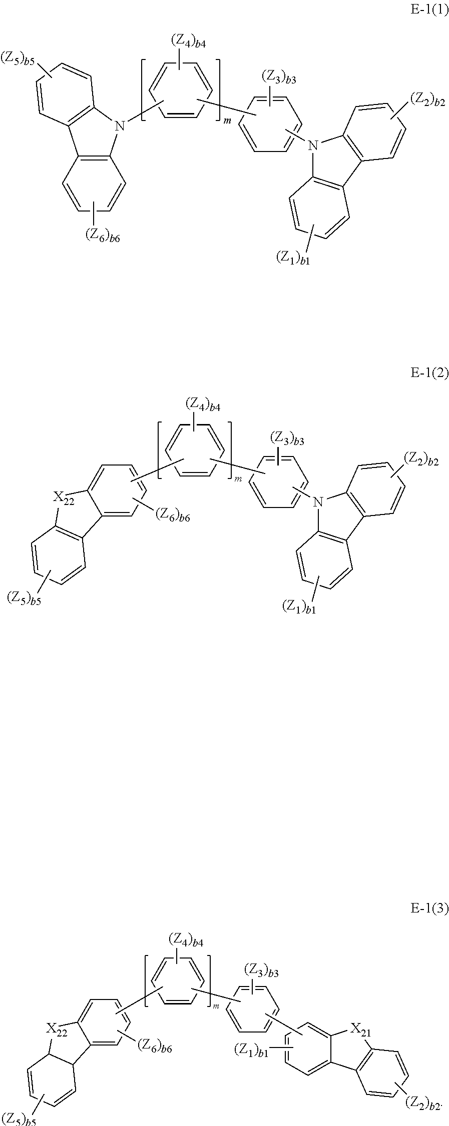

In Formulae E-1 (1) to E-1(3), X₂₁ may be N(Z₇), O, or S, and X₂₂ may be N(Z₈), O, or S.

Each occurrence of Z₁ to Z₈ may be the same or different, and may each independently be: hydrogen, deuterium, or a cyano group (CN); or a C₁-C₂₀ alkyl group, a phenyl group, a biphenyl group, a terphenyl group, a dibenzofuranyl group, or a dibenzothiophenyl group, each unsubstituted or substituted with at least one selected from deuterium, a cyano group, a C₁-C₂₀ alkyl group, a phenyl group, or a biphenyl group.

For example, each occurrence of Z₁ to Z₈ in Formulae E-1 (1) to E-1(3) may be the same or different, and may each independently be: hydrogen, deuterium, or a cyano group; or a C₃-C₁₀ alkyl group, a phenyl group, a biphenyl group, a terphenyl group, a dibenzofuranyl group, or a dibenzothiophenyl group, each unsubstituted or substituted with at least one of deuterium, a cyano group, a C₃-C₁₀ alkyl group, a phenyl group, or a biphenyl group.

In one embodiment, each occurrence of Z₁ to Z₈ in Formulae E-1 (1) to E-1(3) may be the same or different, and may each independently be: hydrogen, deuterium, or a cyano group; or an n-propyl group, an iso-propyl group, an n-butyl group, an isobutyl group, a sec-butyl group, a tert-butyl group, an n-pentyl group, an isopentyl group, a sec-pentyl group, a tert-pentyl group, a phenyl group, a biphenyl group, or a terphenyl group, each unsubstituted or substituted with at least one of deuterium, a cyano group, an n-propyl group, an iso-propyl group, an n-butyl group, an isobutyl group, a sec-butyl group, a tert-butyl group, an n-pentyl group, an isopentyl group, a sec-pentyl group, a tert-pentyl group, a phenyl group, or a biphenyl group.

b1 to b6 in Formulae E-1 (1) to E-1(3) respectively indicate the number of Z₁ groups to Z₆ groups, and may each independently be 1, 2, or 3. When b1 to b6 are each two or more, two or more of the groups Z₁ to the groups Z₆ may each be identical to or different from each other.

In Formulae E-1(1) to E-1(3), at least one of group Z₁ in the number of b1, group Z₂ in the number of b2, group Z₃ in the number of b3, group Z₄ in the number of b4, group Z₅ in the number of b5, and group Z₆ in the number of b6 may be a cyano group. That is, at least one of Z₁ to Z₆ in Formulae E-1(1) to E-1(3) may include at least one cyano group.

For example, the number of cyano groups included in the compound represented by Formula E-1(1), the number of cyano groups included in the compound represented by Formula E-1(2), and the number of cyano groups included in the compound represented by Formula E-1(3) may each independently be 1, 2, or 3, but embodiments of the present disclosure are not limited thereto.

In one embodiment, in Formulae E-1(1) to E-1(3), at least one of group Z₁ in the number of b1 and group Z₂ in the number of b2 may be a cyano group; at least one of group Z₃ in the number of b3 and group Z₄ in the number of b4 may be a cyano group; at least one of group Z₅ in the number of b5 and group Z₆ in the number of b6 may be a cyano group; at least one of group Z₁ in the number of b1 and group Z₂ in the number of b2 may be a cyano group, and at least one of group Z₃ in the number of b3 and group Z₄ in the number of b4 may be a cyano group; at least one of group Z₁ in the number of b1 and group Z₂ in the number of b2 may be a cyano group, and at least one of group Z₅ in the number of b5 and group Z₆ in the number of b6 may be a cyano group; at least one of group Z₃ in the number of b3 and group Z₄ in the number of b4 may be a cyano group, and at least one of group Z₅ in the number of b5 and group Z₆ in the number of b6 may be a cyano group; or at least one of group Z₁ in the number of b1 and group Z₂ in the number of b2 may be a cyano group, at least one of group Z₃ in the number of b3 and group Z₄ in the number of b4 may be a cyano group, and at least one of group Z₅ in the number of b5 and group Z₆ in the number of b6 may be a cyano group.

m in Formulae E-1(1) to E-1(3) may be 0 or 1.

In one embodiment, a group represented by the formula

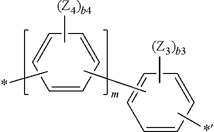

in Formulae E-1(1) to E-1(3) may be one of the groups represented by Formulae PO1 to PO25, PM1 to PM25, PP1 to PP18, MO1 to MO37, MM1 to MM37, MP1 to MP25, OO1 to OO37, OM1 to OM37, OP1 to OP25, O1 to O16, M₁ to M₁₆, or P1 to P9:

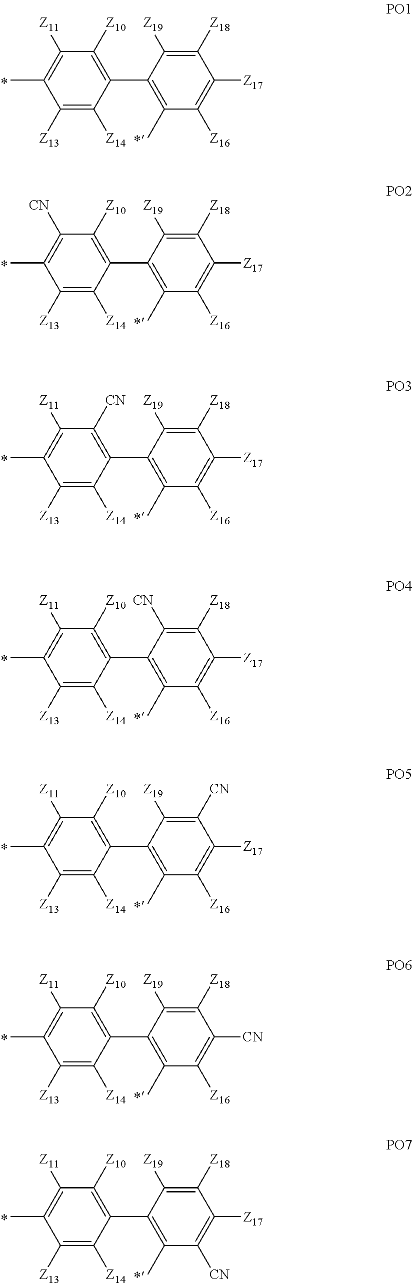

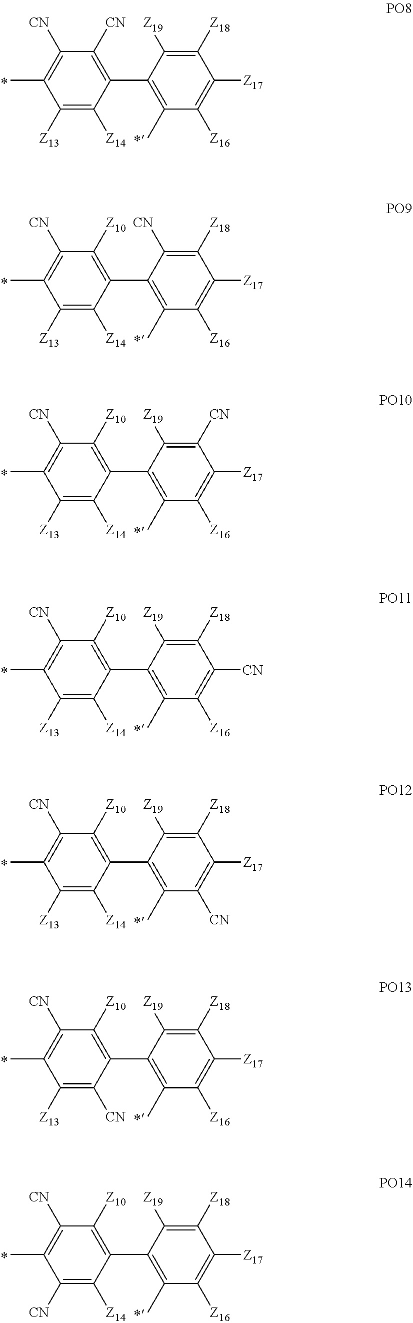

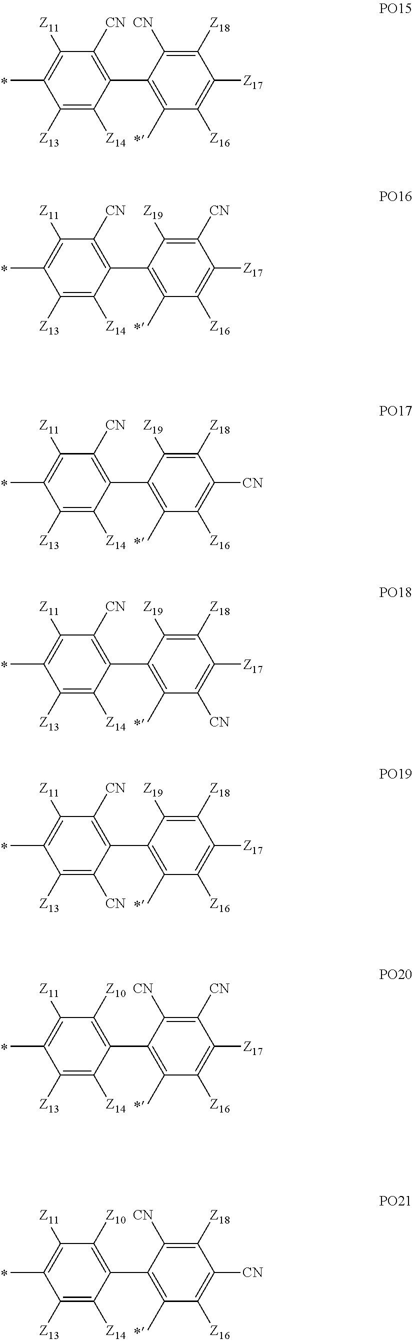

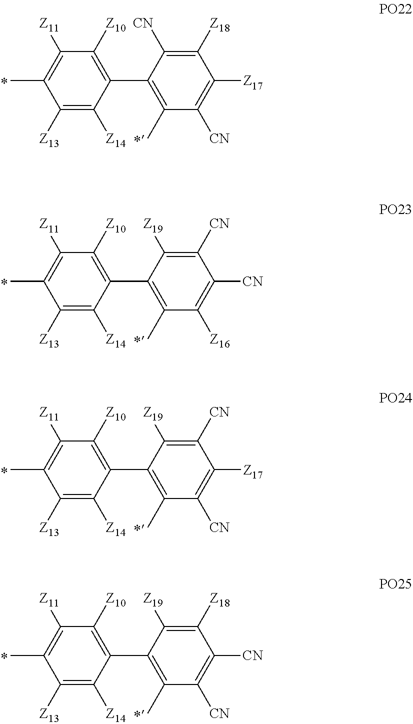

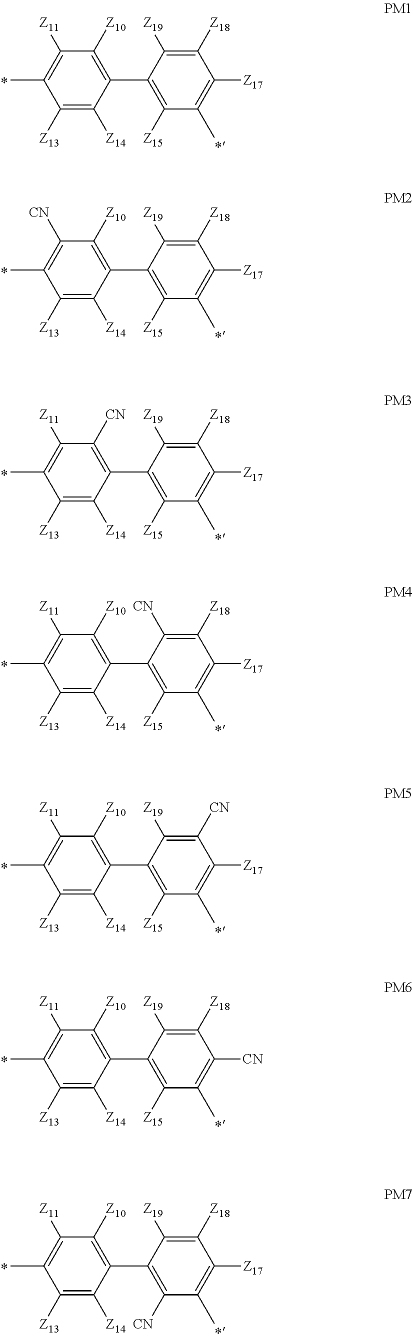

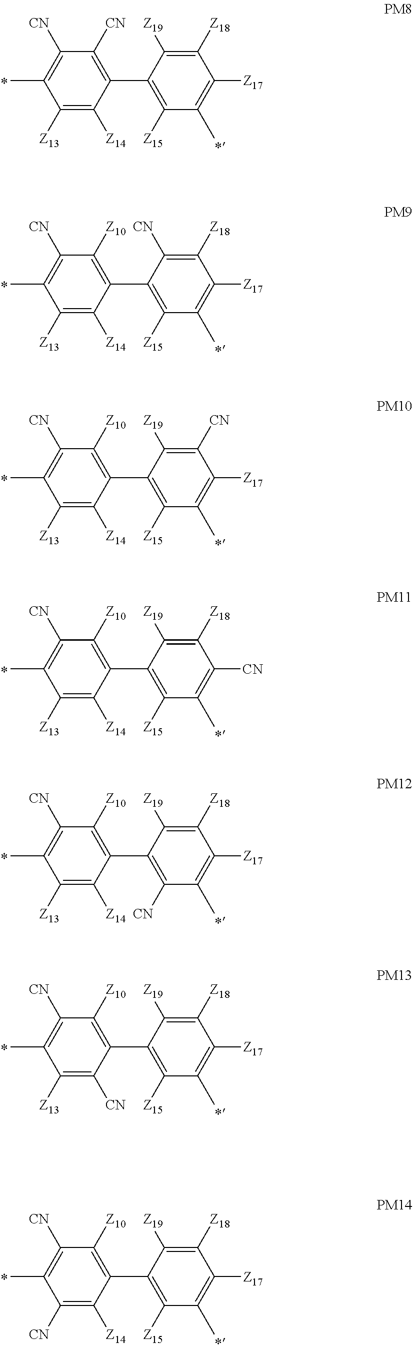

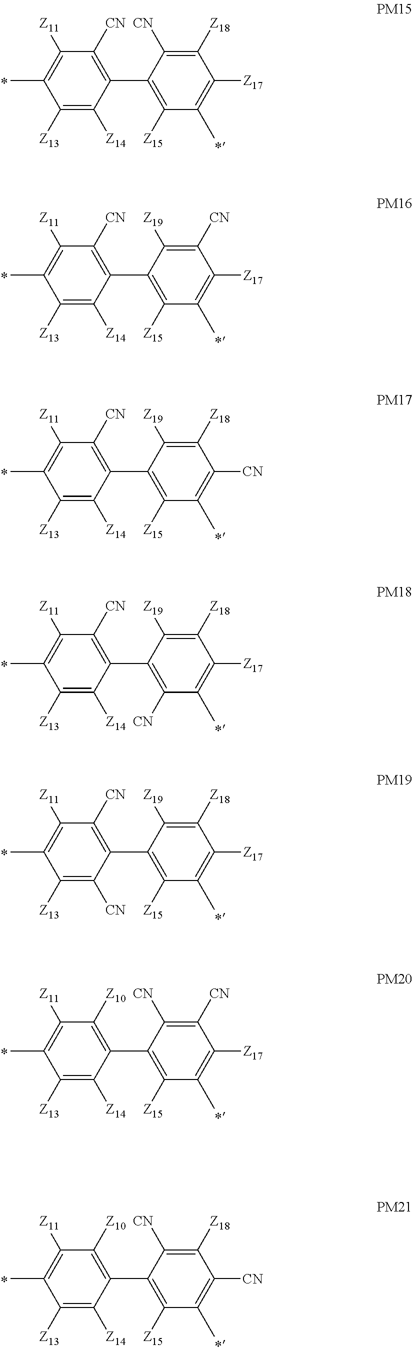

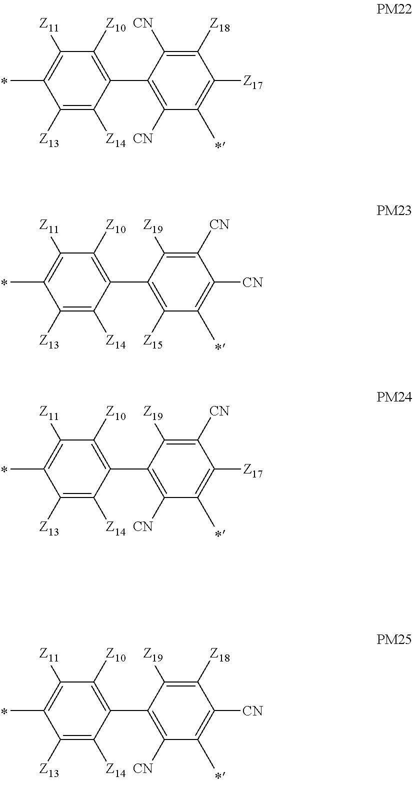

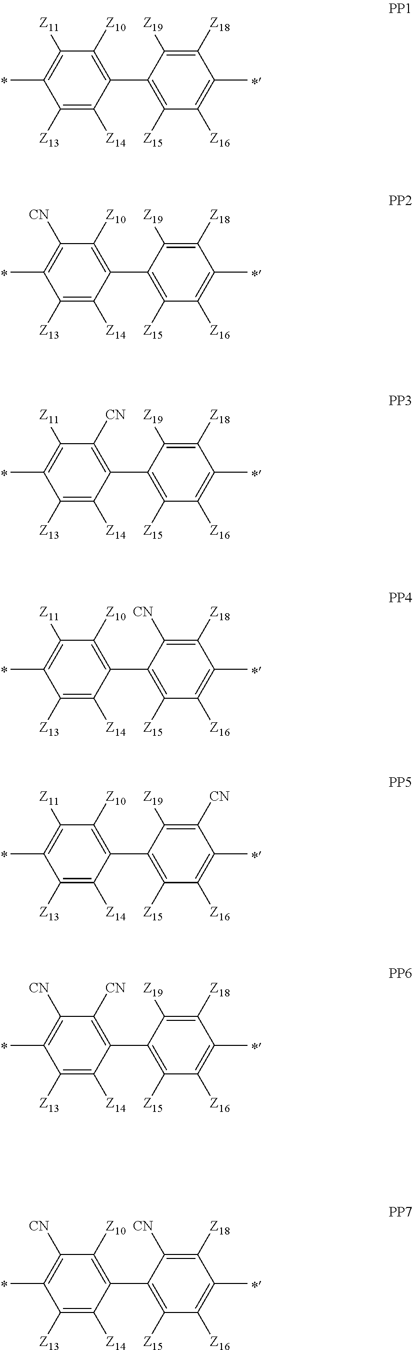

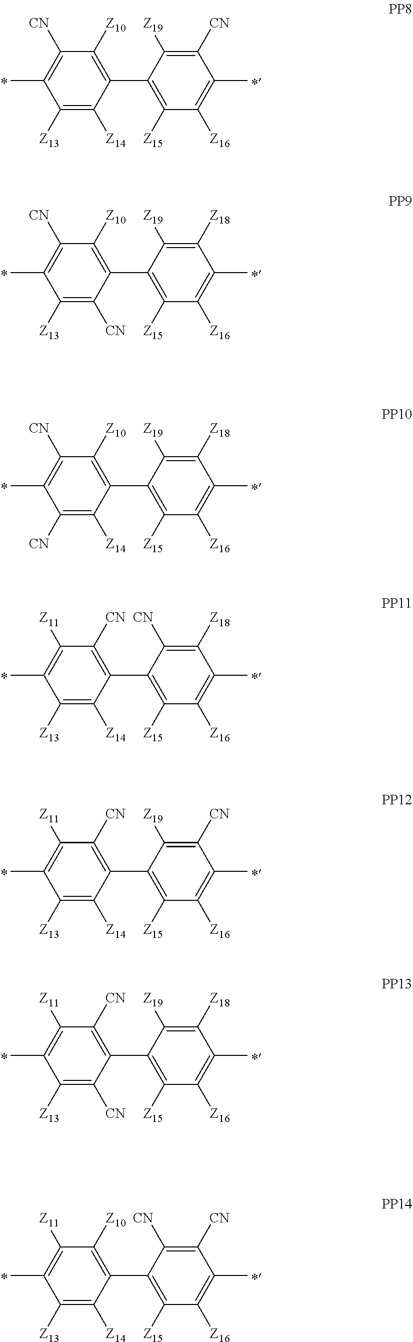

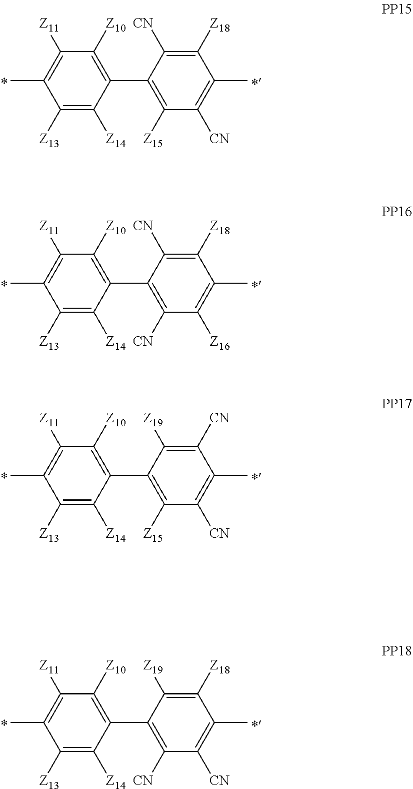

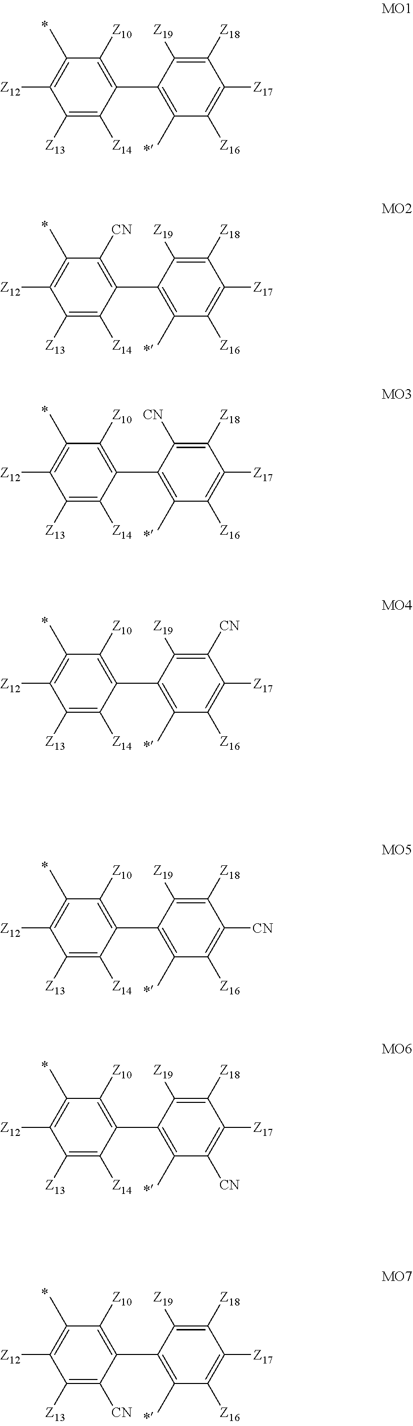

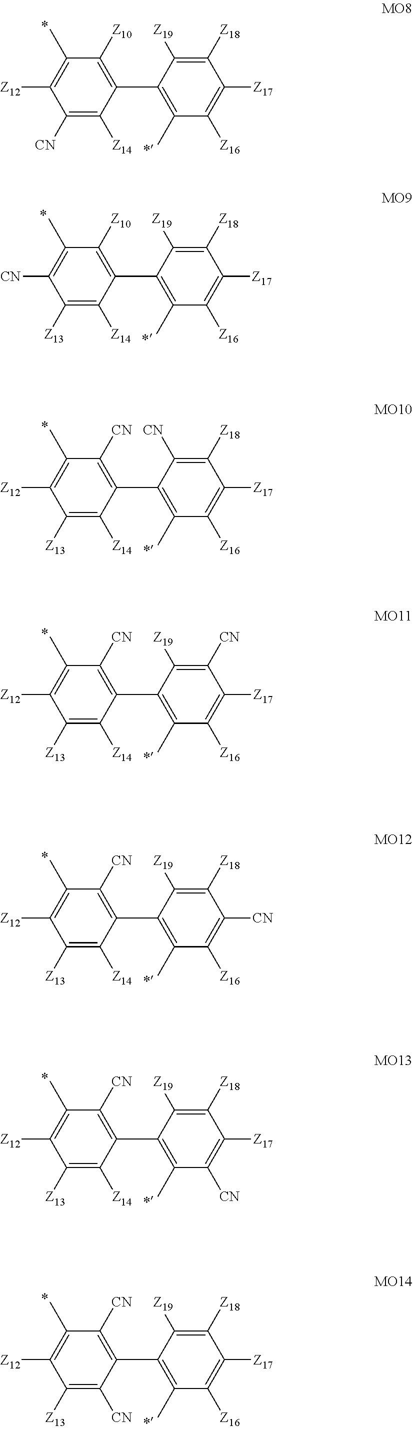

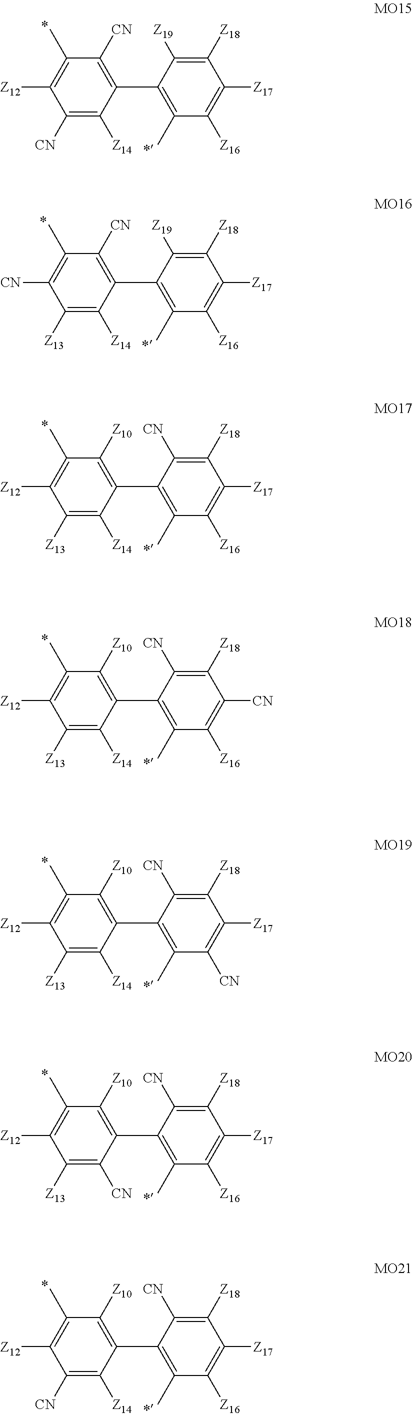

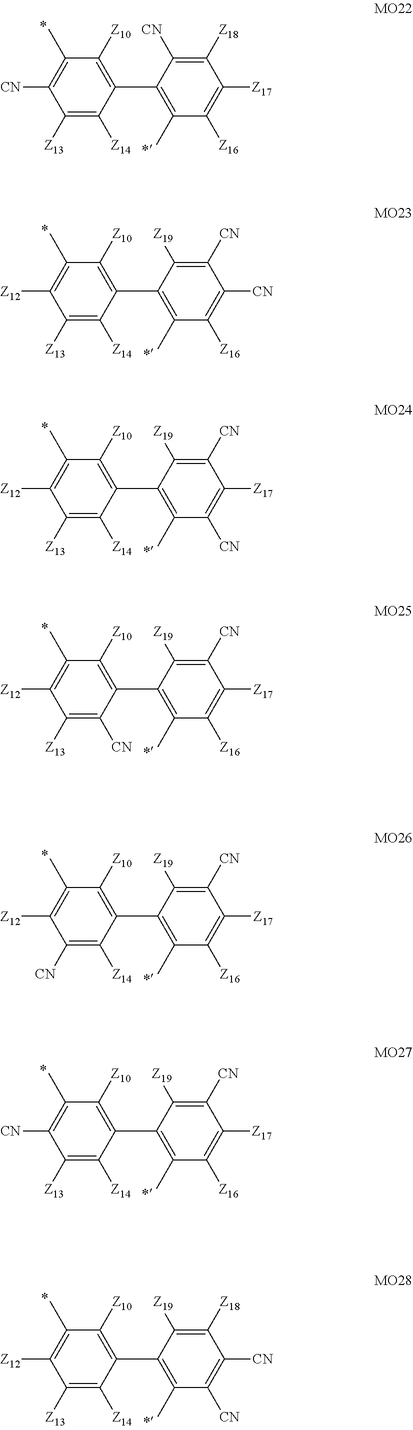

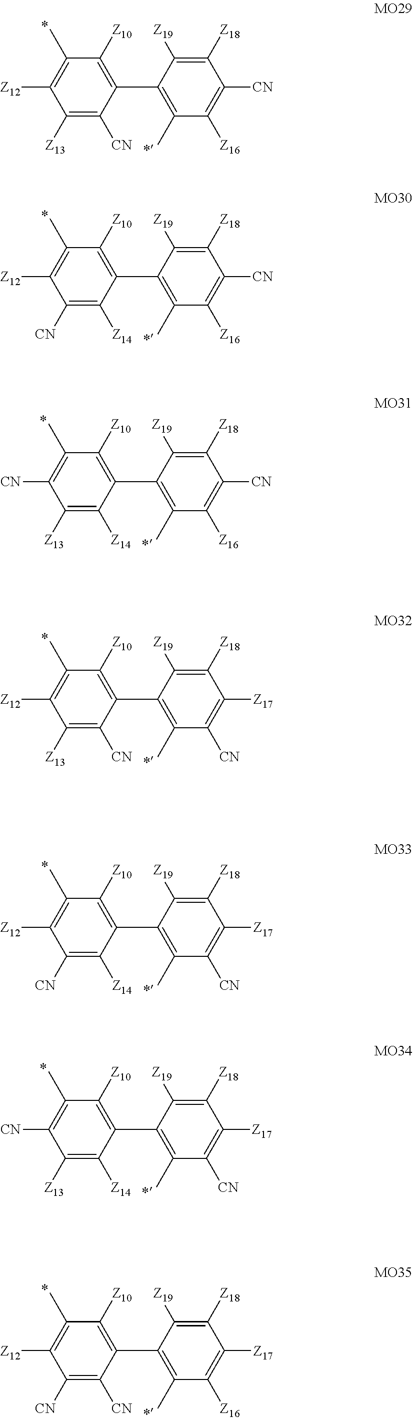

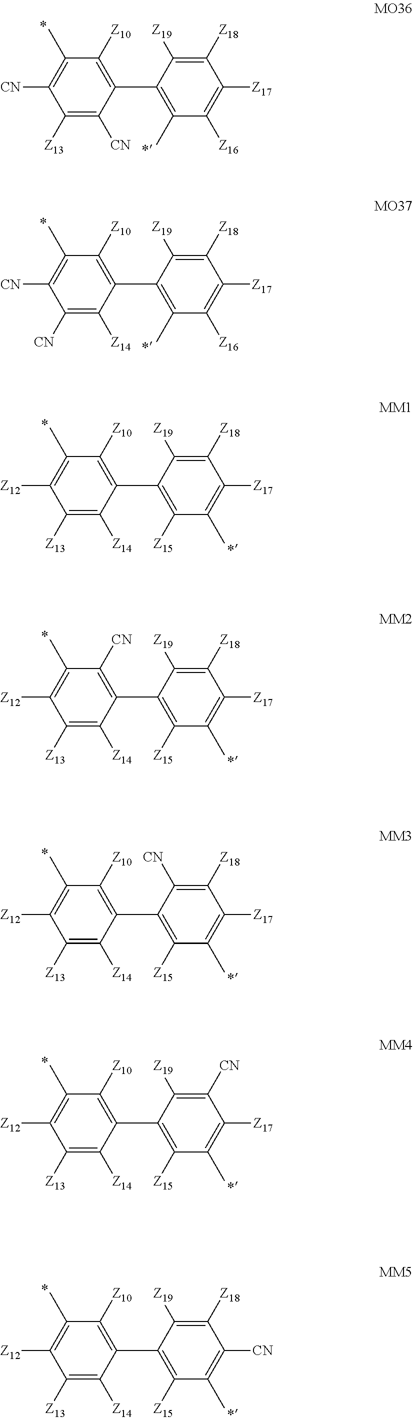

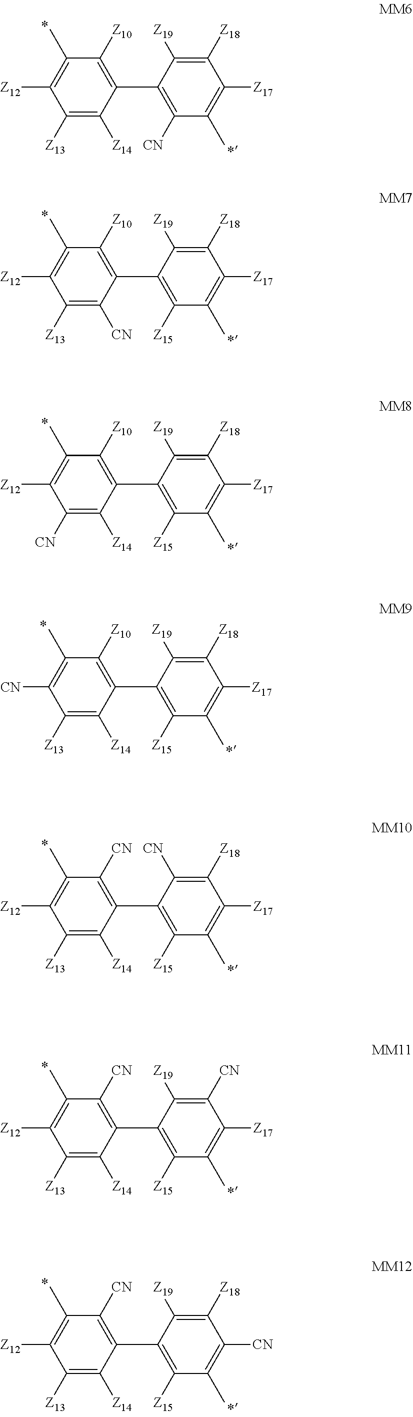

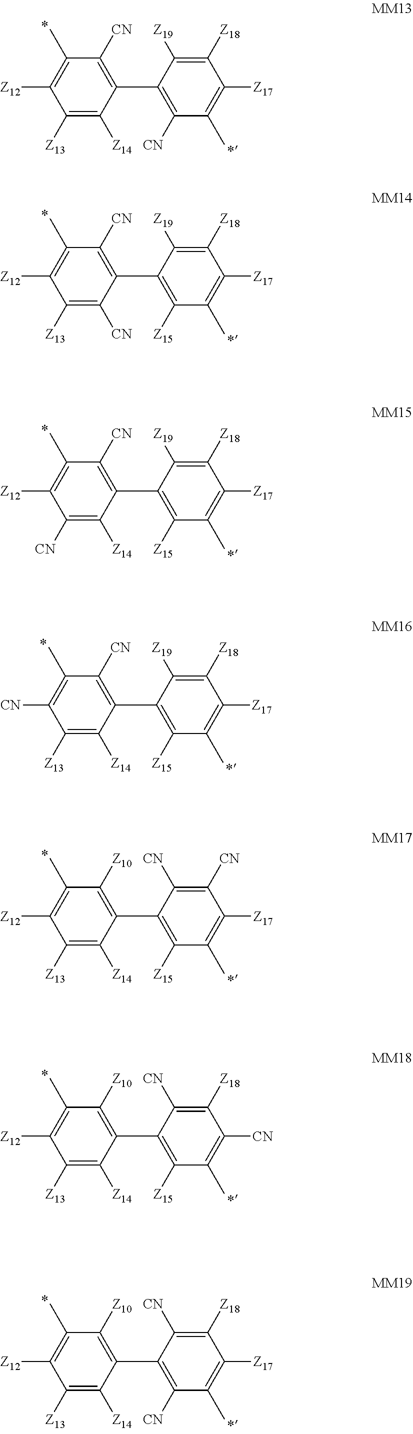

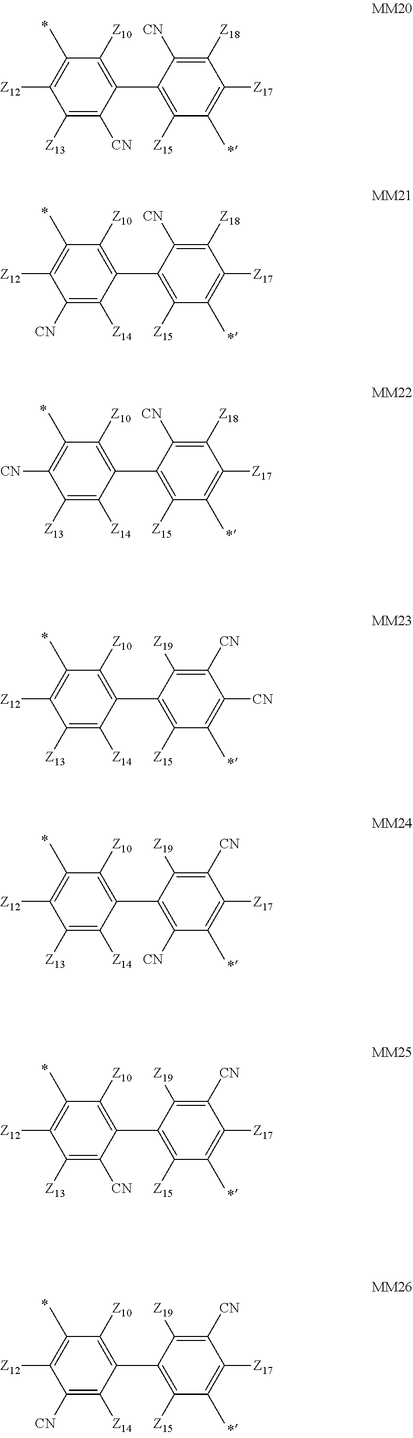

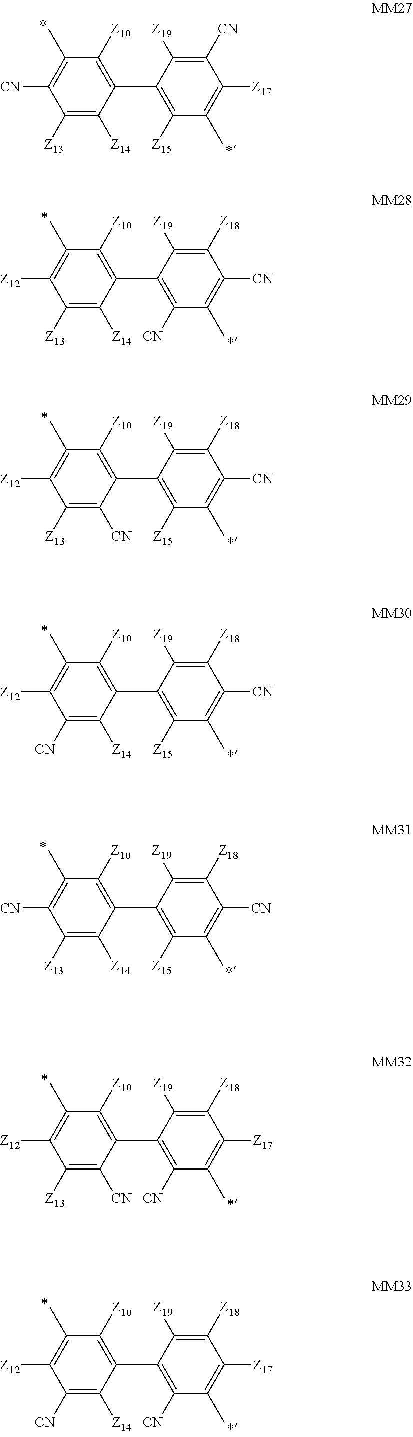

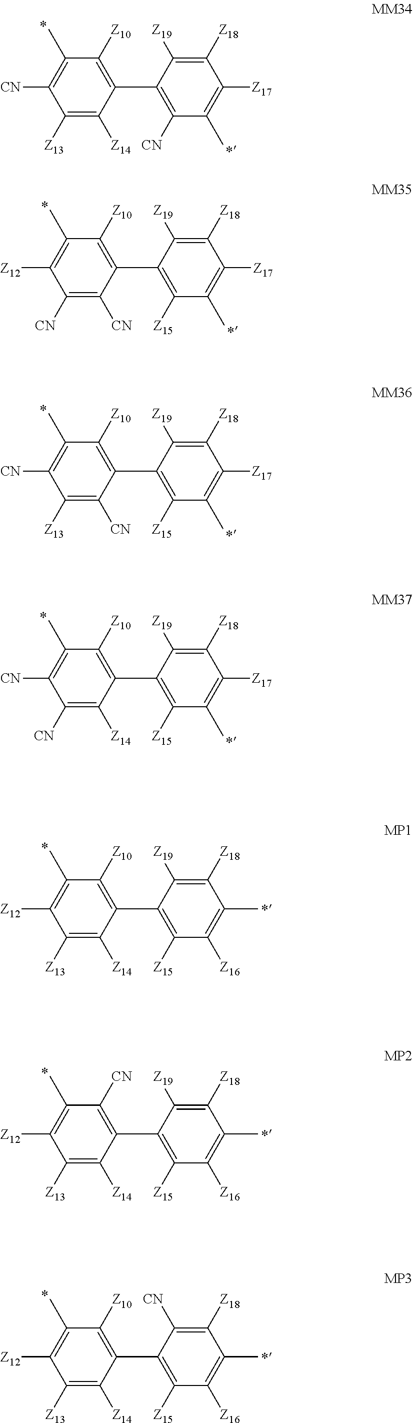

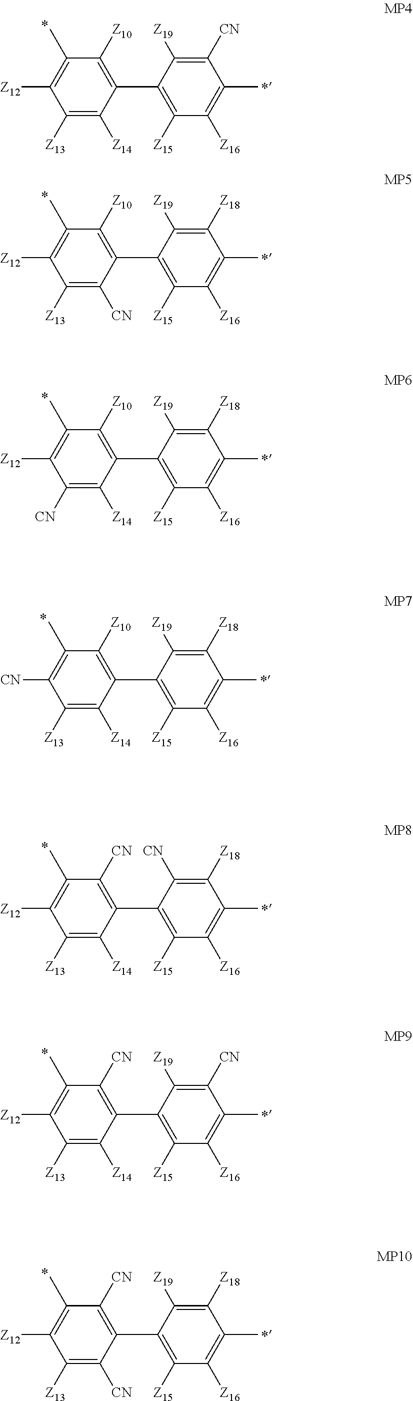

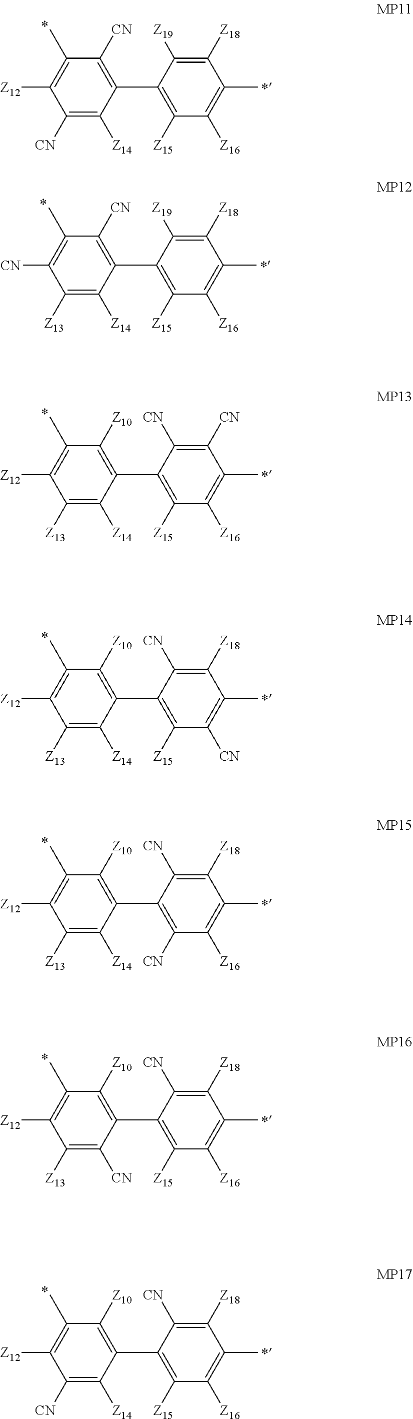

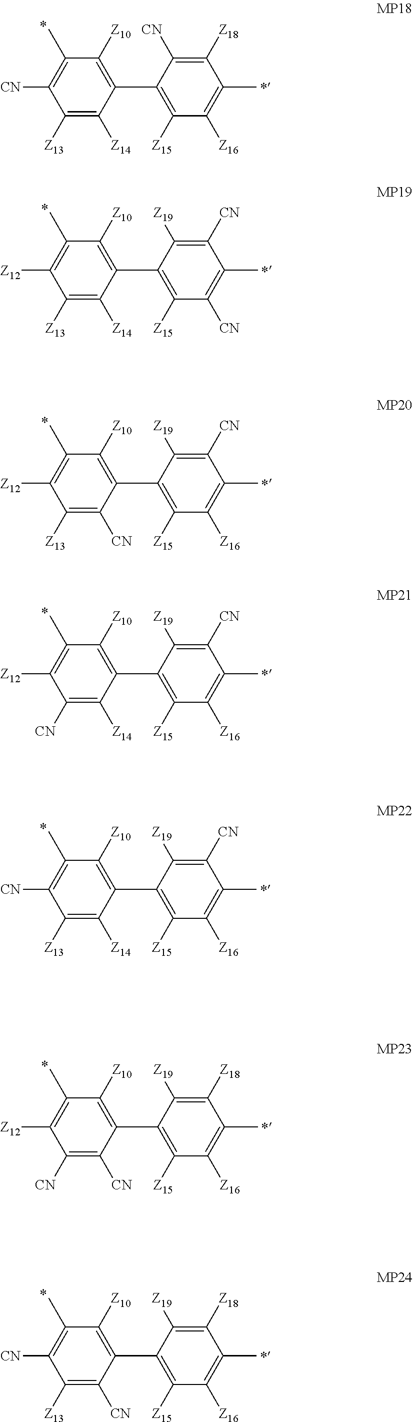

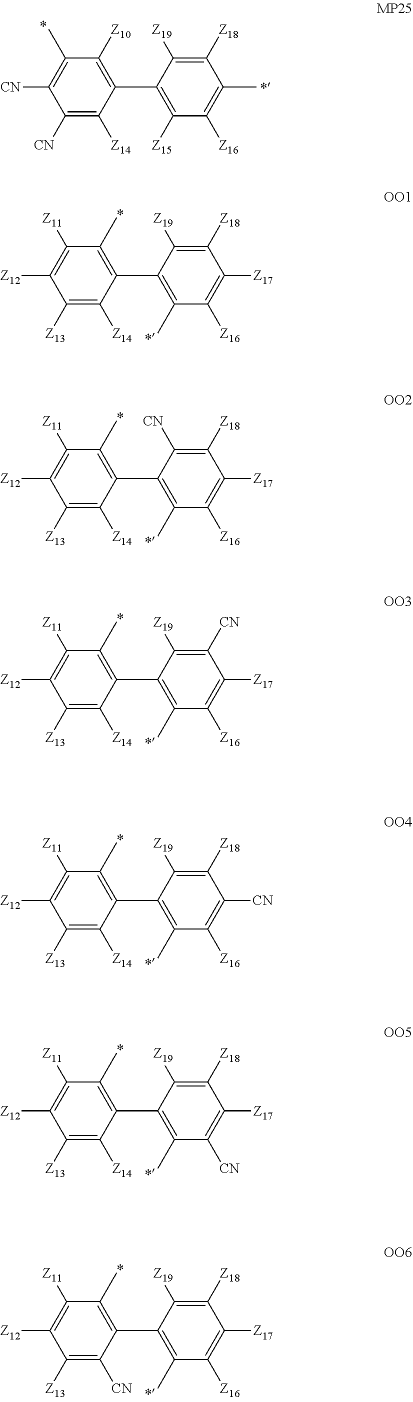

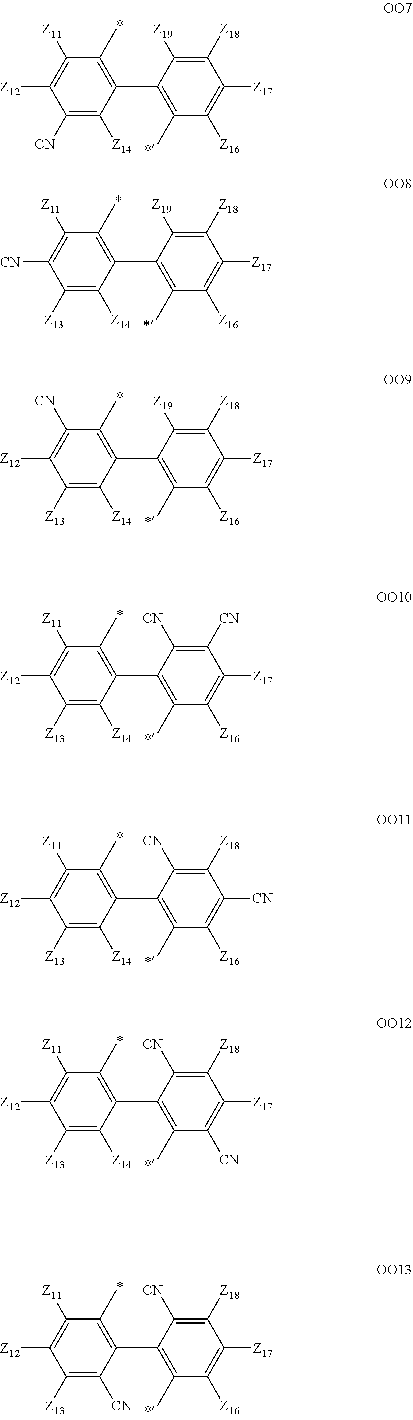

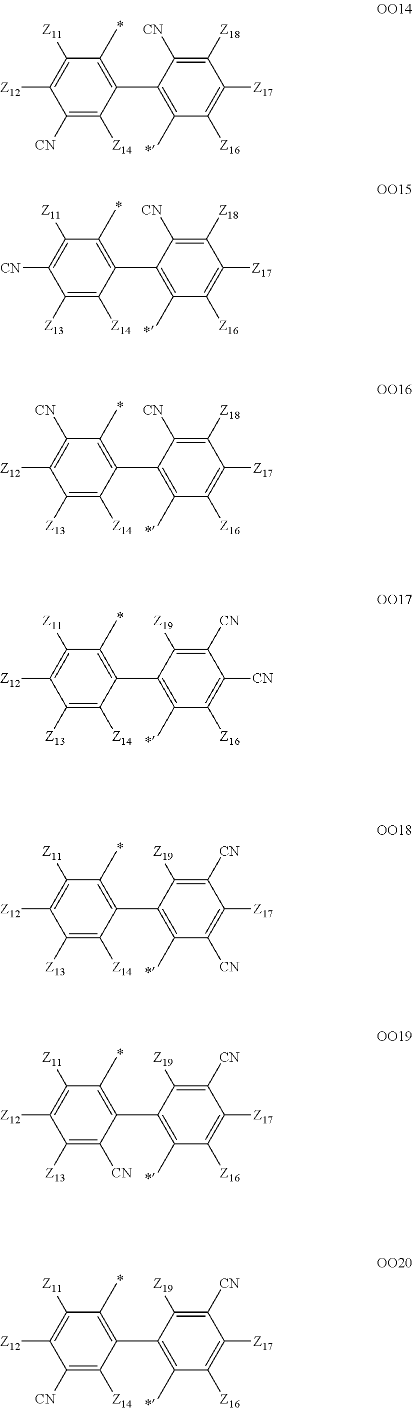

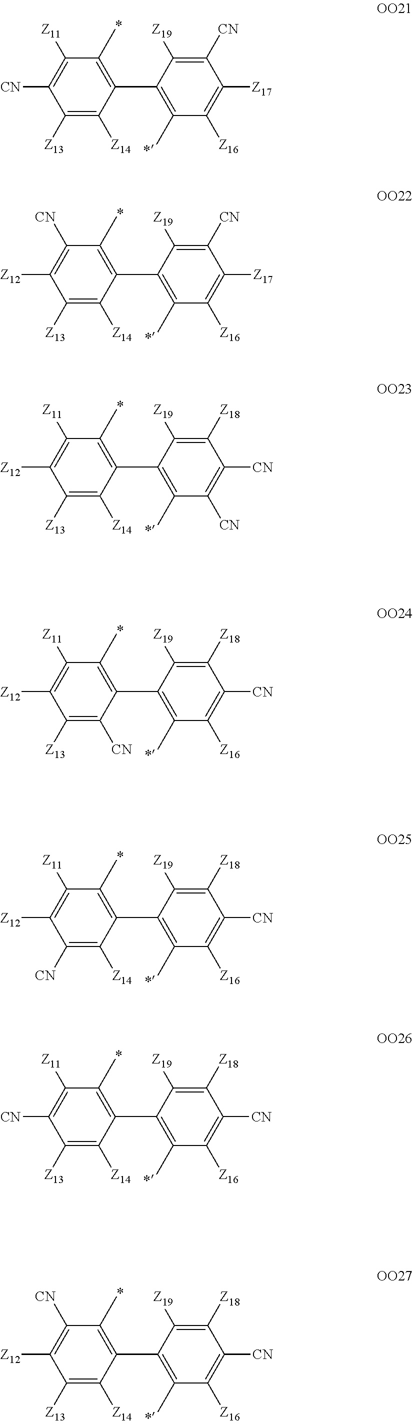

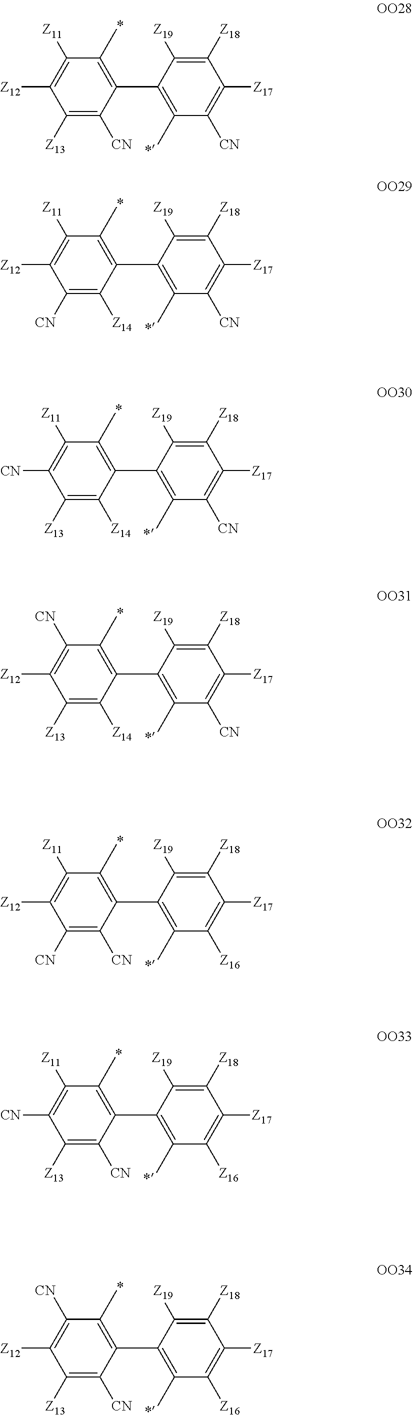

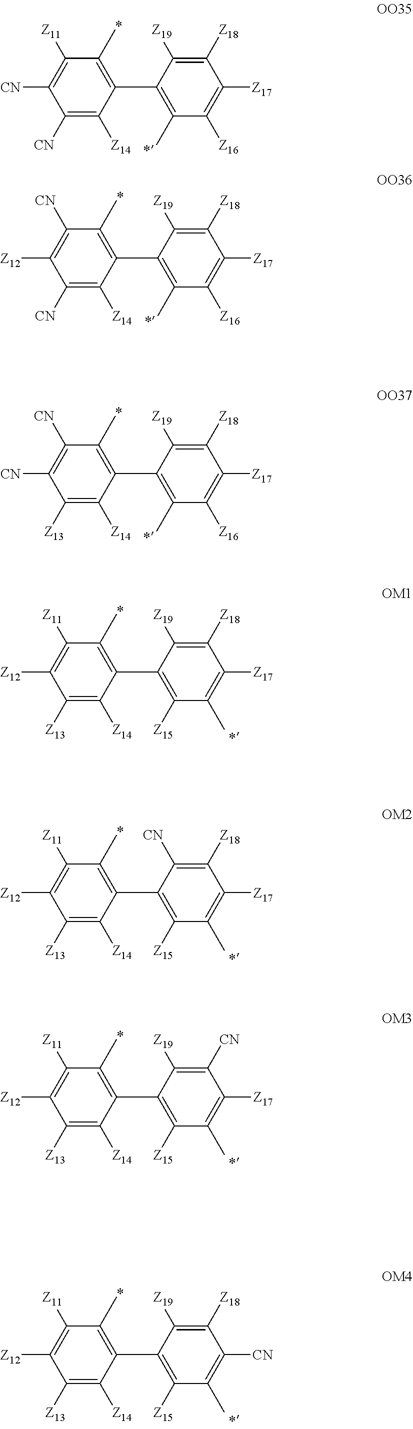

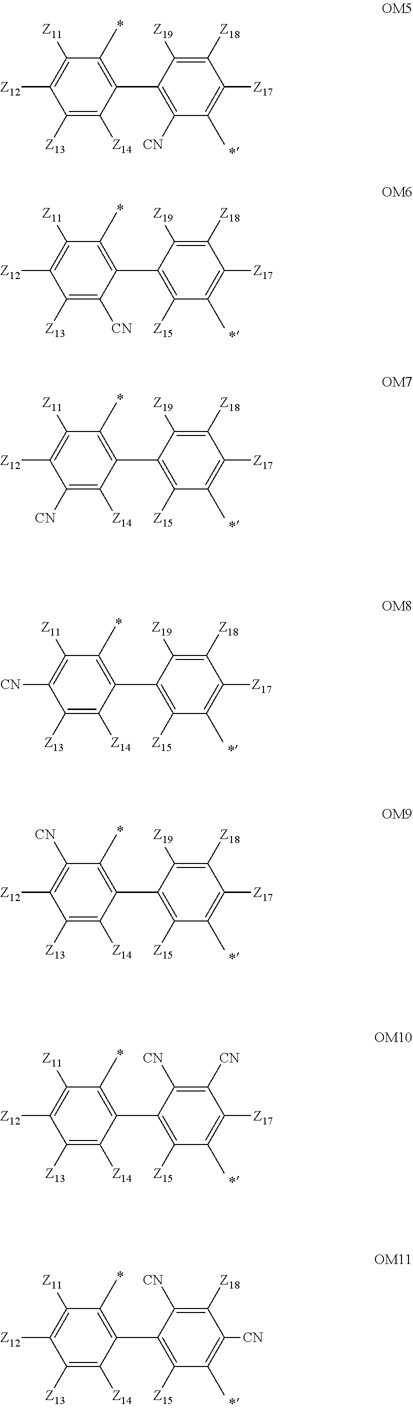

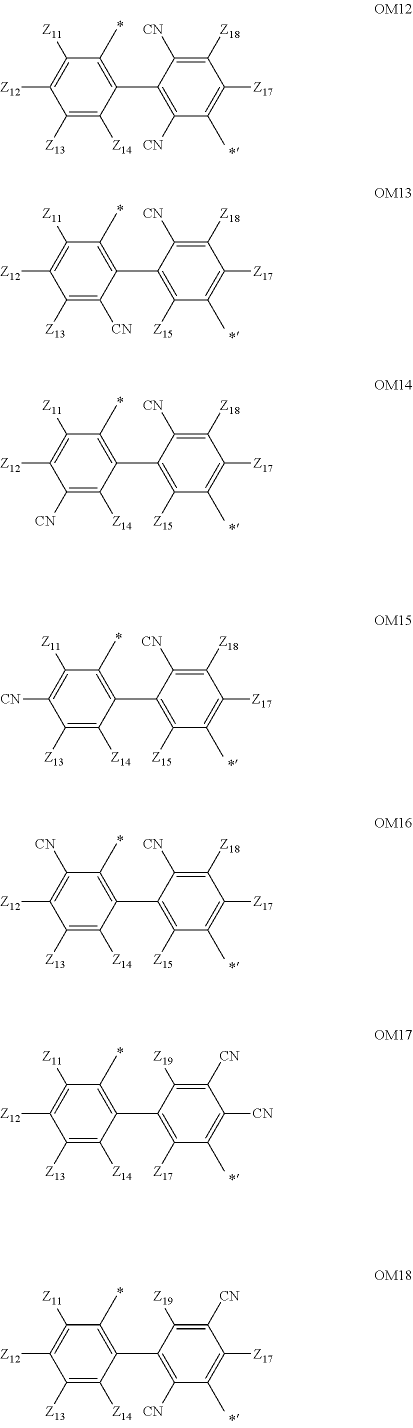

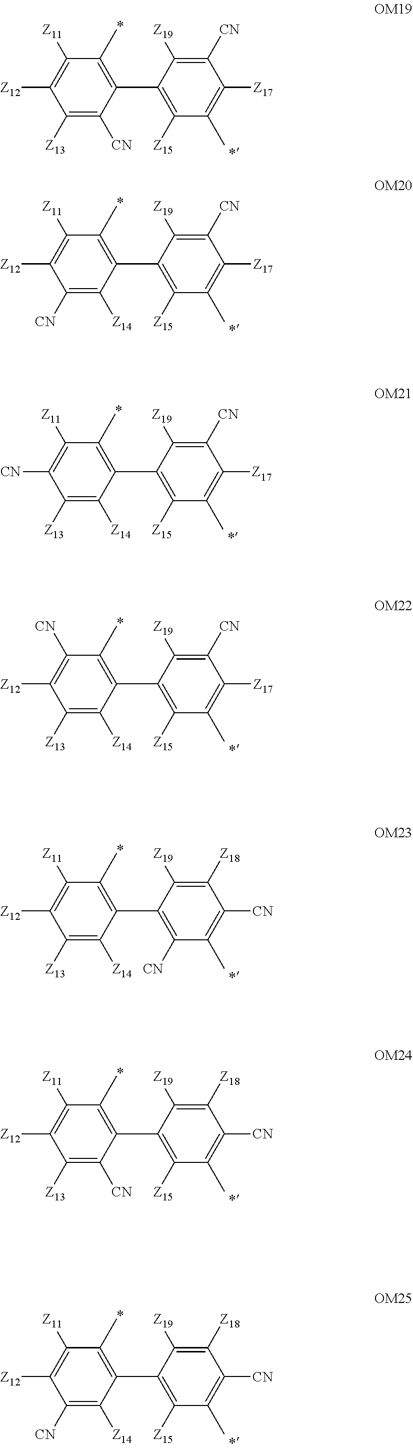

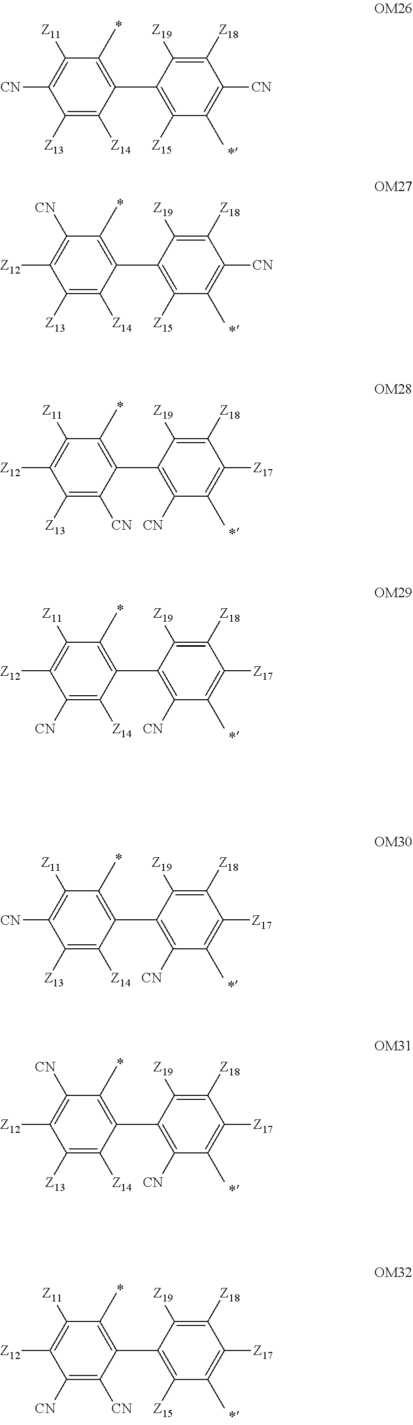

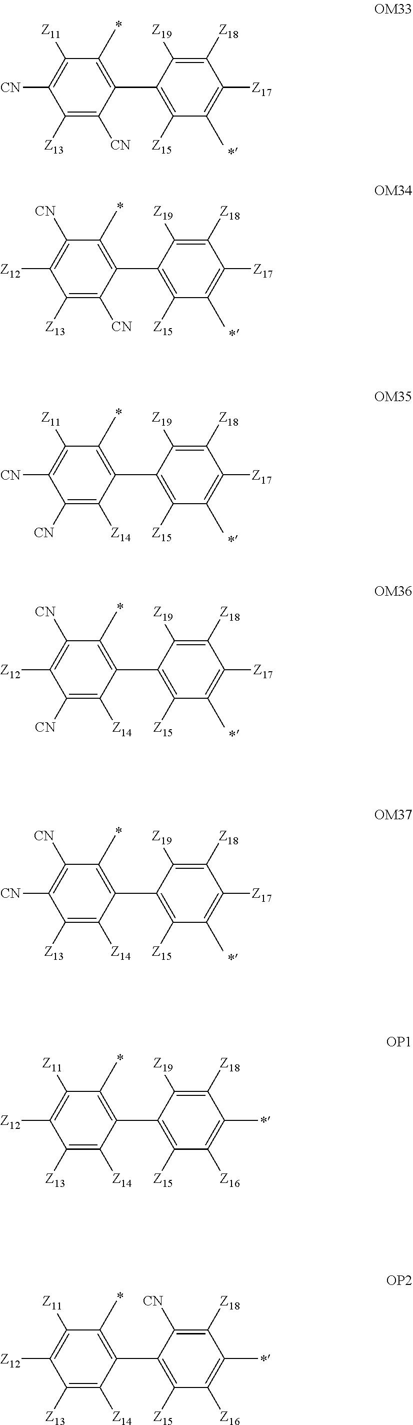

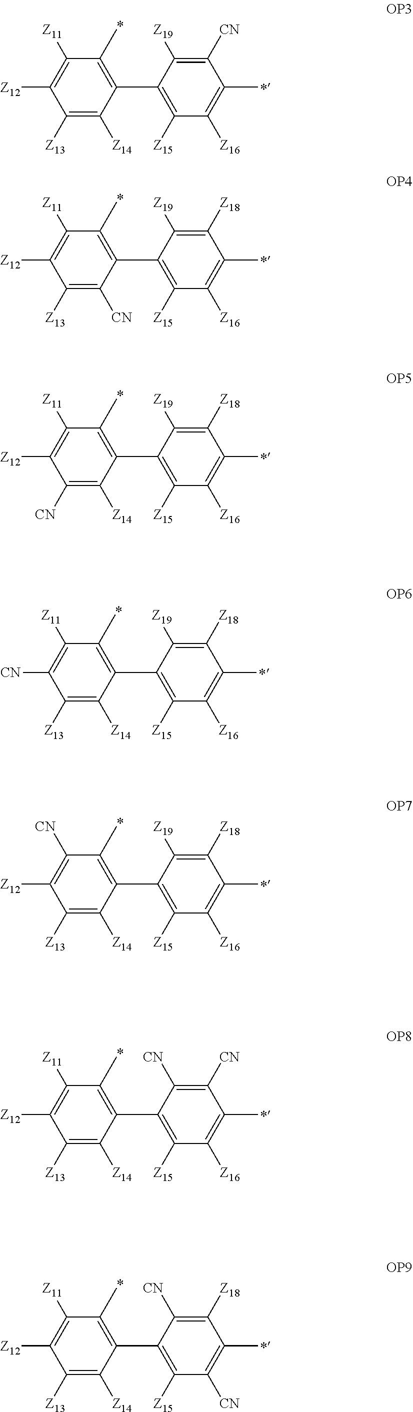

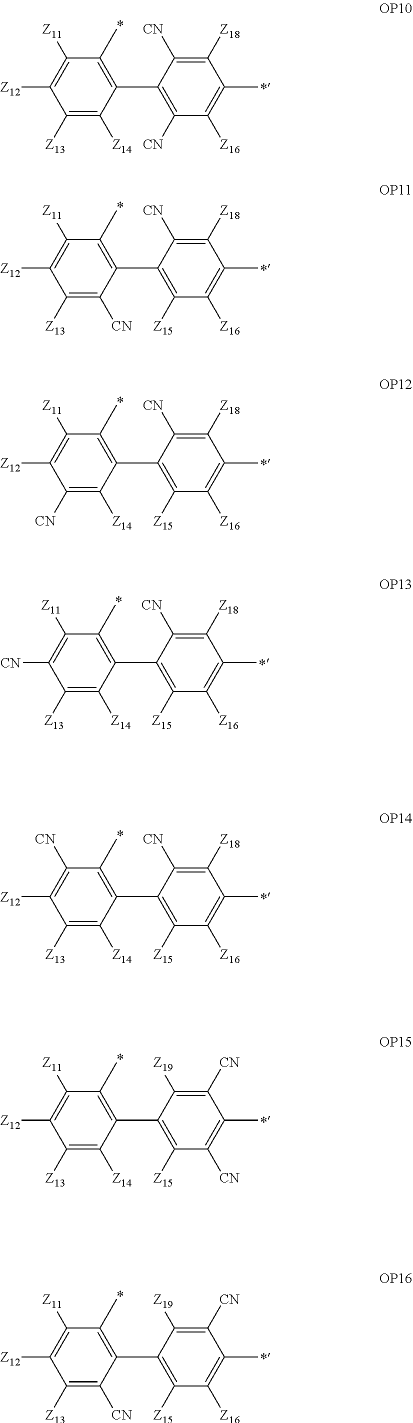

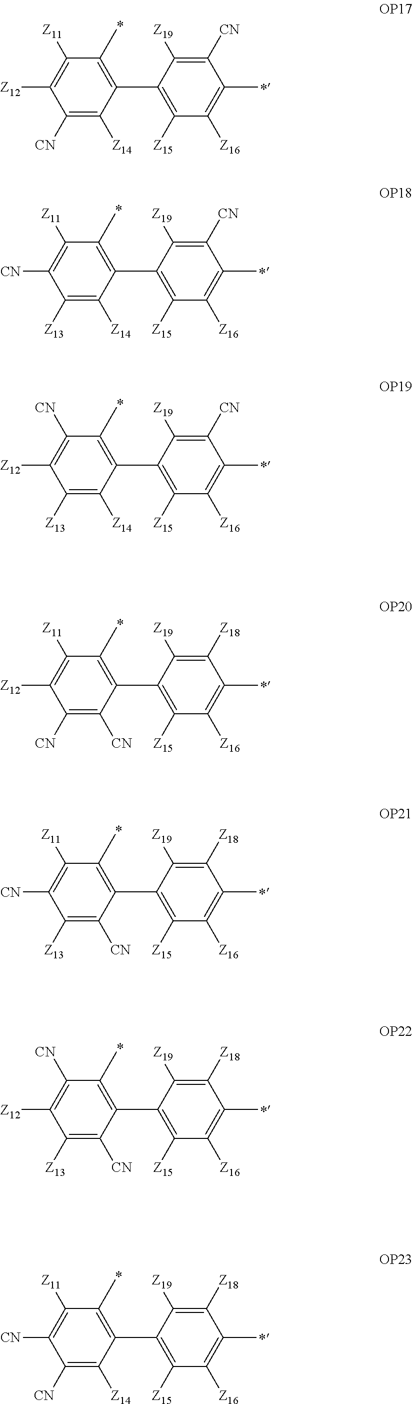

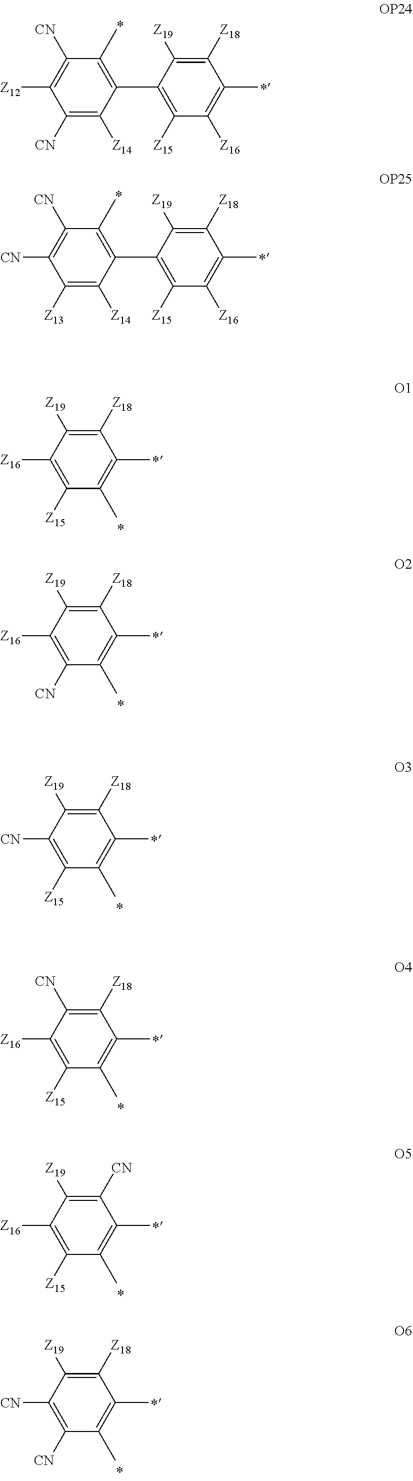

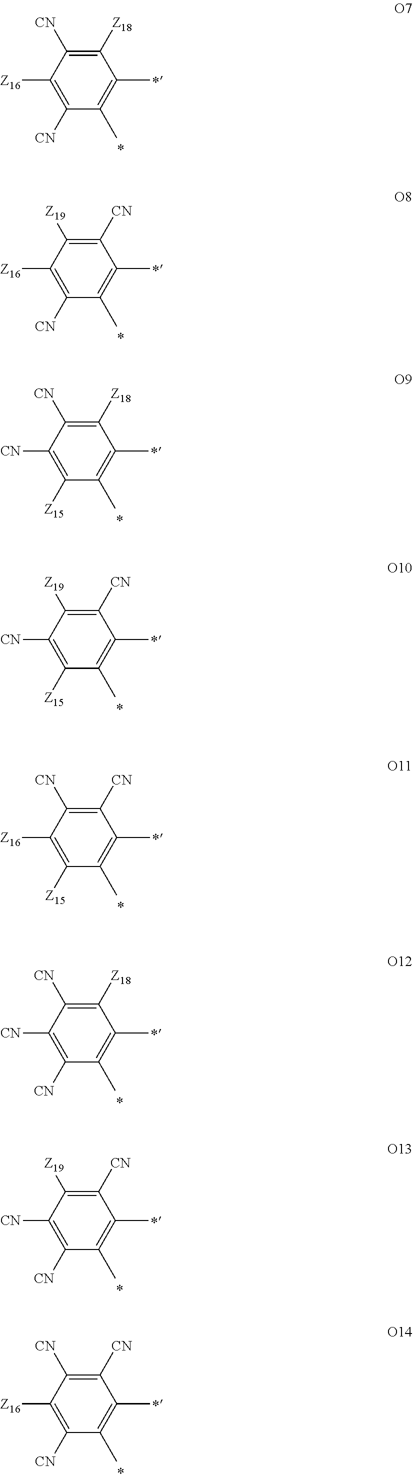

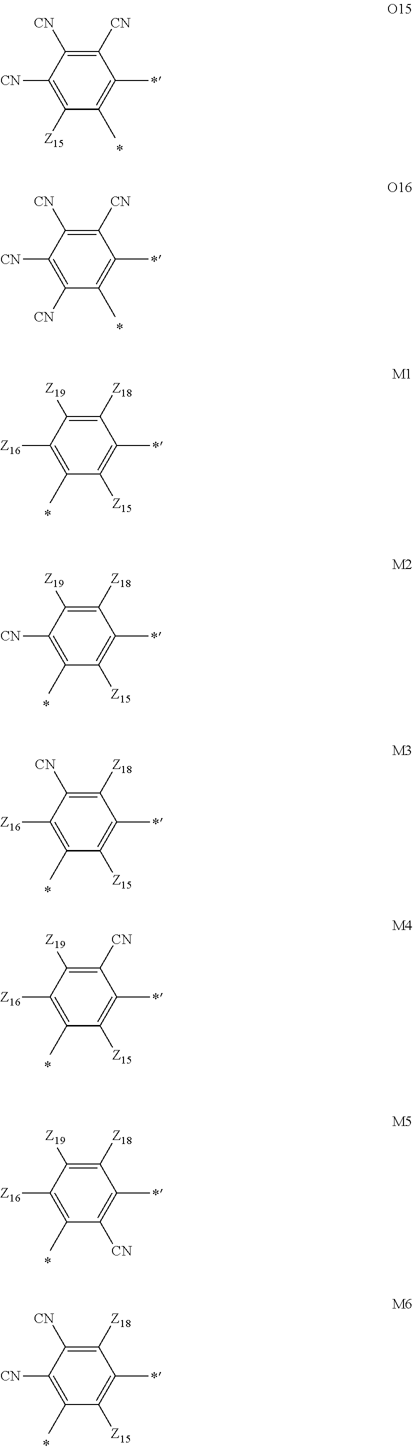

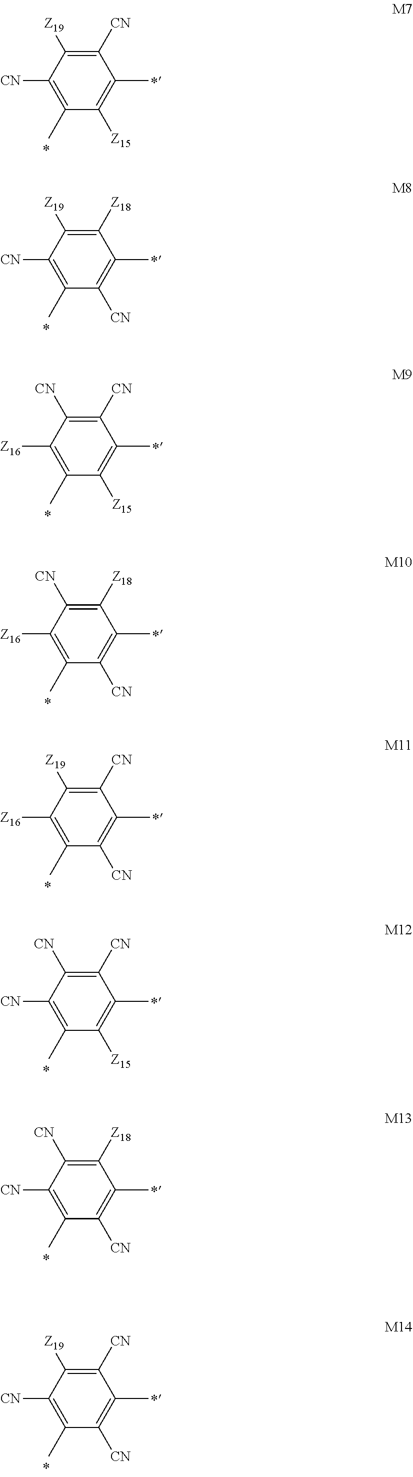

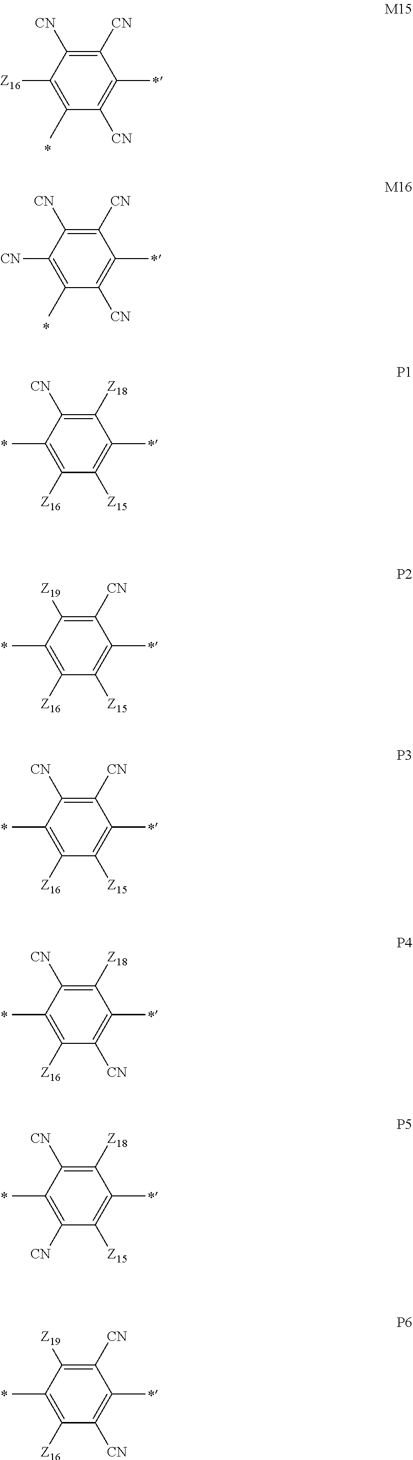

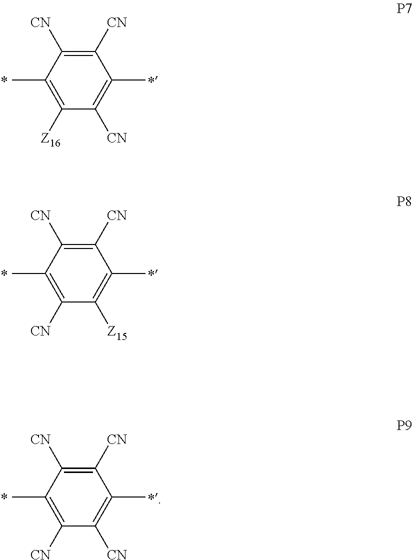

In Formulae PO1 to PO25, PM1 to PM25, PP1 to PP18, MO1 to MO37, MM1 to MM37, MP1 to MP25, OO1 to OO37, OM1 to OM37, OP1 to OP25, O1 to O16, M₁ to M₁₆, and P1 to P9, Z₁₀ to Z₁₉ are the same as described in connection with Z₃ and Z₄, and * and *′ each indicate a binding site to a neighboring atom.

In one embodiment, in Formulae PO1 to PO25, PM1 to PM25, PP1 to PP18, MO1 to MO37, MM1 to MM37, MP1 to MP25, OO1 to OO37, OM1 to OM37, OP1 to OP25, O1 to O16, M₁ to M₁₆, and P1 to P9, Z₁₀ to Z₁₉ may not be a cyano group.

In one or more embodiments, in Formulae PO1 to PO25, PM1 to PM25, PP1 to PP18, MO1 to MO37, MM1 to MM37, MP1 to MP25, OO1 to OO37, OM1 to OM37, OP1 to OP25, O1 to O16, M₁ to M₁₆, and P1 to P9, Z₁₀ to Z₁₉ may each independently be: hydrogen, deuterium, or a cyano group; or an n-propyl group, an iso-propyl group, an n-butyl group, an isobutyl group, a sec-butyl group, a tert-butyl group, an n-pentyl group, an isopentyl group, a sec-pentyl group, a tert-pentyl group, a phenyl group, a biphenyl group, or a terphenyl group, each unsubstituted or substituted with at least one of deuterium, a cyano group, an n-propyl group, an iso-propyl group, an n-butyl group, an isobutyl group, a sec-butyl group, a tert-butyl group, an n-pentyl group, an isopentyl group, a sec-pentyl group, a tert-pentyl group, a phenyl group, or a biphenyl group.

In one or more embodiments, a group represented by the formula:

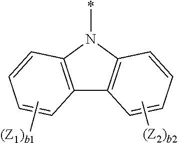

in Formulae E-1(1) and E-1(2) may be one of the groups represented by Formulae A₁-1 to A₁-3, a group represented by the formula:

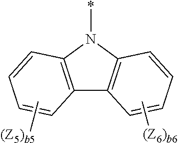

in Formula E-1(1) may be one of groups represented by Formulae A₂-1 to A₂-3, a group represented by the formula:

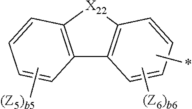

in Formulae E-1(2) and E-1(3) may be one of groups represented by Formulae A₂-4 to A₂-17, and a group represented by the formula:

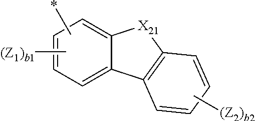

in Formula E-1(3) may be one of groups represented by Formulae A₁-4 to A₁-17:

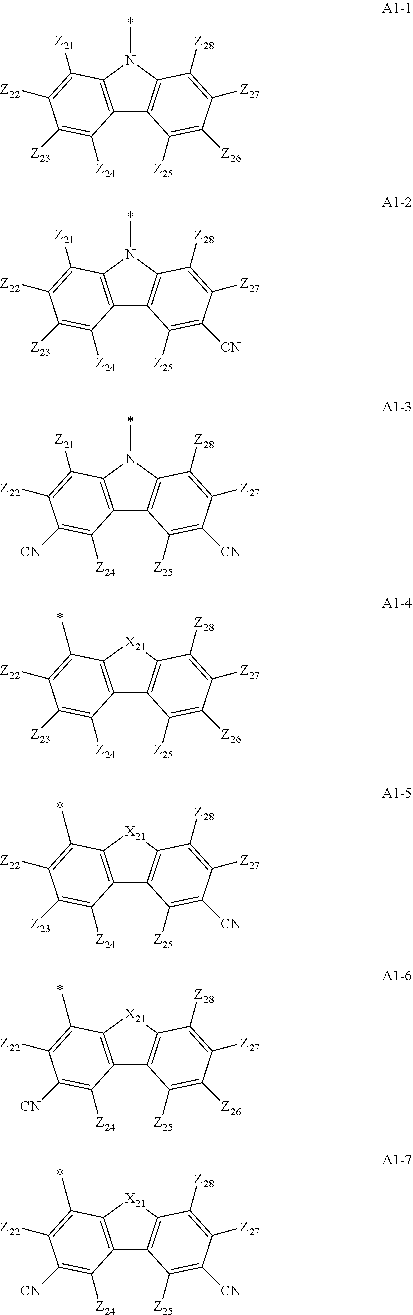

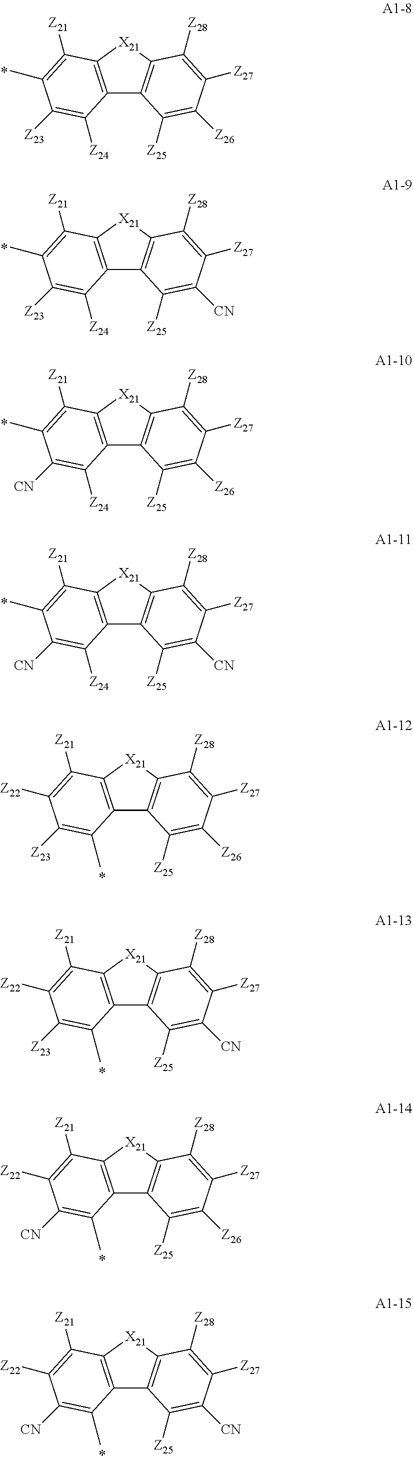

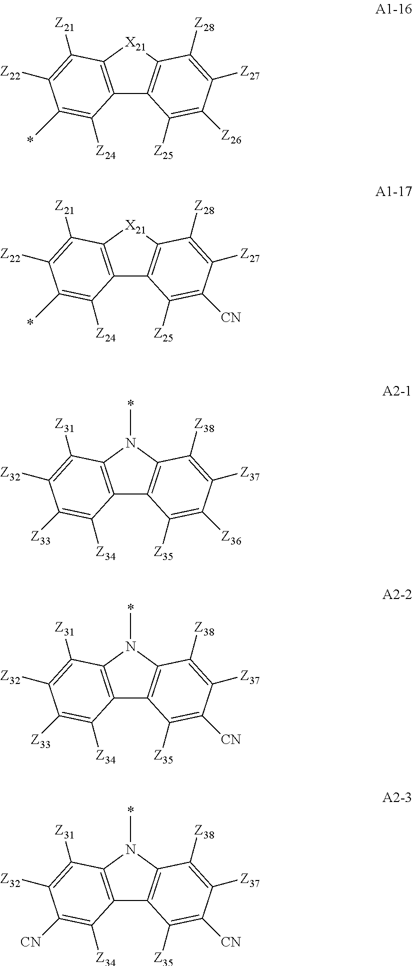

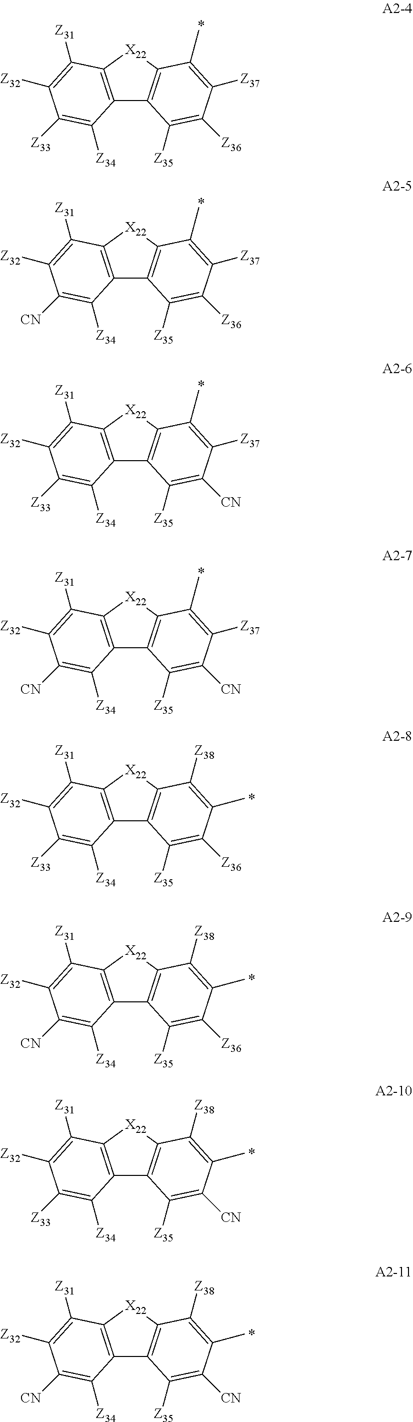

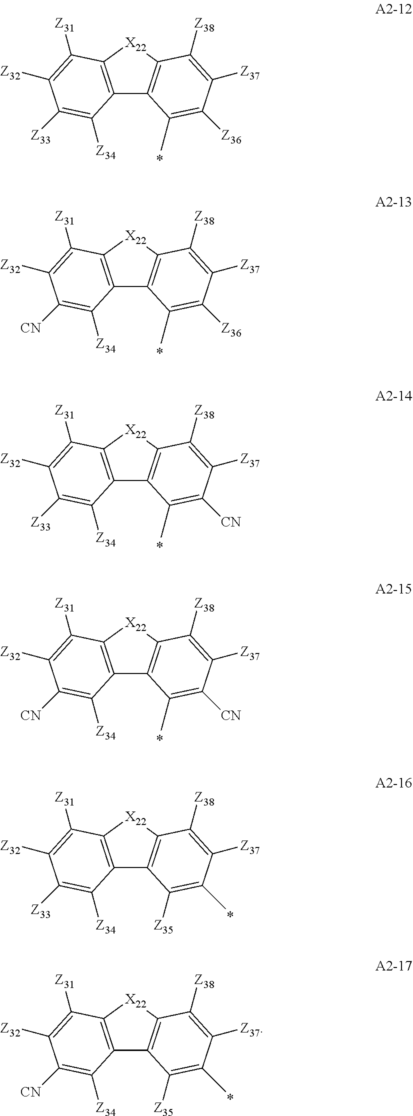

In Formulae A1-1 to A1-17 and A2-1 to A2-17, Z₂₁ to Z₂₈ are the same as described in connection with Z₁ and Z₂, Z₃₁ to Z₃₈ are the same as described in connection with Z₅ and Z₆, and * and *′ each indicate a binding site to a neighboring atom.

In one embodiment, in Formulae A1-1 to A1-17 and A2-1 to A2-17, Z₂₁ to Z₂₈ and Z₃₁ to Z₃₈ may not be a cyano group.

In one or more embodiments, in Formulae A1-1 to A1-17 and A2-1 to A2-17, Z₂₁ to Z₂₈ and Z₃₁ to Z₃₈ may each independently be: hydrogen, deuterium, or a cyano group; or an n-propyl group, an iso-propyl group, an n-butyl group, an isobutyl group, a sec-butyl group, a tert-butyl group, an n-pentyl group, an isopentyl group, a sec-pentyl group, a tert-pentyl group, a phenyl group, a biphenyl group, or a terphenyl group, each unsubstituted or substituted with at least one selected from deuterium, a cyano group, an n-propyl group, an iso-propyl group, an n-butyl group, an isobutyl group, a sec-butyl group, a tert-butyl group, an n-pentyl group, an isopentyl group, a sec-pentyl group, a tert-pentyl group, a phenyl group, or a biphenyl group.

In one embodiment, the second material may include at least one compound of Formulae E1 to E9, but embodiments of the present disclosure are not limited thereto:

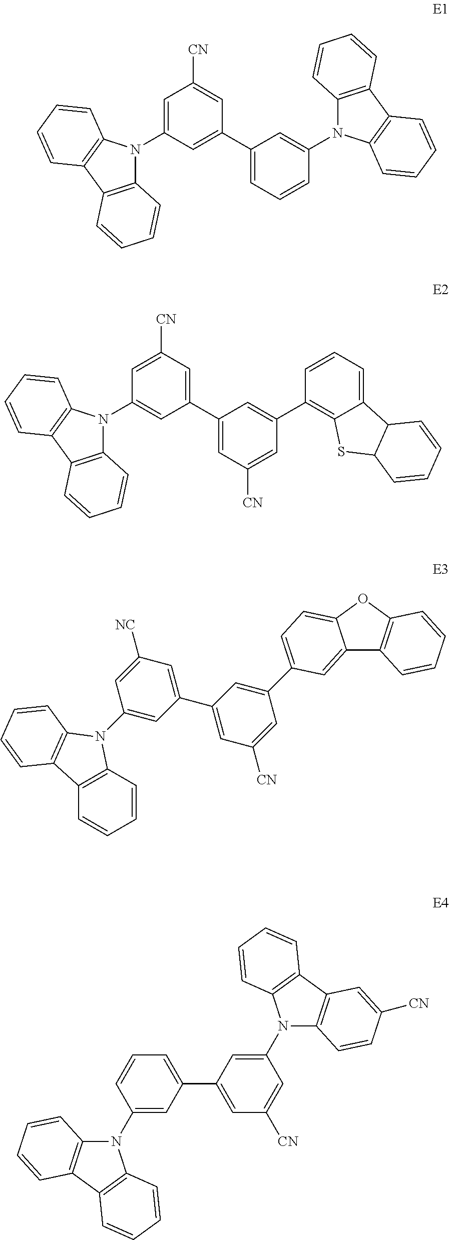 [SMILES: N#Cc1cc(-c2cccc(-n3c4ccccc4c4ccccc43)c2)cc(-n2c3ccccc3c3ccccc32)c1 ; N#Cc1cc(-c2cc(C#N)cc(-n3c4ccccc4c4ccccc43)c2)cc(-c2cccc3c2SC2C=CC=CC32)c1 ; N#Cc1cc(-c2cc(C#N)cc(-n3c4ccccc4c4ccccc43)c2)cc(-c2ccc3oc4ccccc4c3c2)c1 ; N#Cc1cc(-c2cccc(-n3c4ccccc4c4ccccc43)c2)cc(-n2c3ccccc3c3cc(C#N)ccc32)c1]

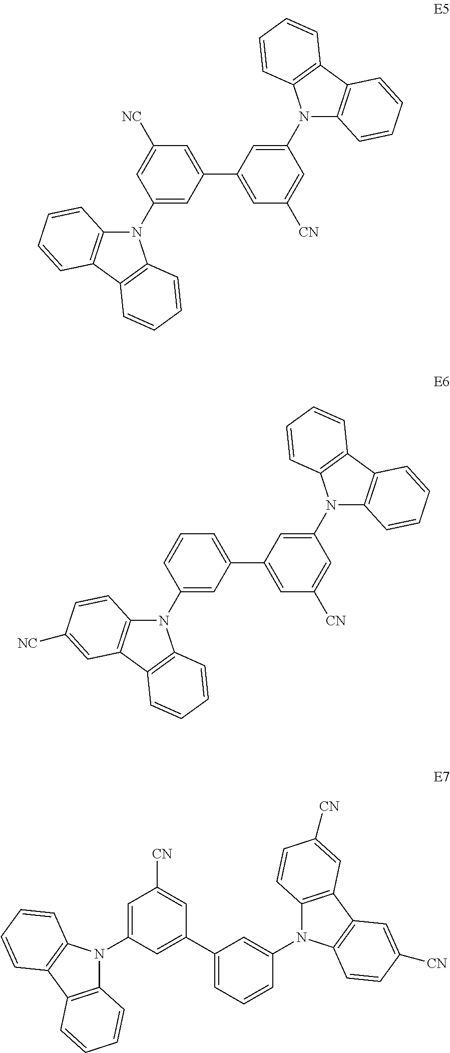 [SMILES: N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccc(C#N)cc4c4cc(C#N)ccc43)c2)cc(-n2c3ccccc3c3ccccc32)c1]

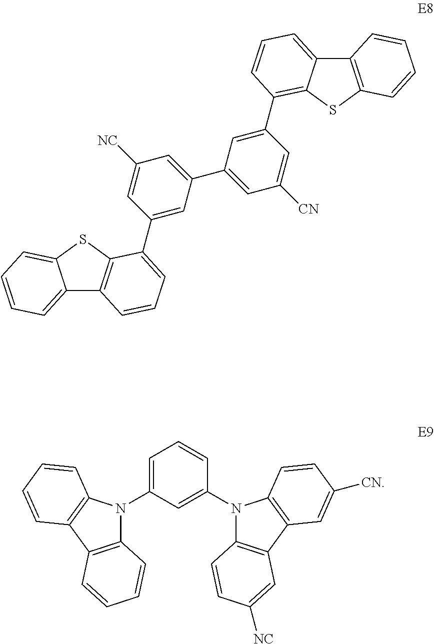

The light-emitting material may include a phosphorescent material. Therefore, the emission layer may emit phosphorescence.

In one embodiment, the light-emitting material may include a transition metal-containing organometallic compound.

The transition metal may be, for example, iridium (Ir), platinum (Pt), osmium (Os), titanium (Ti), zirconium (Zr), hafnium (Hf), europium (Eu), terbium (Tb), thulium (Tm), rhodium (Rh), ruthenium (Ru), rhenium (Re), cobalt(Co), copper(Cu), rhodium (Rh), palladium (Pd), silver (Ag), or gold (Au), but embodiments of the present disclosure are not limited thereto.

In one or more embodiments, the light-emitting material may include a transition metal-containing organometallic compound that emits blue light (about 400 nm to about 500 nm).

In one or more embodiments, the light-emitting material may include an organometallic compound including a bidentate ligand containing at least one cyano group or at least one fluoro group, and a transition metal.

In one or more embodiments, the light-emitting material may include an organometallic compound including a cyano group-containing bidentate ligand and a transition metal.

In one or more embodiments, the light-emitting material may include an organometallic compound including a bidentate ligand containing at least one cyano group and at least one deuterium, and a transition metal.

In one or more embodiments, the light-emitting material may include a homoleptic organometallic compound including a cyano group-containing phenylimidazole-based bidentate ligand and iridium.

In one or more embodiments, the light-emitting material may include an organometallic compound represented by Formula 30:

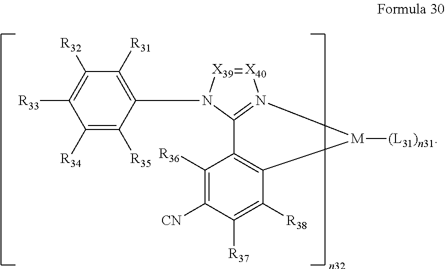

M in Formula 30 may be a first-row transition metal, a second-row transition metal, or a third-row transition metal. For example, M may be Ir, Os, Re, Pt, Pd, or Au, but embodiments of the present disclosure are not limited thereto.

In Formula 30, each occurrence of L₃₁ may be the same or different, and may be a monodentate ligand or a bidentate ligand, and n31 may be 0, 1, 2, 3, or 4, wherein, when n31 is two or more, two or more of the groups L₃₁ may be identical to or different from each other.

n32 in Formula 30 may be 1, 2, or 3.

For example, when M is Ir or Os, the sum of n31 and n32 may be 3, and when M is Pt, the sum of n31 and n32 may be 2.

In Formula 30, each occurrence of X₃₉ may be the same or different, and may be N or C(R₃₉), and each occurrence of X₄₀ may be the same or different, and may be N or C(R₄₀).

Each occurrence of R₃₁ to R₄₀ may be the same or different, and may each independently be hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted heterocycloalkyl group, a substituted or unsubstituted C₃-C₁₀ cycloalkenyl group, a substituted or unsubstituted heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted heteroaryl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —B(Q₆)(Q₇), or —P(═O)(Q₈)(Q₉). Q₁ to Q₉ are the same as described above.

For example, each occurrence of R₃₁ to R₄₀ may be the same or different, and may the same as described in connection with R₂₁.

Two or more neighboring groups of R₃₁ to R₄₀ may optionally be linked to form a C₅-C₃₀ carbocyclic group unsubstituted or substituted with at least one R₂₀ₐ or a C₂-C₃₀ heterocyclic group unsubstituted or substituted with at least one R₂₀ₐ (for example, a benzene group, a naphthalene group, a pyridine group, a pyrimidine group, and a pyrazine group, unsubstituted or substituted with at least one R₂₀ₐ). R₂₀ₐ may be the same as described in connection with R₂₁.

In one embodiment, at least one of R₃₁, R₃₃, and R₃₅ in Formula 30 (for example, R₃₁ and R₃₅) may each independently be: deuterium, a cyano group, a C₁-C₂₀ alkyl group, a phenyl group, a biphenyl group, or a terphenyl group; or a C₁-C₂₀ alkyl group, a phenyl group, a biphenyl group, or a terphenyl group, each unsubstituted or substituted with at least one selected from deuterium, a cyano group, or a C₁-C₂₀ alkyl group.

In one embodiment, a maximum emission wavelength of the organometallic compound represented by Formula 30 may be in a range of about 440 nm to about 470 nm (for example, about 440 nm to about 467 nm). When the maximum emission wavelength is within the range of about 440 nm to about 470 nm, it is possible to provide an organic light-emitting device that emits light of a deep blue color.

In one embodiment, the light-emitting material may include at least one compound of Formulae 1 to 24, D1 to D11, or F₂IrPic, but embodiments of the present disclosure are not limited thereto:

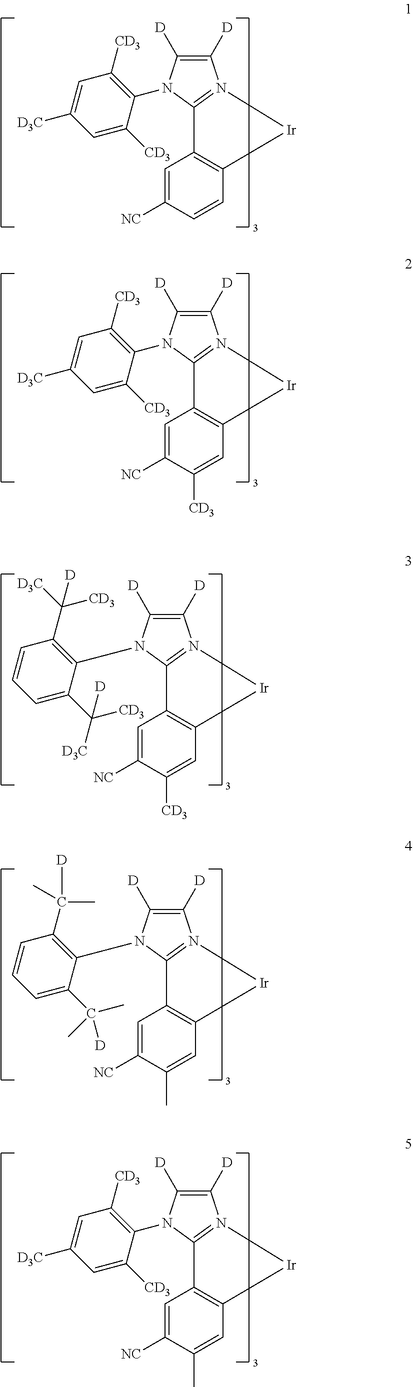

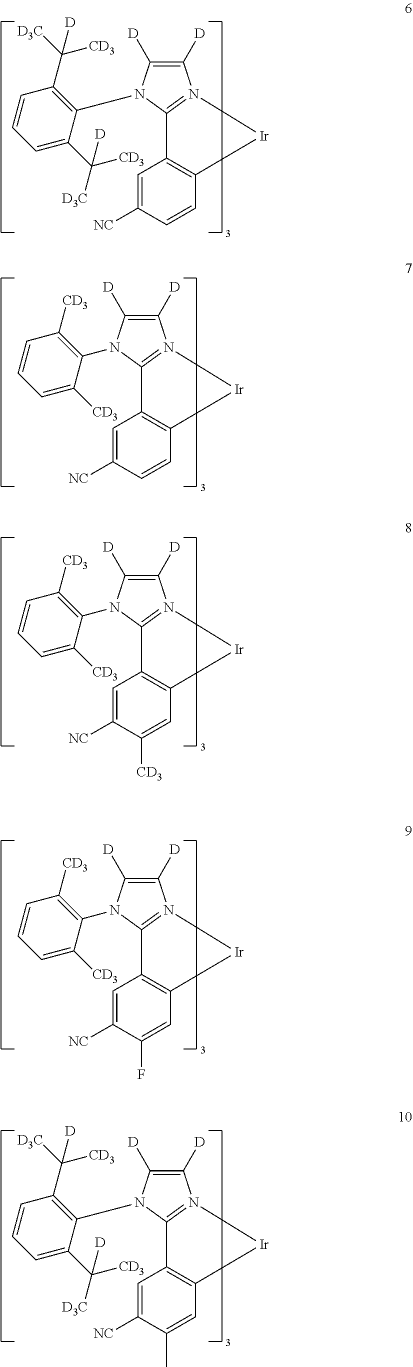

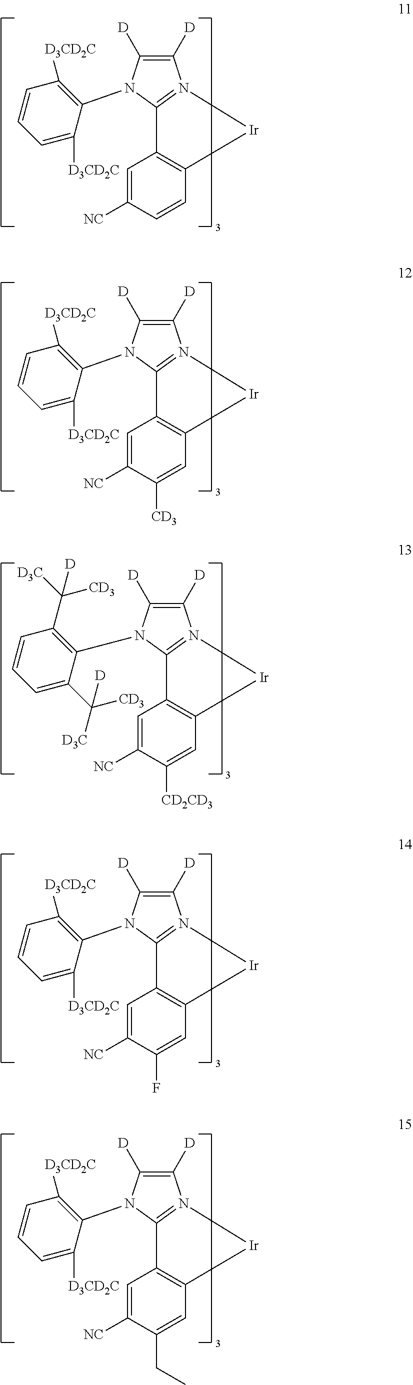

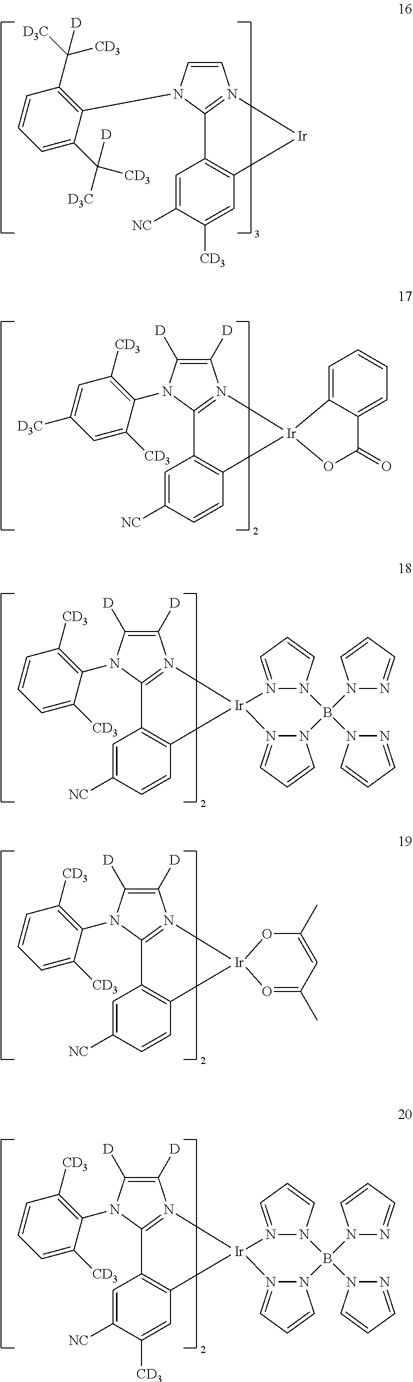

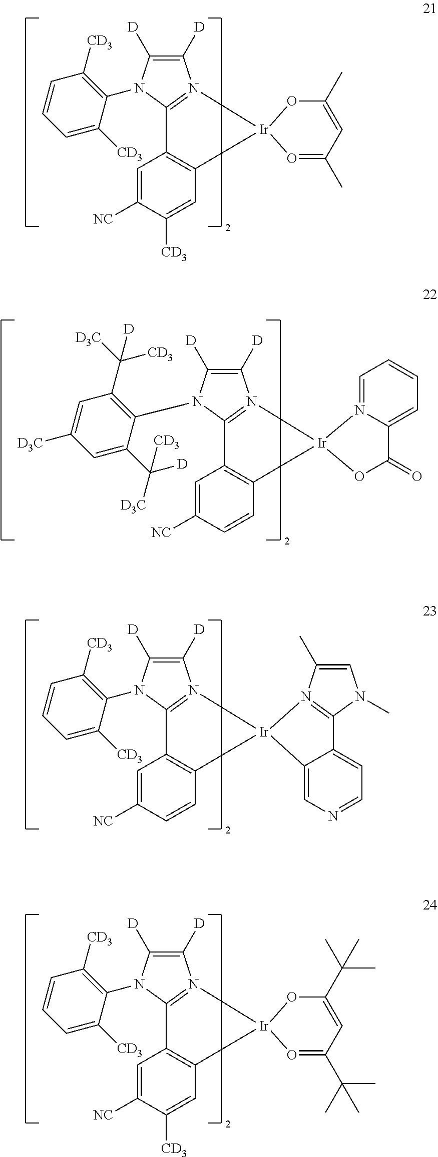

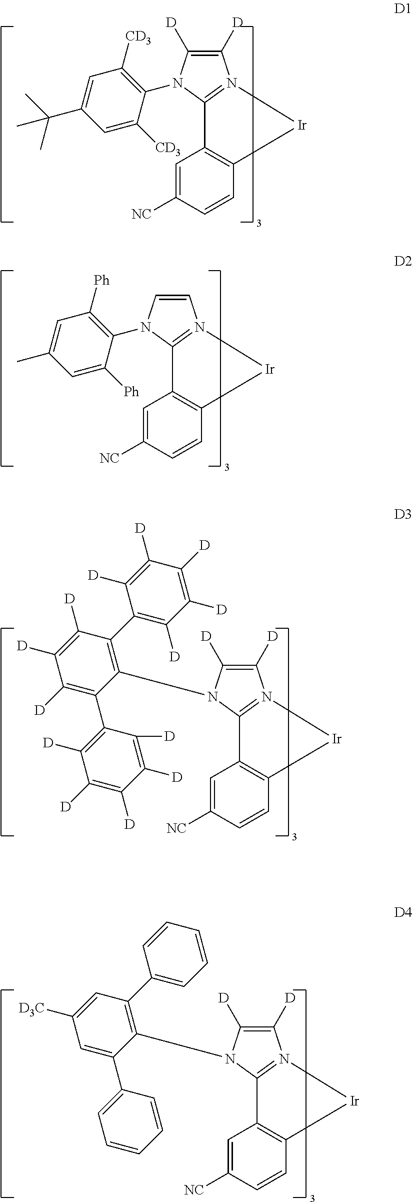

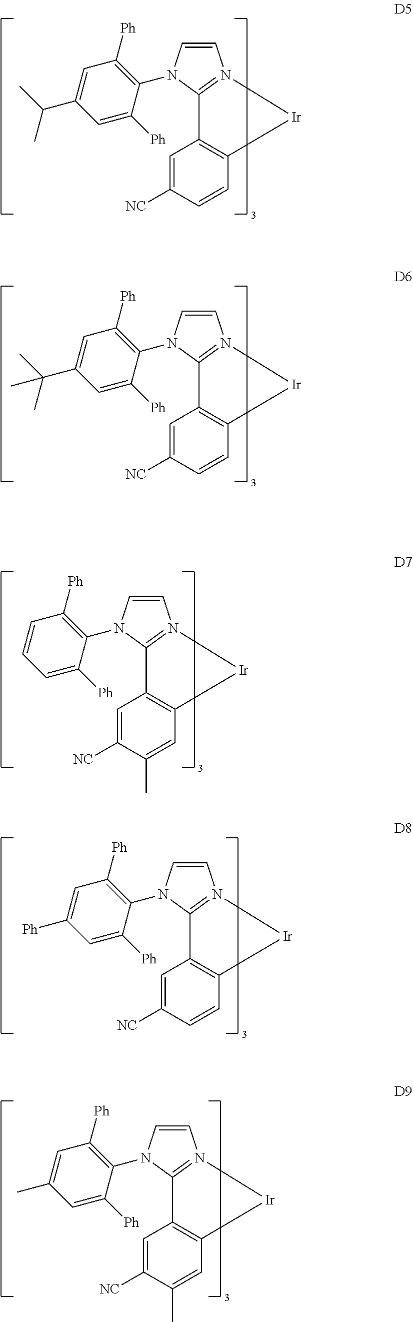

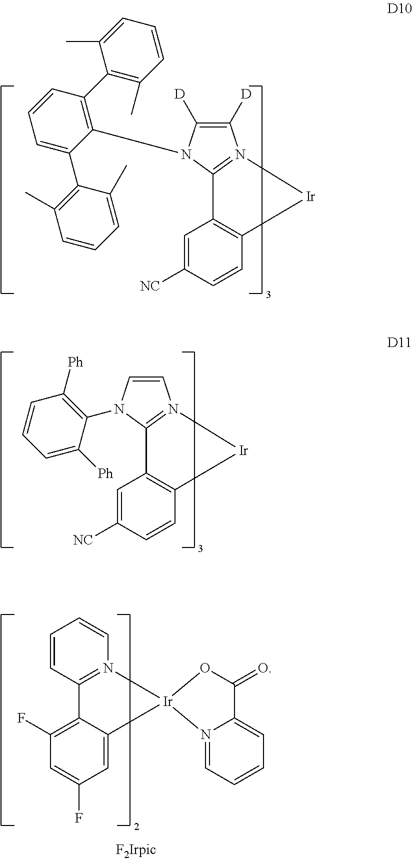

An amount of the light-emitting material may be in a range of about 0 parts by weight to about 20 parts by weight, for example, about 0.01 parts by weight to about 10 parts by weight, based on 100 parts by weight of the total of the first material, the second material, and the light-emitting material. When the amount of the light-emitting material is within this range, high luminescent efficiency may be achieved without concentration quenching.

A weight ratio of the first material to the second material may be from the ratios of 1:9 to 9:1, 2:8 to 8:2, 3:7 to 7:3, or 4:6 to 6:4.

The first material and the second material may act as a host in the emission layer, and the light-emitting material may act as a dopant in the emission layer.

When the organic light-emitting device is a full-color organic light-emitting device, the emission layer may be patterned into a red emission layer, a green emission layer, and a blue emission layer. In one or more embodiments, due to a stacked structure including a red emission layer, a green emission layer, and/or a blue emission layer, the emission layer may emit white light.

A thickness of the emission layer may be in a range of about 100 Angstroms (Å) to about 1,000 Å, for example, about 200 Å to about 600 Å. When the thickness of the emission layer is within this range, excellent light-emission characteristics may be obtained without a substantial increase in driving voltage.

Then, according to one or more embodiments, an electron transport region may be disposed on the emission layer.

The electron transport region may include the first electron transport layer and the second electron transport layer described in the present specification. The first electron transport layer and the second electron transport layer are the same as described above.

The electron transport region may further include, in addition to the first electron transport layer and the second electron transport layer, at least one of a hole blocking layer between the emission layer and the first electron transport layer and an electron injection layer between the second electron transport layer and the second electrode.

A condition for forming the hole blocking layer, the first electron transport layer, the second electron transport layer, and the electron injection layer of the electron transport region is the same as described in the condition for forming the hole injection layer.

When the electron transport region further includes a hole blocking layer, the hole blocking layer may include, for example, BCP or Bphen:

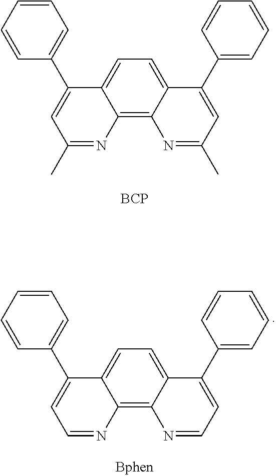

Alternatively, the hole blocking layer may include at least one of the first material and the second material as described herein. When the hole blocking layer includes at least one of the first material and the second material as described herein, the first material and the second material included in the emission layer may be identical to or different from the first material and the second material included in the hole blocking layer.

A thickness of the hole blocking layer may be in a range of about 20 Å to about 1,000 Å, for example, about 30 Å to about 300 Å. When the thickness of the hole blocking layer is within these ranges, the hole blocking layer may have improved hole blocking ability without a substantial increase in driving voltage.

A thickness of each of the first electron transport layer and the second electron transport layer may be in a range of about 10 Å to about 1,500 Å, for example, about 50 Å to about 500 Å. When the thickness of each of the first electron transport layer and the second electron transport layer is within the range described above, the second electron transport layer may have satisfactory electron transport characteristics without a substantial increase in driving voltage.

The electron injection layer facilitates injection of electrons from the second electrode 19, and for example, may include at least one of LiF, NaCl, CsF, Li₂O, or BaO.

A thickness of the electron injection layer may be in a range of about 1 Å to about 150 Å, for example, about 3 Å to about 100 Å. When the thickness of the electron injection layer is within the range described above, the electron injection layer may have satisfactory electron injection characteristics without a substantial increase in driving voltage.

The second electrode 19 may be disposed on the organic layer 15. The second electrode 19 may be a cathode. A material for forming the second electrode 19 may be a metal, a metal alloy, an electrically conductive compound, or a combination thereof, which have a relatively low work function. For example, lithium (Li), magnesium (Mg), aluminum (Al), aluminum-lithium (Al—Li), calcium (Ca), magnesium-indium (Mg—In), or magnesium-silver (Mg—Ag) may be used as a material for forming the second electrode 19. In one or more embodiments, to manufacture a top-emission type light-emitting device, a transmissive electrode formed using ITO or IZO may be used as the second electrode 19.

Hereinbefore, the organic light-emitting device has been described with reference to FIG. 1, but embodiments of the present disclosure are not limited thereto.

The term “C₁-C₆₀ alkyl group” as used herein refers to a linear or branched saturated aliphatic hydrocarbon monovalent group having 1 to 60 carbon atoms, and non-limiting examples thereof include a methyl group, an ethyl group, a propyl group, an isobutyl group, a sec-butyl group, a tert-butyl group, a pentyl group, an iso-amyl group, and a hexyl group. The term “C₁-C₆₀ alkylene group” as used herein refers to a divalent group having the same structure as the C₁-C₆₀ alkyl group.

The term “C₁-C₆₀ alkoxy group” as used herein refers to a monovalent group represented by —OA₁₀₁ (wherein A₁₀₁ is the C₁-C₆₀ alkyl group), and non-limiting examples thereof include a methoxy group, an ethoxy group, and an isopropyloxy group.

The term “C₂-C₆₀ alkenyl group” as used herein refers to a hydrocarbon group having at least one carbon-carbon double bond in the middle or at the terminus of the C₂-C₆₀ alkyl group, and examples thereof include an ethenyl group, a propenyl group, and a butenyl group. The term “C₂-C₆₀ alkenylene group” as used herein refers to a divalent group having the same structure as the C₂-C₆₀ alkenyl group.

The term “C₂-C₆₀ alkynyl group” as used herein refers to a hydrocarbon group having at least one carbon-carbon triple bond in the middle or at the terminus of the C₂-C₆₀ alkyl group, and examples thereof include an ethynyl group, and a propynyl group. The term “C₂-C₆₀ alkynylene group” as used herein refers to a divalent group having the same structure as the C₂-C₆₀ alkynyl group.

The term “C₃-C₁₀ cycloalkyl group” as used herein refers to a monovalent saturated hydrocarbon monocyclic group having 3 to 10 carbon atoms, and non-limiting examples thereof include a cyclopropyl group, a cyclobutyl group, a cyclopentyl group, a cyclohexyl group, and a cycloheptyl group. The term “C₃-C₁₀ cycloalkylene group” as used herein refers to a divalent group having the same structure as the C₃-C₁₀ cycloalkyl group.

The term “C₁-C₁₀ heterocycloalkyl group” as used herein refers to a monovalent saturated monocyclic group having at least one heteroatom selected from N, O, P, Si and S as a ring-forming atom and 1 to 10 carbon atoms, and non-limiting examples thereof include a tetrahydrofuranyl group, and a tetrahydrothiophenyl group. The term “C₁-C₁₀ heterocycloalkylene group” as used herein refers to a divalent group having the same structure as the C₁-C₁₀ heterocycloalkyl group.

The term “C₃-C₁₀ cycloalkenyl group” as used herein refers to a monovalent monocyclic group that has 3 to 10 carbon atoms and at least one carbon-carbon double bond in the ring thereof and no aromaticity, and non-limiting examples thereof include a cyclopentenyl group, a cyclohexenyl group, and a cycloheptenyl group. The term “C₃-C₁₀ cycloalkenylene group” as used herein refers to a divalent group having the same structure as the C₃-C₁₀ cycloalkenyl group.

The term “C₁-C₁₀ heterocycloalkenyl group” as used herein refers to a monovalent monocyclic group that has at least one heteroatom selected from N, O, P, Si, and S as a ring-forming atom, 1 to 10 carbon atoms, and at least one carbon-carbon double bond in the ring thereof and no aromaticity. Examples of the C₁-C₁₀ heterocycloalkenyl group are a 2,3-dihydrofuranyl group, and a 2,3-dihydrothiophenyl group. The term “C₁-C₁₀ heterocycloalkenylene group” as used herein refers to a divalent group having the same structure as the C₁-C₁₀ heterocycloalkenyl group.

The term “C₆-C₆₀ aryl group” used herein refers to a monovalent carbocyclic group with at least one aromatic ring, the group having 6 to 60 carbon atoms, and a C₆-C₆₀ arylene group used herein refers to a divalent group having a carbocyclic aromatic system having 6 to 60 carbon atoms. Non-limiting examples of the C₆-C₆₀ aryl group include a phenyl group, a naphthyl group, an anthracenyl group, a phenanthrenyl group, a pyrenyl group, and a chrysenyl group. More than one ring may be present, and any additional rings may be independently aromatic, saturated or partially unsaturated, and may be fused, pendant, spirocyclic or a combination thereof. For example, when the C₆-C₆₀ aryl group and the C₆-C₆₀ arylene group each include two or more rings, the rings may be fused to each other. The term “C₇-C₆₀ alkylaryl group” used herein refers to a C₆-C₆₀ aryl group substituted with at least one C₁-C₆₀ alkyl group.

The term “C₁-C₆₀ heteroaryl group” as used herein refers to a monovalent carbocyclic ring group having one or more aromatic rings, in which at least one ring member is a heteroatom selected from N, O, P, Si, and S as a ring-forming atom, and 1 to 60 carbon atoms. The term “C₁-C₆₀ heteroarylene group,” as used herein refers to a divalent group having a heterocyclic aromatic system that has at least one heteroatom selected from N, O, P, Si, and S as a ring-forming atom, and 1 to 60 carbon atoms. Non-limiting examples of the C₁-C₆₀ heteroaryl group include a pyridinyl group, a pyrimidinyl group, a pyrazinyl group, a pyridazinyl group, a triazinyl group, a quinolinyl group, and an isoquinolinyl group. Multiple rings, if present, may be pendent, spiro or fused. For example, when the C₁-C₆₀ heteroaryl group and the C₁-C₆₀ heteroarylene group each include two or more rings, the rings may be fused to each other. The term “C₂-C₆₀ alkylheteroaryl group” used herein refers to a C₁-C₆₀ heteroaryl group substituted with at least one C₁-C₆₀ alkyl group.

The term “C₆-C₆₀ aryloxy group” used herein indicates —OA₁₀₂ (wherein A₁₀₂ is the C₆-C₆₀ aryl group), and a C₆-C₆₀ arylthio group used herein indicates —SA₁₀₃ (wherein A₁₀₃ is the C₆-C₆₀ aryl group).

The term “monovalent non-aromatic condensed polycyclic group” as used herein refers to a monovalent group (for example, having 8 to 60 carbon atoms) having two or more rings condensed to each other, having only carbon atoms as ring-forming atoms, and no aromaticity in its entire molecular structure. Examples of the monovalent non-aromatic condensed polycyclic group include a fluorenyl group. The term “divalent non-aromatic condensed polycyclic group” as used herein refers to a divalent group having the same structure as the monovalent non-aromatic condensed polycyclic group.

The term “monovalent non-aromatic condensed heteropolycyclic group” as used herein refers to a monovalent group (for example, having 2 to 60 carbon atoms) having two or more rings condensed to each other, a heteroatom selected from N, O, P, Si, and S as a ring-forming atom, and no aromaticity in its entire molecular structure. Non-limiting examples of the monovalent non-aromatic condensed heteropolycyclic group include a carbazolyl group. The term “divalent non-aromatic condensed heteropolycyclic group” as used herein refers to a divalent group having the same structure as the monovalent non-aromatic condensed heteropolycyclic group.

The term “C₅-C₃₀ carbocyclic group” as used herein refers to a saturated or unsaturated cyclic group having, as a ring-forming atoms, 5 to 30 carbon atoms. The term “C₅-C₃₀ carbocyclic group” as used herein refers to both a monocyclic group and a polycyclic group, and, according to its chemical structure, can be a monovalent, divalent, trivalent, tetravalent, pentavalent, or hexavalent group.

The term “C₂-C₃₀ heterocyclic group” as used herein refers to a saturated or unsaturated cyclic group having, as a ring-forming atom, at least one heteroatom selected from N, O, Si, P, and S and 2 to 30 carbon atoms. The term “C₂-C₃₀ heterocyclic group” as used herein refers to both a monocyclic group and a polycyclic group, and, according to its chemical structure, can be a monovalent, divalent, trivalent, tetravalent, pentavalent, or hexavalent group.

“S u bst ituted” means a compound or radical substituted with at least one (e.g., 1, 2, 3, 4, 5, 6 or more) substituent instead of hydrogen, provided that the substituted atom's normal valence is not exceeded. At least one substituent of the substituted C₅-C₃₀ carbocyclic group, the substituted C₂-C₃₀ heterocyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₇-C₆₀ alkylaryl group, the substituted C₆-C₆₀ aryloxy group, the substituted C₆-C₆₀ arylthio group, the substituted C₁-C₆₀ heteroaryl group, the substituted C₂-C₆₀ alkylheteroaryl group, the substituted monovalent non-aromatic condensed polycyclic group, and the substituted monovalent non-aromatic condensed heteropolycyclic group may be: deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, or a C₁-C₆₀ alkoxy group; a C₁-C₆₀ alkyl group, a C₂-C₆₀ alkenyl group, a C₂-C₆₀ alkynyl group, and a C₁-C₆₀ alkoxy group, each substituted with at least one selected from deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkylaryl group, a C₆-C₆₀ aryloxy group, a C₆-C₆₀ arylthio group, a C₁-C₆₀ heteroaryl group, a C₂-C₆₀ alkylheteroaryl group, a monovalent non-aromatic condensed polycyclic group, a monovalent non-aromatic condensed heteropolycyclic group, —N(Q₁₁)(Q₁₂), —Si(C₂₁₃)(Q₁₄)(Q₁₅), —B(Q₁₆)(Q₁₇), or —P(═O)(Q₁₈)(Q₁₉); a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkylaryl group, a C₆-C₆₀ aryloxy group, a C₆-C₆₀ arylthio group, a C₁-C₆₀ heteroaryl group, a C₂-C₆₀ alkylheteroaryl group, a monovalent non-aromatic condensed polycyclic group, or a monovalent non-aromatic condensed heteropolycyclic group; a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkylaryl group, a C₆-C₆₀ aryloxy group, a C₆-C₆₀ arylthio group, a C₁-C₆₀ heteroaryl group, a C₂-C₆₀ alkylheteroaryl group, a monovalent non-aromatic condensed polycyclic group, or a monovalent non-aromatic condensed heteropolycyclic group, each substituted with at least one of deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkylaryl group, a C₆-C₆₀ aryloxy group, a C₆-C₆₀ arylthio group, a C₁-C₆₀ heteroaryl group, a C₂-C₆₀ alkylheteroaryl group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —B(Q₂₆)(Q₂₇), or —P(═O)(Q₂₈)(Q₂₉), or —N(Q₃₁)(Q₃₂), —Si(Q₃₃)(Q₃₄)(Q₃₅), —B(Q₃₆)(Q₃₇), or —P(═O)(Q₃₈)(Q₃₉).

Q₁ to Q₉, Q₁₁ to Q₁₉, Q₂₁ to Q₂₉, and Q₃₁ to Q₃₉ may each independently be hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, or a C₆-C₆₀ aryl group substituted with at least of a C₁-C₆₀ alkyl group and a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, or a monovalent non-aromatic condensed heteropolycyclic group.

As used herein, when a definition is not otherwise provided, the term “amino group” refers to —NRR′ wherein R and R′ are independently hydrogen, a C₁-C₂₀ alkyl group, or a C₆-C₃₀ aryl group.

Hereinafter, a compound and an organic light-emitting device according to embodiments are described in more detail with reference to Synthesis Examples and Examples. However, such embodiments are provided for illustrative purposes only, and the scope of the organic light-emitting devices is not limited thereto in any manner. Further, it should be understood that the present disclosure is not limited to the above descriptions since other various modifications of the present disclosure may be apparent to persons having ordinary knowledge in the related art pertinent to the present disclosure.

### EXAMPLES

The term “B was used instead of A” used in describing the Synthesis Examples means that an identical molar equivalent of component B was used in place of component A.

### Synthesis Example 1: Synthesis of Compound D1

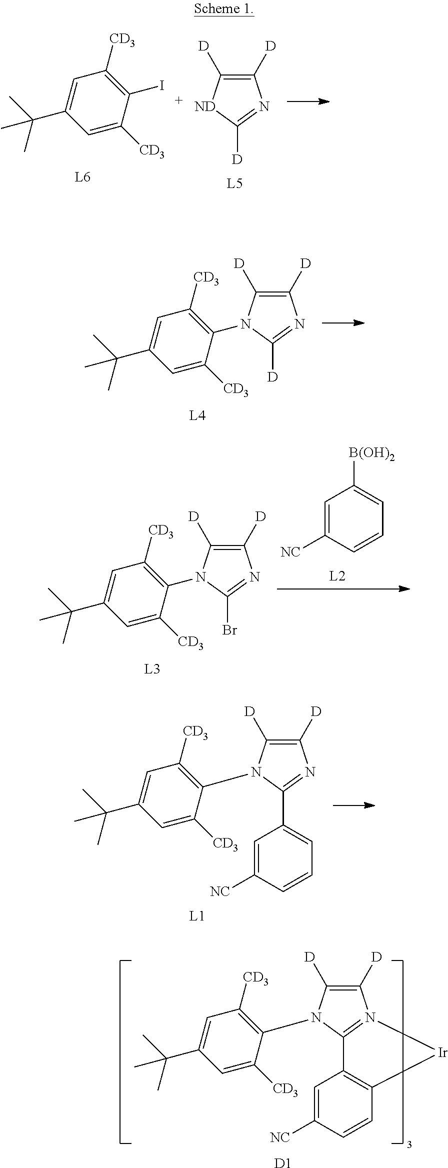

The overall synthesis of compound D1 is shown in Scheme 1.

### (1) Synthesis of Compound L₄

Compound L₆ (34.70 mmol), Compound L₅ (41.64 mmol), K₂CO₃ (173.51 mmol), CuI (1.74 mmol), 1,10-phenanthroline (3.47 mmol), and 500 mL of DMF were added to a 1-L reaction vessel and then heated at reflux for 12 hours in a nitrogen atmosphere. After the reaction was completed (i.e., after heating at reflux for 12 hours), the mixture was cooled to room temperature, and dichloromethane and deionized water were added thereto to separate an organic layer. The separated organic layer was washed twice by using deionized water and dried by using MgSO₄. Then, a solvent was removed therefrom. A crude product was purified by silica gel column chromatography (eluent: ethyl acetate and n-hexane) to obtain Compound L₄ (26.37 mmol). The obtained Compound L₄ was identified by liquid chromatography-mass spectrometry (LC-MS). LC-MS (m/z): 237.22 [M+1].

### (2) Synthesis of Compound L₃

Compound L₄ (26.37 mmol) and tetrahydrofuran (THF) were added to a reaction vessel and cooled to a temperature of −78° C. in a nitrogen atmosphere. n-BuLi (2.5 M in n-hexane, 27.69 mmol) was slowly added thereto and stirred at a temperature of −78° C. After stirring for 1 hour, Br₂ (52.74 mmol) was slowly added thereto at a temperature of −78° C. After 30 minutes, a cooler was removed, and the temperature of the mixture was raised. Then, the mixture was stirred at room temperature for 6 hours. After the reaction was completed, dichloromethane and deionized water were added thereto to separate an organic layer. The separated organic layer was washed twice by using deionized water and dried by using MgSO₄. Then, a solvent was removed therefrom. A crude product was purified by silica gel column chromatography (eluent: ethyl acetate and n-hexane) to obtain Compound L₃ (18.72 mmol). The obtained Compound L₃ was identified by LC-MS. LC-MS (m/z): 314.12 [M+1].

### (3) Synthesis of Compound L₁

Compound L₃ (18.72 mmol), Compound L₂ (28.08 mmol), Pd(PPh₃)₄ (1.87 mmol), K₂CO₃ (210.63 mmol), and THF:deionized water (=2:1) were added to a reaction vessel and then heated at reflux for 12 hours in a nitrogen atmosphere. After the reaction was completed, the mixture was cooled to room temperature, and dichloromethane and distilled water were added thereto to separate an organic layer. The separated organic layer was washed twice by using deionized water and dried by using MgSO₄. Then, a solvent was removed therefrom. A crude product was purified by silica gel column chromatography (eluent: ethyl acetate and n-hexane) to obtain Compound L₁ (16.47 mmol). The obtained Compound L₁ was identified by LC-MS. LC-MS (m/z): 337.24 [M±1].

### (4) Synthesis of Compound D1

Ir(acac)₃ (3.29 mmol), Compound L₁ (16.47 mmol), and glycerol were added to a reaction vessel and then heated at reflux for 12 hours in a nitrogen atmosphere. After the reaction was completed, the mixture was cooled to room temperature, and dichloromethane and deionized water were added thereto to separate an organic layer. The separated organic layer was washed twice by using deionized water and dried by using MgSO₄. Then, a solvent was removed therefrom. A crude product was purified by silica gel column chromatography (eluent: dichloromethane and n-hexane) to obtain Compound D1 (0.49 mmol). The obtained Compound D1 was identified by matrix assisted laser desorption ionization-time of flight mass spectrometry (MALDI-TOF/MS). MALDI-TOF/MS (m/z): 529.19 [M]+.

Evaluation Example 1: Measurement of dipole moment

A distance between atoms and Mulliken charge of each atom of Compounds E2-1 and A was obtained by using a density functional theory (DFT) method of a Gaussian program structurally optimized at a level of B3LYP, 6-31G(d,p)) and dipole moments (debyes, D) of Compounds E2-1 and A were calculated. Results thereof are shown in Table 1.

TABLE 1

| Compound No. | Dipole moment (D) |
|---|---|
| E2-1 | 3.79 |
| A | 2.66 |

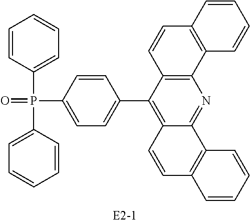 [SMILES: O=P(c1ccccc1)(c1ccccc1)c1ccc(-c2c3ccc4ccccc4c3nc3c2ccc2ccccc23)cc1 ; "E2-1"]

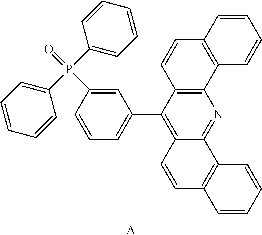

From Table 1, it is confirmed that Compound E2-1 has a higher dipole moment than that of Compound A.

### Comparative Example 1

A glass substrate, on which an Indium tin oxide (ITO) electrode (first electrode, anode) was formed to a thickness of 1500 Å, was cleaned by deionized water ultrasonic waves. After the deionized water cleaning was completed, isopropyl alcohol, acetone, and methanol were sequentially used to perform ultrasonic wave cleaning. Then, the glass substrate was dried and transferred to a plasma cleaner. Then, the glass substrate was cleaned for 5 minutes by using oxygen plasma and transferred to a vacuum deposition apparatus.

Compound HT21 was vacuum-deposited on the ITO electrode of the glass substrate to form a first hole injection layer having a thickness of 350 nm, Compound HT-D1 was vacuum-deposited on the first hole injection layer to form a second hole injection layer having a thickness of 30 nm, TAPC was vacuum-deposited on the second hole injection layer to form an electron blocking layer having a thickness of 10 nm, thereby forming a hole transport region.

Compound H12 (first material), Compound E4 (second material), and Compound D1 (light-emitting material) were co-deposited on the hole transport region, so that i) an amount of the light-emitting material was 1 weight percent (wt %) based on 100 wt % of the emission layer, and ii) a weight ratio of the first material to the second material was 5:5, thereby forming an emission layer having a thickness of 30 nm.

Compound mCP was vacuum-deposited on the emission layer to form a hole blocking layer having a thickness of 10 nm, Compound E1-1 and ET-D1 (LiQ) were co-deposited on the hole blocking layer at a weight ratio of 45:55 to form an electron transport layer having a thickness of 30 nm, LiQ was deposited on the electron transport layer to form an electron injection layer having a thickness of 0.5 nm, Al was deposited on the electron injection layer to form an Al second electrode (cathode) having a thickness of 100 nm, thereby completing the manufacture of an organic light-emitting device.

The structures of the compounds are as follows:

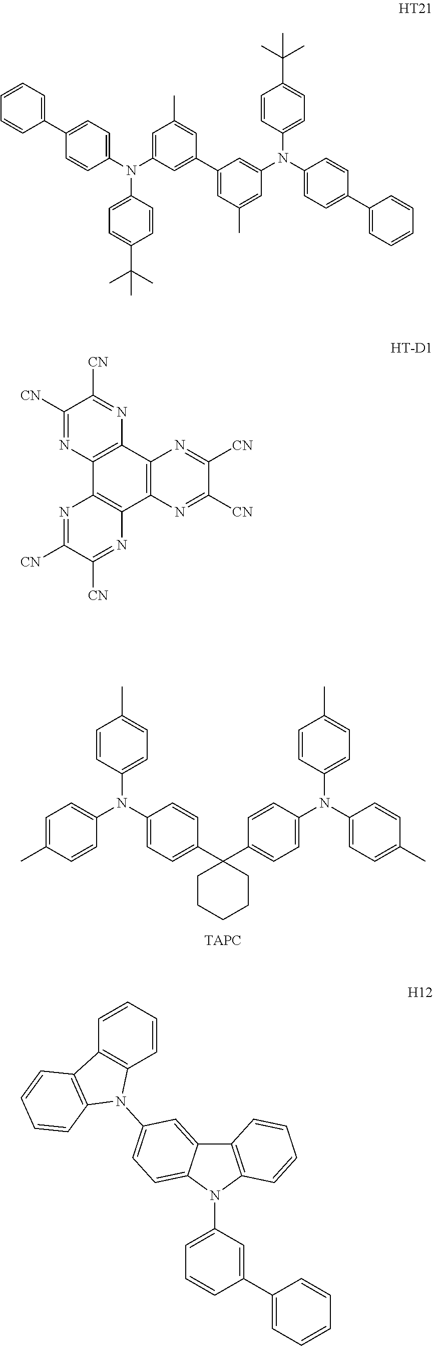

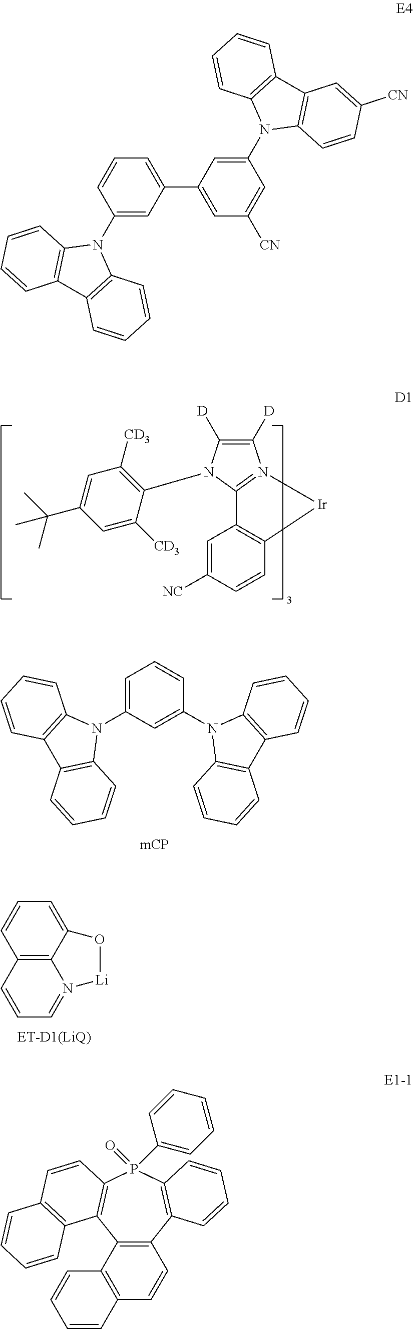

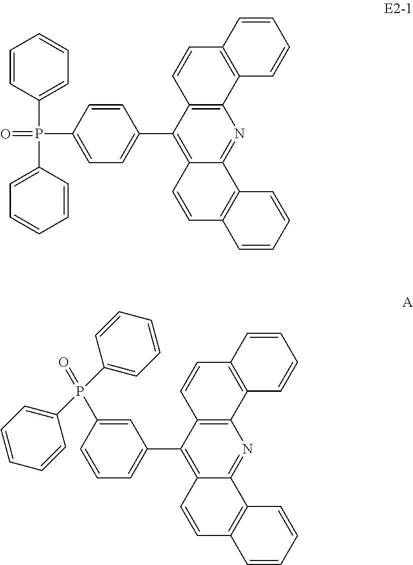 [SMILES: O=P(c1ccccc1)(c1ccccc1)c1ccc(-c2c3ccc4ccccc4c3nc3c2ccc2ccccc23)cc1 ; O=P(c1ccccc1)(c1ccccc1)c1cccc(-c2c3ccc4ccccc4c3nc3c2ccc2ccccc23)c1]

### Comparative Example 2

An organic light-emitting device was manufactured in the same manner as in Comparative Example 1, except that Compound E1-1 and LiQ were co-deposited on an emission layer at a weight ratio of 40:60 to form an electron transport layer having a thickness of 40 nm, without forming a hole blocking layer.

### Comparative Example 3

An organic light-emitting device was manufactured in the same manner as in Comparative Example 1, except that an electron transport layer was formed by co-depositing Compound E1-1 and LiQ on an emission layer at a weight ratio of 40:60 to form a first electron transport layer having a thickness of 10 nm and co-depositing Compound A and LiQ on the first electron transport layer at a weight ratio of 50:50 to form a second electron transport layer having a thickness of 30 nm, without forming a hole blocking layer.

### Comparative Example 4

An organic light-emitting device was manufactured in the same manner as in Comparative Example 1, except that Compound E2-1 and LiQ were co-deposited on an emission layer at a weight ratio of 50:50 to form an electron transport layer having a thickness of 40 nm, without forming a hole blocking layer.

### Example 1

An organic light-emitting device was manufactured in the same manner as in Comparative Example 1, except that an electron transport layer was formed by co-depositing Compound E1-1 and LiQ on an emission layer at a weight ratio of 45:55 to form a first electron transport layer having a thickness of 10 nm, and co-depositing Compound E2-1 and LiQ on the electron transport layer at a weight ratio of 50:50 to form a second electron transport layer having a thickness of 30 nm, without forming a hole blocking layer.

### Example 2

An organic light-emitting device was manufactured in the same manner as in Example 1, except that a weight ratio of Compound E1-1 and LiQ was changed to 40:60 in forming a first electron transport layer.

### Example 3

An organic light-emitting device was manufactured in the same manner as in Example 1, except that a weight ratio of Compound E1-1 and LiQ was changed to 30:70 in forming a first electron transport layer.

### Example 4

An organic light-emitting device was manufactured in the same manner as in Comparative Example 1, except that an electron transport layer was formed by co-depositing Compound E1-1 and LiQ on a hole blocking layer at a weight ratio of 40:60 to form a first electron transport layer having a thickness of 10 nm, and co-depositing Compound E2-1 and LiQ on the first electron transport layer at a weight ratio of 50:50 to form a second electron transport layer having a thickness of 20 nm.

### Evaluation Example 2: Evaluation of Characteristics of Organic Light-Emitting Device

The lifespan (T95, %) of each of the organic light-emitting devices manufactured according to Comparative Examples 1 to 4 and Examples 1 to 4 was evaluated, and results thereof are shown in Table 2. The lifespan was measured at 1,000 candela per square meter (cd/m²) of luminance and indicates an amount of time that elapsed to when luminance was 95% of initial luminance (100%), and was evaluated by using a luminance meter (Minolta Cs-1000A). Lifespan is reported as a relative value with respect to the lifespan of Comparative Example 2 (i.e., the lifespan of Comparative Example 2 is 100%).

TABLE 2

| | Hole | Electron transport layer(s) | | |
|---|---|---|---|---|
| | blocking | First electron | Second electron | Lifespan |
| | layer | transport layer | transport layer | (%) |
| Comparative | mCP | E1-1:LiQ^{†} (45:55)^{‡} | | 112 |
| Example 1 | (10 nm)* | (30 nm)* | | |
| Comparative | — | E1-1:LiQ^{†} (40:60) | | 100 |
| Example 2 | | (40 nm) | | |
| Comparative | — | E1-1:LiQ (40:60) | A:LiQ (50:50) | 150 |
| Example 3 | | (10 nm) | (30 nm) | |
| Comparative | — | E2-1:LiQ^{†} (50:50) | | 107 |
| Example 4 | | (40 nm) | | |
| Example 1 | — | E1-1:LiQ (45:55) | E2-1:LiQ (50:50) | 179 |
| | | (10 nm) | (30 nm) | |
| Example 2 | — | E1-1:LiQ (40:60) | E2-1:LiQ (50:50) | 284 |
| | | (10 nm) | (30 nm) | |
| Example 3 | — | E1-1:LiQ (30:70) | E2-1:LiQ (50:50) | 566 |
| | | (10 nm) | (30 nm) | |
| Example 4 | mCP | E1-1:LiQ (40:60) | E2-1:LiQ (50:50) | 286 |
| | (10 nm) | (10 nm) | (20 nm) | |

^{†}Comparative Examples 1, 2, and 4 each have a single electron transport layer.
^{‡}Indicates the weight ratio of E1-1 to LiQ in Comparative Example 1 and 2 and for the first electron transport layer in Comparative Example 3 and Examples 1 to 4;
similar notation is used for the weight ratio of A to LiQ for the second electron transport layer in Comparative Example 3 and the weight ratio of E2-1 to LiQ for the second electron transport layer in Examples 1 to 4.
*Indicates the thickness of the layer.

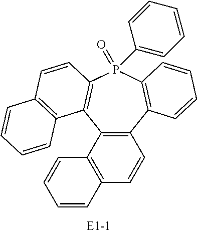 [SMILES: O=P1(c2ccccc2)c2ccccc2-c2ccc3ccccc3c2-c2c1ccc1ccccc21]

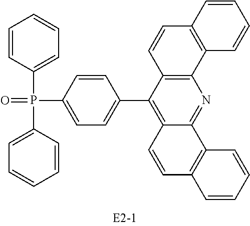 [SMILES: O=P(c1ccccc1)(c1ccccc1)c1ccc(-c2c3ccc4ccccc4c3nc3c2ccc2ccccc23)cc1]

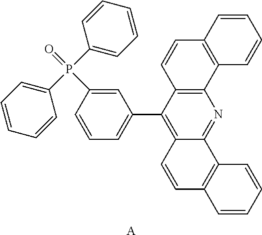

Referring to Table 2, it is confirmed that Examples 1 to 4 have excellent lifespan characteristics, as compared with Comparative Examples 1 to 4.

As described above, an organic light-emitting device according to one or more of the above embodiments includes i) an electron transport layer including a first electron transport layer and a second electron transport layer, and ii) the second electron transport layer includes a second metal-free compound represented by Formula 2, thereby achieving a long lifespan.

It should be understood that exemplary embodiments described herein should be considered in a descriptive sense and not for purposes of limitation. Descriptions of features or aspects within each embodiment should be considered as available for other similar features or aspects in other exemplary embodiments.

While one or more exemplary embodiments have been described with reference to the figures, it will be understood by those of ordinary skill in the art that various changes in form and details may be made therein without departing from the spirit and scope of the present disclosure as defined by the following claims.

What is claimed is:

1. An organic light-emitting device comprising:
a first electrode;
a second electrode facing the first electrode; and
an organic layer disposed between the first electrode and the second electrode,
wherein the organic layer comprises an emission layer and an electron transport layer disposed between the emission layer and the second electrode,
the electron transport layer comprises a first electron transport layer disposed between the emission layer and the second electrode and a second electron transport layer disposed between the first electron transport layer and the second electrode,
the first electron transport layer comprises a first metal-free compound,
the second electron transport layer comprises a second metal-free compound,
the first metal-free compound and the second metal-free compound are different from each other, and
the second metal-free compound is represented by Formula 2: 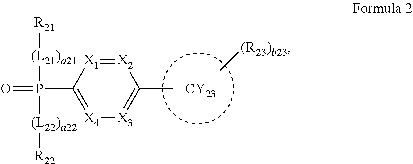
wherein, in Formula 2,
ring CY₂₃ is a pi electron-depleted nitrogen-containing C₁-C₃₀ cyclic group,
X₁ is N or C(R₁), X₂ is N or C(R₂), X₃ is N or C(R₃), and X₄ is N or C(R₄),
each occurrence of L₂₁ and L₂₂ is the same or different, and are each independently a single bond, a substituted or unsubstituted C₅-C₃₀ carbocyclic group, or a substituted or unsubstituted C₁-C₃₀ heterocyclic group,
a21 and a22 are each independently an integer from 1 to 10,
R₁ to R₄, R₂₁, and R₂₂ are each independently hydrogen, deuterium, —F, —Cl, —Br, —I, —SF₅, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkylaryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkylheteroaryl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —B(Q₆)(Q₇), or —P(═O)(Q₈)(Q₉),
each occurrence of R₂₃ is the same or different, and is hydrogen, deuterium, —F, —Cl, —Br, —I, —SF₅, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkylaryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkylheteroaryl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —B(Q₆)(Q₇), or —P(═O)(Q₈)(Q₉),
b23 is an integer from 0 to 20,
R₁ and R₂ are optionally linked to form a substituted or unsubstituted C₅-C₃₀ carbocyclic group or a substituted or unsubstituted C₁-C₃₀ heterocyclic group,
R₃ and R₄ are optionally linked to form a substituted or unsubstituted C₅-C₃₀ carbocyclic group or a substituted or unsubstituted C₁-C₃₀ heterocyclic group,
at least one substituent of the substituted C₅-C₃₀ carbocyclic group, the substituted C₁-C₃₀ heterocyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₇-C₆₀ alkylaryl group, the substituted C₆-C₆₀ aryloxy group, the substituted C₆-C₆₀ arylthio group, the substituted C₁-C₆₀ heteroaryl group, the substituted C₂-C₆₀ alkylheteroaryl group, the substituted monovalent non-aromatic condensed polycyclic group, and the substituted monovalent non-aromatic condensed heteropolycyclic group, when present, is:
deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, or a C₁-C₆₀ alkoxy group;
a C₁-C₆₀ alkyl group, a C₂-C₆₀ alkenyl group, a C₂-C₆₀ alkynyl group, and a C₁-C₆₀ alkoxy group, each substituted with at least one selected from deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkylaryl group, a C₆-C₆₀ aryloxy group, a C₆-C₆₀ arylthio group, a C₁-C₆₀ heteroaryl group, a C₂-C₆₀ alkylheteroaryl group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —B(Q₁₆)(Q₁₇), or —P(═O)(Q₁₈)(Q₁₉);
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkylaryl group, a C₆-C₆₀ aryloxy group, a C₆-C₆₀ arylthio group, a C₁-C₆₀ heteroaryl group, a C₂-C₆₀ alkylheteroaryl group, a monovalent non-aromatic condensed polycyclic group, or a monovalent non-aromatic condensed heteropolycyclic group;
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkylaryl group, a C₆-C₆₀ aryloxy group, a C₆-C₆₀ arylthio group, a C₁-C₆₀ heteroaryl group, a C₂-C₆₀ alkylheteroaryl group, a monovalent non-aromatic condensed polycyclic group, or a monovalent non-aromatic condensed heteropolycyclic group, each substituted with at least one selected from deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkylaryl group, a C₆-C₆₀ aryloxy group, a C₆-C₆₀ arylthio group, a C₁-C₆₀ heteroaryl group, a C₂-C₆₀ alkylheteroaryl group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —B(Q₂₆)(Q₂₇), or —P(═O)(Q₂₈)(Q₂₉); or
—N(Q₃₁)(Q₃₂), —Si(Q₃₃)(Q₃₄)(Q₃₅), —B(Q₃₆)(Q₃₇), or —P(═O)(Q₃₈)(Q₃₉), and
Q₁ to Q₉, Q₁₁ to Q₁₉, Q₂₁ to Q₂₉, and Q₃₁ to Q₃₉ are each independently hydrogen, deuterium, —F, —Cl, —Br, —I, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryl group substituted with at least one of a C₁-C₆₀ alkyl group and a C₆-C₆₀ aryl group, a C₆-C₆₀ aryloxy group, a C₆-C₆₀ arylthio group, a C₁-C₆₀ heteroaryl group, a C₂-C₆₀ alkylheteroaryl group, a monovalent non-aromatic condensed polycyclic group, or a monovalent non-aromatic condensed heteropolycyclic group.

2. The organic light-emitting device of claim 1, wherein
ring CY₂₃ is i) a first ring, ii) a condensed ring in which two or more first rings are condensed with each other, or iii) a condensed ring in which at least one first ring and at least one second ring are condensed with each other,
the first ring is an imidazole group, a pyrazole group, a thiazole group, an isothiazole group, an oxazole group, an isoxazole group, a pyridine group, a pyrazine group, a pyridazine group, a pyrimidine group, an indazole group, a purine group, a quinoline group, an isoquinoline group, a benzoquinoline group, a benzoisoquinoline group, a phthalazine group, a naphthyridine group, a quinoxaline group, a benzoquinoxaline group, a quinazoline group, a cinnoline group, a phenanthridine group, a phenanthroline group, a phenazine group, a benzimidazole group, an iso-benzothiazole group, a benzoxazole group, an isobenzoxazole group, a triazole group, a tetrazole group, an oxadiazole group, a triazine group, a thiadiazole group, an imidazopyridine group, an imidazopyrimidine group, an azaindene group, an azaindole group, an azabenzofuran group, an azabenzothiophene group, an azabenzosilole group, an azafluorene group, an azacarbazole group, an azadibenzofuran group, an azadibenzothiophene group, or an azadibenzosilole group, and
the second ring is a benzene group, a heptalene group, an indene group, a naphthalene group, an azulene group, a heptalene group, an indacene group, an acenaphthylene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentacene group, a hexacene group, a pentaphene group, a rubicen group, a coronen group, an ovalene group, a pyrrole group, an iso-indole group, an indole group, a furan group, a thiophene group, a benzofuran group, a benzothiophene group, a benzosilole group, a benzocarbazole group, a dibenzocarbazole group, a dibenzofuran group, a dibenzothiophene group, a dibenzothiophene sulfone group, a carbazole group, a dibenzosilole group, an indeno carbazole group, an indolocarbazole group, a benzofurocarbazole group, a benzothienocarbazole group, a benzosilolocarbazole group, a triindolobenzene group, an acridine group, or a dihydroacridine group.

3. The organic light-emitting device of claim 1, wherein
the second metal-free compound is represented by one of Formulae 2-1 to 2-10: 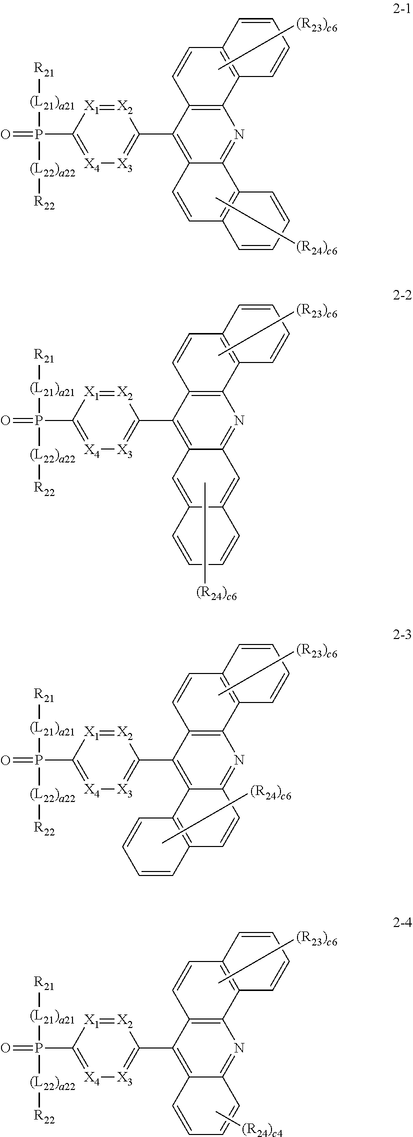 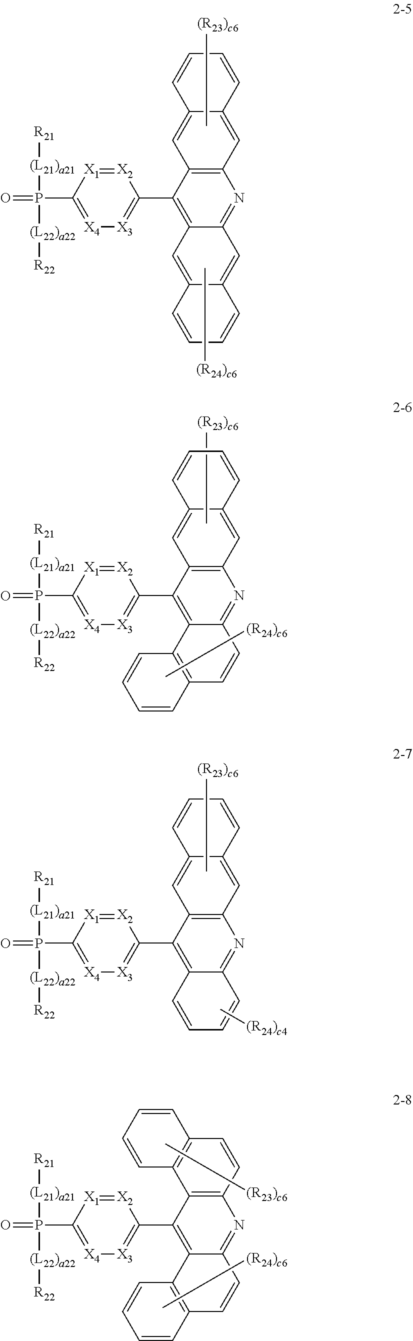 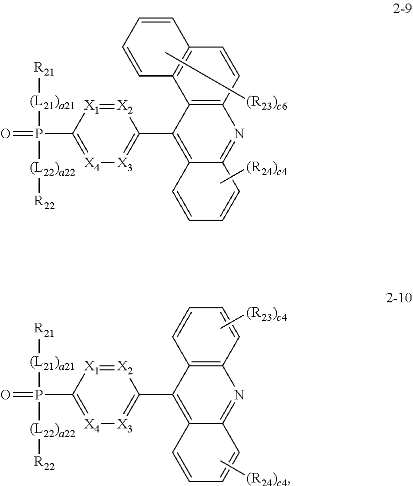
wherein, in Formulae 2-1 to 2-10, X₁ to X₄, L₂₁, L₂₂, a21, a22, and R₂₁ to R₂₃ are the same as described in claim 1, R₂₄ is the same as described in connection with R₂₃ in claim 1, c6 is an integer from 0 to 6, and c4 is an integer from 0 to 4.

4. The organic light-emitting device of claim 1, wherein
the second metal-free compound has a dipole moment of about 3.0 D or more.

5. The organic light-emitting device of claim 1, wherein
a dipole moment of the second metal-free compound is greater than a dipole moment of the first metal-free compound.

6. The organic light-emitting device of claim 1, wherein
the first metal-free compound is represented by Formula 1: 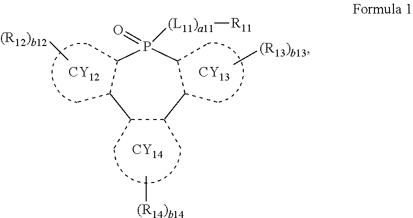
wherein, in Formula 1,
rings CY₁₂ to CY₁₄ are each independently a C₅-C₃₀ carbocyclic group or a C₁-C₃₀ heterocyclic group,
each occurrence of L₁₁ is the same or different, and is independently a single bond, a substituted or unsubstituted C₅-C₃₀ carbocyclic group, or a substituted or unsubstituted C₁-C₃₀ heterocyclic group,
a₁₁ is an integer from 1 to 10,
R₁₁ to R₁₄ are each independently hydrogen, deuterium, —F, —Cl, —Br, —I, —SF₅, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkylaryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkylheteroaryl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —B(Q₆)(Q₇), or —P(═O)(Q₈)(Q₉),
Q₁ to Q₉ are each independently hydrogen, deuterium, —F, —Cl, —Br, —I, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryl group substituted with at least one of a C₁-C₆₀ alkyl group and a C₆-C₆₀ aryl group, a C₆-C₆₀ aryloxy group, a C₆-C₆₀ arylthio group, a CI-Coo heteroaryl group, a C₂-C₆₀ alkylheteroaryl group, a monovalent non-aromatic condensed polycyclic group, or a monovalent non-aromatic condensed heteropolycyclic group, and
b12 to b14 are each independently an integer from 0 to 20.

7. The organic light-emitting device of claim 1, wherein
the first metal-free compound is represented by one of Formulae 1-1 to 1-16: 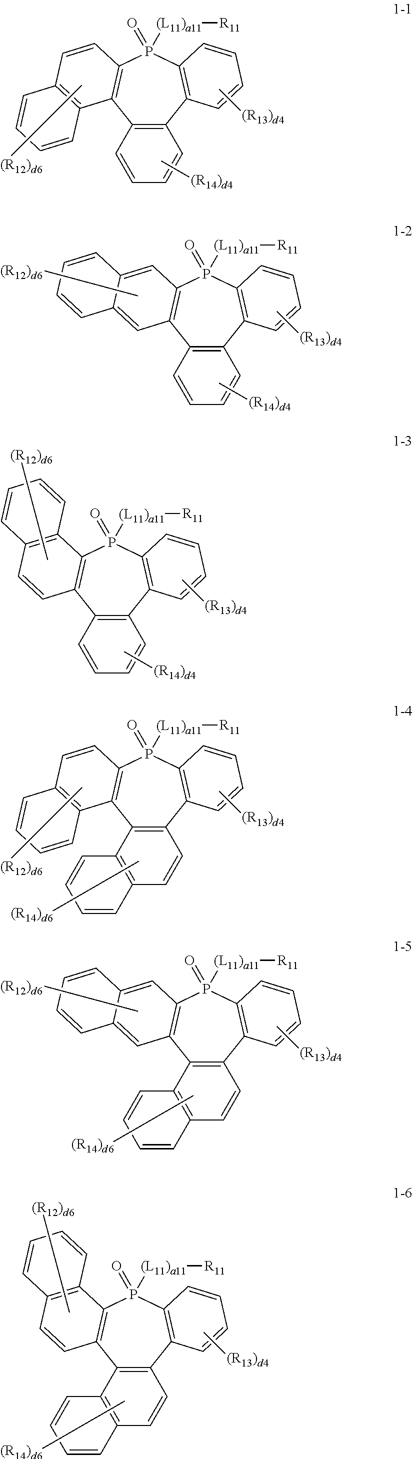 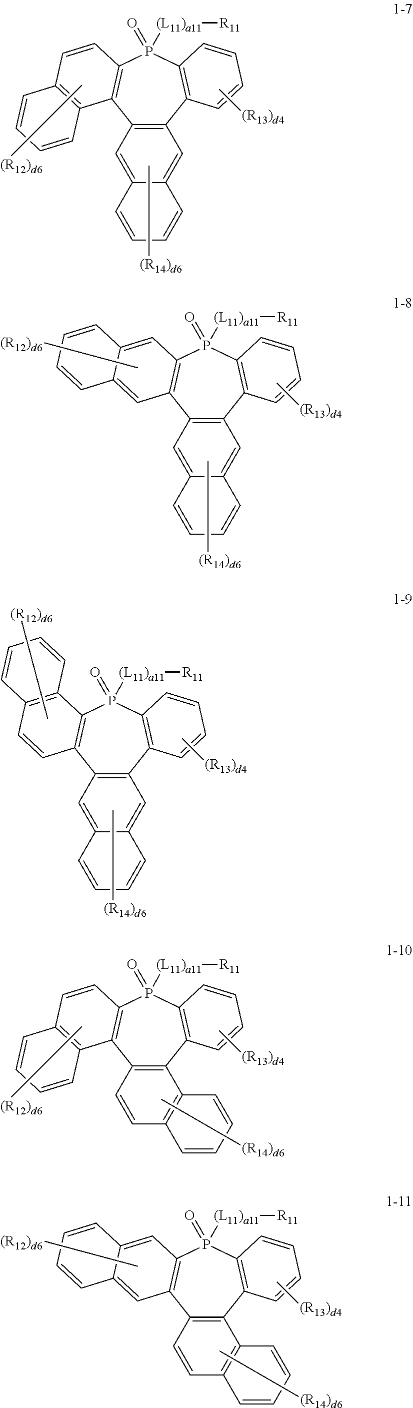 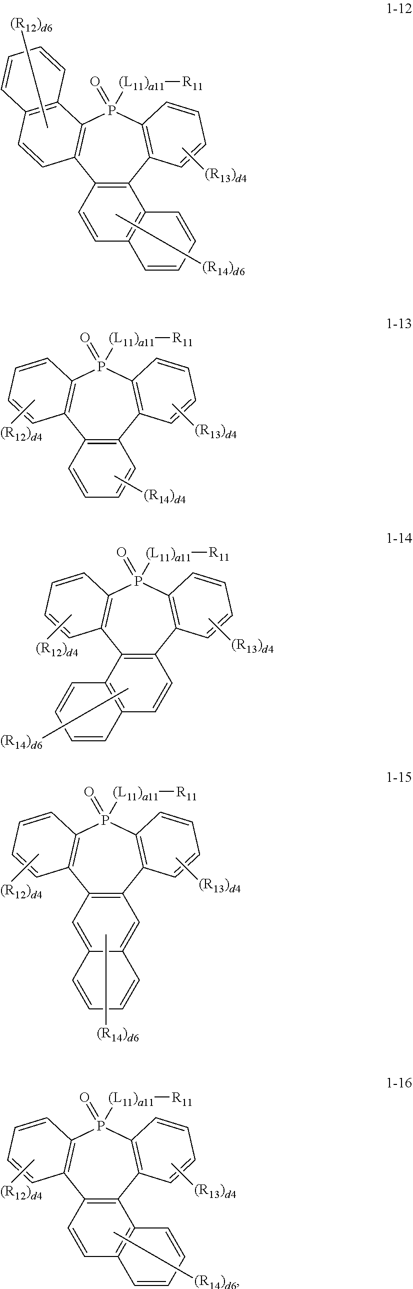
wherein, in Formulae 1-1 to 1-16,
each occurrence of L₁₁ is the same or different, and is a single bond, a substituted or unsubstituted C₅-C₃₀ carbocyclic group, or a substituted or unsubstituted C₁-C₃₀ heterocyclic group,
a₁₁ is an integer from 1 to 10,
each occurrence of R₁₁ to R₁₄ are the same or different, and are each independently hydrogen, deuterium, —F, —Cl, —Br, —I, —SF₅, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkylaryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkylheteroaryl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —B(Q₆)(Q₇), or —P(═O)(Q₈)(Q₉),
Q₁ to Q₉ are each independently hydrogen, deuterium, —F, —Cl, —Br, —I, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryl group substituted with at least one of a C₁-C₆₀ alkyl group and a C₆-C₆₀ aryl group, a C₆-C₆₀ aryloxy group, a C₆-C₆₀ arylthio group, a CI-Coo heteroaryl group, a C₂-C₆₀ alkylheteroaryl group, a monovalent non-aromatic condensed polycyclic group, or a monovalent non-aromatic condensed heteropolycyclic group,
d6 is an integer from 0 to 6, and
d4 is an integer from 0 to 4.

8. The organic light-emitting device of claim 1, wherein at least one of
the first electron transport layer further comprises a first metal-containing compound, or
the second electron transport layer further comprises a second metal-containing compound.

9. The organic light-emitting device of claim 8, wherein
the first metal-containing compound and the second metal-containing compound are each independently a metal halide, a compound represented by Formulae 5-1 to 5-3, or a compound having a moiety represented by one of Formulae 5-1 to 5-3, wherein a metal of the metal halide is an alkali metal or an alkaline earth metal: 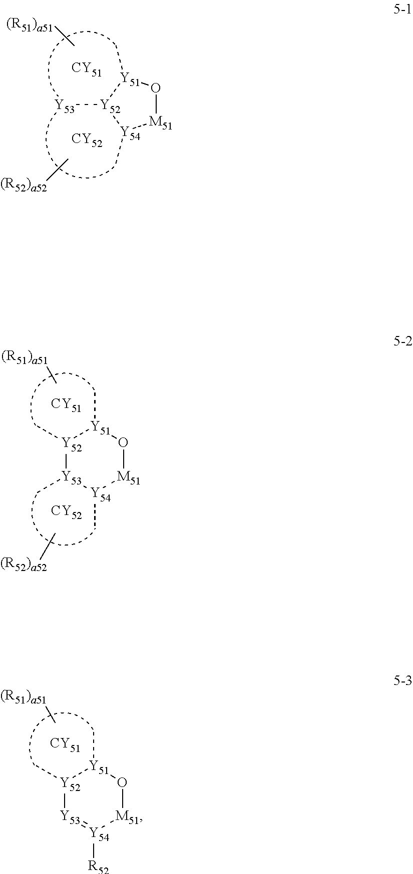
wherein, in Formulae 5-1 to 5-3,
M₅₁ is an alkali metal or an alkaline earth metal,
rings CY₅₁ and CY₅₂ are each independently a C₅-C₃₀ carbocyclic group or a C₁-C₃₀ heterocyclic group,
Y₅₁ is C,
Y₅₂ and Y₅₃ are each independently N or C,
Y₅₄ is N,
each occurrence of R₅₁ and R₅₂ are the same or different, and are each independently hydrogen, deuterium, —F, —Cl, —Br, —I, —SF₅, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkylaryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkylheteroaryl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —B(Q₆)(Q₇), or —P(═O)(Q₈)(Q₉), and
a51 and a52 are each independently an integer from 0 to 20.

10. The organic light-emitting device of claim 8, wherein
the first metal-containing compound and the second metal-containing compound are identical to each other.

11. The organic light-emitting device of claim 8, wherein
an amount of the first metal-containing compound based on 100 parts by weight of the first electron transport layer is different from an amount of the second metal-containing compound based on 100 parts by weight of the second electron transport layer.

12. The organic light-emitting device of claim 1, wherein

|LUMO(ETL2)|>|LUMO(ETL1)| is satisfied,

|LUMO(ETL1)| is an absolute value of a lowest unoccupied molecular orbital (LUMO) energy level (eV) of the first electron transport layer,

|LUMO(ETL2)| is an absolute value of a LUMO energy level (eV) of the second electron transport layer, and
LUMO(ETL1) and LUMO(ETL2) are determined by using a density functional theory method.

13. The organic light-emitting device of claim 1, wherein
the first electron transport layer directly contacts the second electron transport layer.

14. The organic light-emitting device of claim 1, wherein
the emission layer comprises a first material, a second material, and a light-emitting material,
the first material does not comprise an electron transport moiety, and
the second material comprises at least one electron transport moiety.

15. The organic light-emitting device of claim 14, wherein
the first material comprises at least one pi electron-depleted nitrogen-free cyclic group,
the second material comprises at least one pi electron-depleted nitrogen-free cyclic group and at least one electron transport moiety, and
the at least one electron transport moiety is a cyano group, a pi electron-depleted nitrogen-containing cyclic group, or a group represented by one of the Formulae provided below: 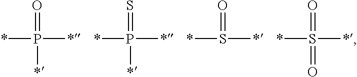
wherein *, *′, and *″ in the Formulae above each indicate a binding site to a neighboring atom.

16. The organic light-emitting device of claim 14, wherein
the first material comprises at least one of a compound represented by Formula H-1(1), a compound represented by Formula H-1(2), or a compound represented by Formula H-1(3): 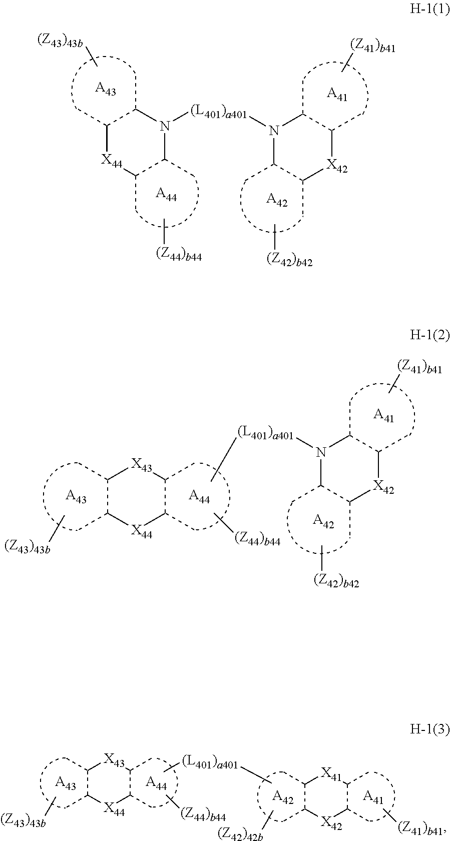
wherein, in Formulae H-1(1) to H-1(3),
rings A₄₁ to A₄₄ are each independently a benzene group, a naphthalene group, an indene group, an indole group, a benzofuran group, a benzothiophene group, a benzosilole group, a fluorene group, a carbazole group, a dibenzofuran group, a dibenzothiophene group, or a dibenzosilole group,
X₄₁ is N—[(L₄₁₁)_{c411}-Z₄₁₁], C(Z₄₁₅)(Z₄₁₆), O, or S,
X₄₂ is a single bond, N-[(L₄₁₂)_{c412}-Z₄₁₂], C(Z₄₁₇)(Z₄₁₈), O, or S,
X₄₃ is N-[(L₄₁₃)_{c413}-Z₄₁₃], C(Z₄₁₉)(Z₄₂₀), O, or S,
X₄₄ is a single bond, N-[(L₄₁₄)_{c414}-Z₄₁₄], C(Z₄₂₁)(Z₄₂₂), O, or S,
each occurrence of L₄₀₁ and L₄₁₁ to L₄₁₄ are the same or different, and are each independently:
a single bond; or
a pi electron-depleted nitrogen-free cyclic group, which is unsubstituted or substituted with at least one selected from deuterium, a C₁-C₁₀ alkyl group, a C₁-C₁₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, a tetraphenyl group, or —Si(Q₄₀₁)(Q₄₀₂)(Q₄₀₃),
a401 and c411 to c414 are each independently an integer from 1 to 10, wherein, when a401 is two or more, two or more of L₄₀₁ are identical to or different from each other, when c411 is two or more, two or more of L₄₁₁ are identical to or different from each other, when c412 is two or more, two or more of L₄₁₂ are identical to or different from each other, when c413 is two or more, two or more of L₄₁₃ are identical to or different from each other, and when c414 is two or more, two or more of L₄₁₄ are identical to or different from each other,
each occurrence of Z₄₁ to Z₄₄ and Z₄₁₁ to Z₄₂₂ are the same or different, and are each independently:
hydrogen, deuterium, a C₁-C₁₀ alkyl group, or a C₁-C₁₀ alkoxy group; or
a pi electron-depleted nitrogen-free cyclic group, which is unsubstituted or substituted with at least one of deuterium, a C₁-C₁₀ alkyl group, a C₁-C₁₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, a tetraphenyl group, or —Si(Q₄₀₁)(Q₄₀₂)(Q₄₀₃),
b41 to b44 are each independently 1, 2, 3, or 4, and
Q₄₀₁ to Q₄₀₃ are each independently hydrogen, deuterium, a C₁-C₁₀ alkyl group, a alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, or a tetraphenyl group.

17. The organic light-emitting device of claim 14, wherein
the second material comprises at least one cyano group.

18. The organic light-emitting device of claim 14, wherein
the second material comprises at least one of a compound represented by Formula E-1(1), a compound represented by Formula E-1(2), or a compound represented by Formula E-1(3): 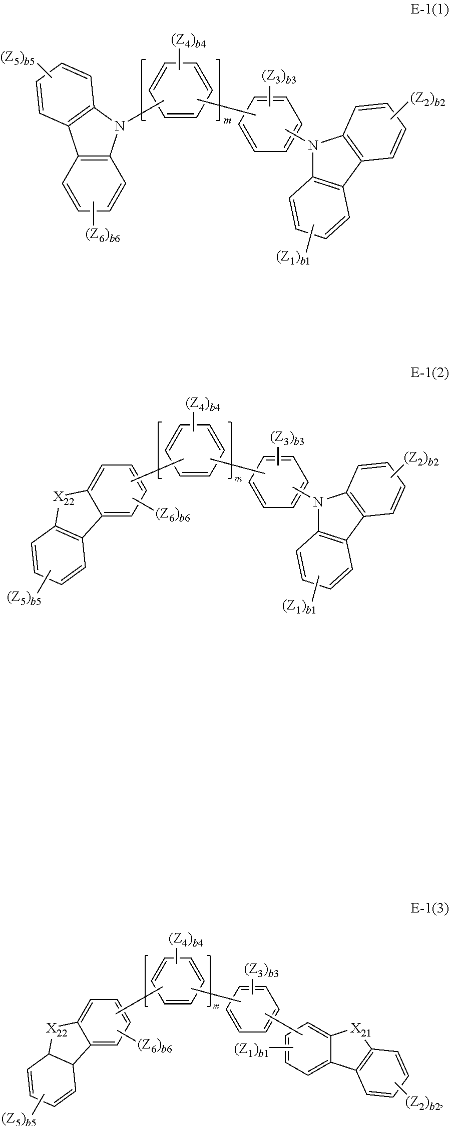
wherein, in Formulae E-1(1) to E-1(3),
X₂₁ is N(Z₇), O, or S,
X₂₂ is N(Z₈), O, or S,
each occurrence of Z₁ to Z₈ are the same or different, and are each independently:
hydrogen, deuterium, or a cyano group; or
a C₁-C₂₀ alkyl group, a phenyl group, a biphenyl group, a terphenyl group, a dibenzofuranyl group, or a dibenzothiophenyl group, each being unsubstituted or substituted with at least one selected from deuterium, a cyano group, a C₁-C₂₀ alkyl group, a phenyl group, or a biphenyl group,
b1 to b6 are each independently 1, 2, or 3,
at least one of Z₁ in the number of b1, Z₂ in the number of b2, Z₃ in the number of b3, Z₄ in the number of b4, Z₅ in the number of b5, and R₆ in the number of b6 is a cyano group, and
m is 0 or 1.

19. The organic light-emitting device of claim 14, wherein
the light-emitting material comprises a transition metal-containing organometallic compound that emits blue light.

20. The organic light-emitting device of claim 14, wherein
the light-emitting material comprises an organometallic compound,
the organometallic compound comprises a bidentate ligand and a transition metal, and
the bidentate ligand comprises at least one cyano group or at least one fluoro group.
